(19) United States
(12) Patent Application Publication
(10) Pub. No.: US 2023/0273521 A1
(43) Pub. Date: Aug. 31, 2023

(54) CHEMICALLY AMPLIFIED PHOTOSENTIVE COMPOSITION, PHOTOSENSITIVE DRY FILM, PRODUCTION METHOD OF SUBSTRATE HAVING TEMPLATE FOR PLATING, AND PRODUCTION METHOD OF PLATED ARTICLE

(71) Applicant: TOKYO OHKA KOGYO CO., LTD., Kawasaki-shi (JP)

(72) Inventors: Daisuke OJIMA, Kawasaki-shi (JP); Yuta YAMAMOTO, Kawasaki-shi (JP); Akiya KAWAUE, Kawasaki-shi (JP)

(21) Appl. No.: 18/006,987

(22) PCT Filed: Jul. 7, 2021
(86) PCT No.: PCT/JP2021/025556

§ 371 Date: Jan. 26, 2023

(30) Foreign Application Priority Data
Aug. 4, 2020 (JP) 2020-132562

(51) Int. Cl. G03F 7/039

(52) U.S. Cl. CPC G03F 7/0392

(57) ABSTRACT

A chemically amplified positive-type photosensitive composition capable of forming a patterned resist film having a square cross-section of a nonresist portion and good plating liquid resistance, even when forming a thick patterned resist film; a photosensitive dry film including a photosensitive layer consisting of the photosensitive composition; a production method of a substrate having a template for plating using the photosensitive composition; and a production method of a plated article using the substrate having the template formed by the aforementioned method. An acrylic resin having a constituent unit derived from a crosslinkable monomer which meets predetermined requirements as a resin is added to a chemically amplified positive-type photosensitive composition containing an acid generator which generates an acid by irradiation of active rays or radioactive rays and the resin, and a calculated value of glass transition temperature of hypothetical non-crosslinked acrylic resin which the constituent unit is excluded from the acrylic resin is set to 90° C. or higher and 120° C. or lower.

### TECHNICAL FIELD

The present invention relates to a chemically amplified photosensitive composition used for forming a template for plating on a substrate by photolithography method; a photosensitive dry film including a photosensitive layer consisting of this chemically amplified photosensitive composition; a production method of a substrate having a template for plating using the aforementioned chemically amplified photosensitive composition; a production method of a plated article using the aforementioned substrate having the template for plating.

### BACKGROUND ART

Photofabrication is now the mainstream of a microfabrication technique. Photofabrication is a generic term describing the technology used for manufacturing a wide variety of precision components such as semiconductor packages. The manufacturing is carried out by applying a photoresist composition to the surface of a processing target to form a photoresist layer, patterning this photoresist layer using photolithographic techniques, and then conducting chemical etching, electrolytic etching, or electroforming based mainly on electroplating, using the patterned photoresist layer (photoresist pattern) as a mask.

In recent years, high density packaging technologies have progressed in semiconductor packages along with downsizing electronics devices, and the increase in package density has been developed on the basis of mounting multi-pin thin film in packages, miniaturizing of package size, two-dimensional packaging technologies in flip-tip systems or three-dimensional packaging technologies. In these types of high-density packaging techniques, connection terminals, for example, protruding electrodes (mounting terminals) known as bumps that protrude above the package or metal posts that extend from peripheral terminals on the wafer and connect rewiring with the mounting terminals, are disposed on the surface of the substrate with high precision.

In the photofabrication as described above, a photoresist composition is used, and chemically amplified photosensitive compositions containing an acid generator have been known as such a photoresist composition (see Patent Documents 1, 2 and the like). According to the chemically amplified photosensitive composition, an acid is generated from the acid generator upon irradiation with radiation (exposure) and diffusion of the acid is promoted through heat treatment, to cause an acid catalytic reaction with a base resin and the like in the composition resulting in a change to the alkali-solubility of the same.

Such chemically amplified photosensitive compositions are used, for example, in formation of plated articles such as bumps, metal posts, and Cu-rewiring by a plating step, in addition to patterned insulating film or formation of etching mask. Specifically, a photoresist layer having a desired film thickness is formed on a support such as a metal substrate using a chemically amplified photosensitive composition, and the photoresist layer is exposed through a predetermined mask pattern and is developed. Thereby, a patterned resist film used as a template in which portions for forming plated articles have been selectively removed (stripped) is formed. Then, bumps or metal posts, and Cu rewiring can be formed by embedding a conductor such as copper into the removed portions (nonresist portions) using plating, and then removing the surrounding resist film.

Patent Document 1: Japanese Unexamined Patent Application, Publication No. H09-176112

Patent Document 2: Japanese Unexamined Patent Application, Publication No. H11-52562

### DISCLOSURE OF THE INVENTION

### Problems to be Solved by the Invention

Generally, in the formation of resist pattern, rectangular cross-sectional shape of the resist pattern is often desired. In particular, in the formation of connection terminals such as bumps and metal posts according to the above-described plating process, rectangular cross-sectional shape of nonresist portion in the resist pattern as the template is strongly desired. In addition, when the thick resist film is used as the template, sometimes, temperature for plating is set to high temperature, or plating is conducted for a long time. Therefore, high resistance to the plating liquid is required for the resist film.

The present invention has been made taking account of the above-mentioned problems, and has an object of providing a chemically amplified positive-type photosensitive composition capable of forming a patterned resist film having a square cross-section of a nonresist portion and good plating liquid resistance, even when forming a thick patterned resist film; a photosensitive dry film including a photosensitive layer consisting of this chemically amplified positive-type photosensitive composition; a production method of a substrate having a template for plating using the aforementioned chemically amplified positive-type photosensitive composition; and a production method of a plated article using the substrate having the template formed by the aforementioned method.

### Means for Solving the Problems

As a result of diligently researching in order to achieve the above-mentioned object, the present inventors found that it was possible to solve the above-mentioned problem by inclusion of an acrylic resin (B1a) having a constituent unit (bL1) derived from a crosslinkable monomer which meets predetermined requirements as a resin (B) whose solubility in alkali increases and by setting a calculated value of glass transition temperature of hypothetical non-crosslinked acrylic resin which the constituent unit (bL1) is excluded from the acrylic resin (B1a) to 90° C. or higher and 120° C. or lower in a chemically amplified positive-type photosensitive composition containing an acid generator (A) which generates an acid by irradiation of active rays or radioactive rays and the resin (B). More specifically, the present invention provides the following.

A first aspect of the present invention is a chemically amplified positive-type photosensitive composition used for forming a template for plating on a substrate by photolithography method,
in which the chemically amplified positive-type photosensitive composition includes an acid generator (A) which generates an acid by irradiation of active rays or radioactive rays; and a resin (B) whose solubility in alkali increases under an action of acid,
in which the resin (B) includes an acrylic resin (B1a) including a constituent unit (bL1) derived form a crosslinkable monomer represented by formula (BL1):

R^{B1}—O—R^{B3}—O—R^{B2} (BL1)
in which, in the formula (BL1), R^{B1} and R^{B2} are each independently a (meth)acryloyl group or a vinylphenyl group, R^{B3} is a divalent bridging group, and at least one of two O—R^{B3} bonds in the formula (BL1) generates a carboxy group or a phenolic hydroxy group by cleavage by an action of acid, a molar ratio of the constituent unit (bL1) is 1% by mole or more and 10% by mole or less relative to all constituent units of the acrylic resin (B1a), and
a calculated value of glass transition temperature of hypothetical non-crosslinked acrylic resin which the constituent unit (bL1) is excluded from the acrylic resin (B1a) is 90° C. or higher and 120° C. or lower.

A second aspect of the present invention is a chemically amplified positive-type photosensitive composition used for forming a template for plating on a substrate by photolithography method, in which the chemically amplified positive-type photosensitive composition includes an acid generator (A) which generates an acid by irradiation of active rays or radioactive rays; and a resin (B) whose solubility in alkali increases under an action of acid,
in which the resin (B) includes an acrylic resin (B1a) including a constituent unit (bL1) derived form a crosslinkable monomer represented by formula (BL1):

R^{B1}—O—R^{B3}—O—R^{B2} (BL1)
in which, in the formula (BL1), R^{B1} and R^{B2} are each independently a (meth)acryloyl group or a vinylphenyl group, R^{B3} is a divalent bridging group, and at least one of two O—R^{B3} bonds in the formula (BL1) generates a carboxy group or a phenolic hydroxy group by cleavage by an action of acid, a constituent unit (bL2) derived form an alkyl (meth)acrylate (BL2), and
a constituent unit (bL3) derived from an (meth)acrylate (BL3) including an alicyclic hydrocarbon group or an aromatic group, in the alkyl (meth)acrylate (BL2), an alkyl group optionally substituted with a hydroxy group or an alkoxy group and having 1 or more and 10 or less carbon atoms bonds to a (meth)acryloyloxy group, and a carbon atom which bonds to the (meth)acryloyloxy group does not correspond to a tertiary carbon atom having an sp³ hybrid orbital,
in the (meth)acrylate (BL3) including the alicyclic hydrocarbon group or the aromatic group, the alicyclic hydrocarbon group or the aromatic group bonds to a (meth)acryloyloxy group, the alicyclic hydrocarbon group or the aromatic group may be substituted with one or more substituents selected from the group consisting of an alkyl group, an alkoxy group and a hydroxy group, and a carbon atom to which the (meth)acryloyloxy group bonds does not correspond to a tertiary carbon atom having an sp³ hybrid orbital, a molar ratio of the constituent unit (bL1) is 1% by mole or more and 10% by mole or less relative to all constituent units of the acrylic resin (B1b),
a molar ratio of the constituent unit (bL2) is 0.1% by mole or more and 10% by mole or less relative to all constituent units of the acrylic resin (B1b), a molar ratio of the constituent unit (bL3) is 25% by mole or more and 50% by mole or less relative to all constituent units of the acrylic resin (B1b).

A third aspect of the present invention is a photosensitive dry film including: a base film, and a photosensitive layer formed on a surface of the base film, in which the photosensitive layer consisting of the chemically amplified positive-type photosensitive composition according to the first aspect or the second aspect.

A fourth aspect of the present invention is a production method of a substrate having a template for plating including: a lamination step of laminating a photosensitive layer consisting of the chemically amplified positive-type photosensitive composition according to the first aspect or the second aspect on a substrate, an exposure step of position selectively irradiating active rays or radioactive rays onto the photosensitive layer; and a template-formation step of forming a patterned resist film as a template for plating by developing the photosensitive layer after exposure.

A fifth aspect of the present invention is a production method for a plated article including:
forming the plated article by plating to the substrate having the template produced by the method according to the fourth aspect.

### Effects of the Invention

According to the present invention, it is possible to provide a chemically amplified positive-type photosensitive composition capable of forming a patterned resist film having a square cross-section of a nonresist portion and good plating liquid resistance, even when forming a thick patterned resist film; a photosensitive dry film including a photosensitive layer consisting of this chemically amplified positive-type photosensitive composition; a production method of a substrate having a template for plating using the aforementioned chemically amplified positive-type photosensitive composition; and a production method of a plated article using the substrate having the template formed by the aforementioned method.

### PREFERRED MODE FOR CARRYING OUT THE INVENTION

### <<Chemically Amplified Positive-Type Photosensitive Composition>>

A chemically amplified positive-type photosensitive composition is used for forming a template for plating on a substrate by photolithography method.

Hereinafter, a chemically amplified positive-type photosensitive composition used for forming a template for plating on a substrate by photolithography method,
in which the chemically amplified positive-type photosensitive composition includes an acid generator (A) which generates an acid by irradiation of active rays or radioactive rays; and a resin (B) whose solubility in alkali increases under an action of acid,
in which the resin (B) includes an acrylic resin (B1a) including a constituent unit (bL1) derived form a crosslinkable monomer represented by formula (BL1):

R^{B1}—O—R^{B3}—O—R^{B2} (BL1)
in which, in the formula (BL1), R^{B1} and R^{B2} are each independently a (meth)acryloyl group or a vinylphenyl group, R^{B3} is a divalent bridging group, and at least one of two O—R^{B3} bonds in the formula (BL1) generates a carboxy group or a phenolic hydroxy group by cleavage by an action of acid, a molar ratio of the constituent unit (bL1) is 1% by mole or more and 10% by mole or less relative to all constituent units of the acrylic resin (B1a), and
a calculated value of glass transition temperature of hypothetical non-crosslinked acrylic resin which the constituent unit (bL1) is excluded from the acrylic resin (B1a) is 90° C. or higher and 120° C. or lower,
will be described as a first chemically amplified positive-type photosensitive composition.

Hereinafter, a chemically amplified positive-type photosensitive composition used for forming a template for plating on a substrate by photolithography method,
in which the chemically amplified positive-type photosensitive composition includes an acid generator (A) which generates an acid by irradiation of active rays or radioactive rays; and a resin (B) whose solubility in alkali increases under an action of acid,
in which the resin (B) includes an acrylic resin (B1b) including a constituent unit (bL1) derived form a crosslinkable monomer represented by formula (BL1):

R^{B1}—O—R^{B3}—O—R^{B2} (BL1)
in which, in the formula (BL1), R^{B1} and R^{B2} are each independently a (meth)acryloyl group or a vinylphenyl group, R^{B3} is a divalent bridging group, and at least one of two O—R^{B3} bonds in the formula (BL1) generates a carboxy group or a phenolic hydroxy group by cleavage by an action of acid, a constituent unit (bL2) derived from an alkyl (meth)acrylate (BL2), and
a constituent unit (bL3) derived from an (meth)acrylate (BL3) including an alicyclic hydrocarbon group or an aromatic group,
in the alkyl (meth)acrylate (BL2), an alkyl group optionally substituted with a hydroxy group or an alkoxy group and having 1 or more and 10 or less carbon atoms bonds to a (meth)acryloyloxy group, and a carbon atom which bonds to the (meth)acryloyloxy group does not correspond to a tertiary carbon atom having an sp³ hybrid orbital,
in the (meth)acrylate (BL3) including the alicyclic hydrocarbon group or the aromatic group, the alicyclic hydrocarbon group or the aromatic group bonds to a (meth)acryloyloxy group, the alicyclic hydrocarbon group or the aromatic group may be substituted with one or more substituents selected from the group consisting of an alkyl group, an alkoxy group and a hydroxy group, and a carbon atom to which the (meth)acryloyloxy group bonds does not correspond to a tertiary carbon atom having an sp³ hybrid orbital, a molar ratio of the constituent unit (bL1) is 1% by mole or more and 10% by mole or less relative to all constituent units of the acrylic resin (B1b),
a molar ratio of the constituent unit (bL2) is 0.1% by mole or more and 10% by mole or less relative to all constituent units of the acrylic resin (B1b), and
a molar ratio of the constituent unit (bL3) is 25% by mole or more and 50% by mole or less relative to all constituent units of the acrylic resin (B1b),
will be described as a second chemically amplified positive-type photosensitive composition.

### <First Chemically Amplified Positive-Type Photosensitive Composition>

The first chemically amplified positive-type photosensitive composition is a chemically amplified positive-type photosensitive composition used for forming a template for plating on a substrate by photolithography method.

The first chemically amplified positive-type photosensitive composition includes an acid generator (A) which generates an acid by irradiation of active rays or radioactive rays; and a resin (B) whose solubility in alkali increases under an action of acid. The resin (B) includes an acrylic resin (B1a) including a constituent unit (bL1) derived form a crosslinkable monomer represented by formula (BL1):

R^{B1}—O—R^{B3}—O—R^{B2} (BL1)
in which, in the formula (BL1), R^{B1} and R^{B2} are each independently a (meth)acryloyl group or a vinylphenyl group, R^{B3} is a divalent bridging group, and at least one of two O—R^{B3} bonds in the formula (BL1) generates a carboxy group or a phenolic hydroxy group by cleavage by an action of acid. A molar ratio of the constituent unit (bL1) is 1% by mole or more and 10% by mole or less relative to all constituent units of the acrylic resin (B1a). A calculated value of glass transition temperature of hypothetical non-crosslinked acrylic resin which the constituent unit (bL1) is excluded from the acrylic resin (B1a) is 90° C. or higher and 120° C. or lower.

The patterned resist film having a square cross-section of a nonresist portion and good plating liquid resistance can be formed by using the first chemically amplified positive-type photosensitive composition which meets the above requirements, even when forming a thick patterned resist film by photolithography method.

Hereinafter, for the first chemically amplified positive-type photosensitive composition, essential or optional components, and the manufacturing method will be described. Hereinafter, the first chemically amplified positive-type photosensitive composition is also referred to as “first photosensitive composition”

It should be noted that an acid generator (A) described below and various optional components can be used for the second chemically amplified positive-type photosensitive composition described below.

### {Acid Generator (A)}

The acid generator (A) is a compound capable of producing an acid when irradiated with an active ray or radiation, and is not particularly limited as long as it is a compound which directly or indirectly produces an acid under the action of light. The acid generator (A) is preferably any one of the acid generators of the first to fifth aspects that will be described below. Hereinafter, among the suitably used acid generators (A) in the first photosensitive composition, suitable acid generators (A) will be described as the first to fifth aspects.

The first aspect of the acid generator (A) may be a compound represented by the following formula (a1).

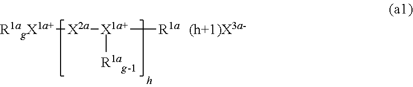

In the formula (a1), X^{1a} represents a sulfur atom or iodine atom respectively having a valence of g; g represents 1 or 2. h represents the number of repeating units in the structure within parentheses. R^{1a} represents an organic group that is bonded to X^{1a}, and represents an aryl group having 6 or more and 30 or less carbon atoms, a heterocyclic group having 4 or more and 30 or less carbon atoms, an alkyl group having 1 or more and 30 or less carbon atoms, an alkenyl group having 2 or more and 30 or less carbon atoms, or an alkynyl group having 2 or more and 30 or less carbon atoms, and R^{1a} may be substituted with at least one selected from the group consisting of an alkyl group, a hydroxyl group, an alkoxy group, an alkylcarbonyl group, an arylcarbonyl group, an alkoxycarbonyl group, an aryloxycarbonyl group, an arylthiocarbonyl group, an acyloxy group, an arylthio group, an alkylthio group, an aryl group, a heterocyclic group, an aryloxy group, an alkylsulfinyl group, an arylsulfinyl group, an alkylsulfonyl group, an arylsulfonyl group, an alkyleneoxy group, an amino group, a cyano group, a nitro group, and halogen atoms. The number of R^{1a}s is g+h(g−1)+1, and the R^{1a}s may be respectively identical to or different from each other. Furthermore, two or more Rias may be bonded to each other directly or via —O—, —S—, —SO—, —SO₂—, —NH—, —NR^{2a}—, —CO—, —COO—, —CONH—, an alkylene group having 1 or more and 3 or less carbon atoms, or a phenylene group, and may form a ring structure including Xia. R^{2a} represents an alkyl group having 1 or more and 5 or less carbon atoms, or an aryl group having 6 or more and 10 or less carbon atoms.

X^{2a} represents a structure represented by the following formula (a2).

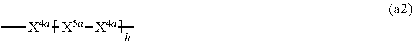

In the above formula (a2), X^{4a} represents an alkylene group having 1 or more and 8 or less carbon atoms, an arylene group having 6 or more and 20 or less carbon atoms, or a divalent group of a heterocyclic compound having 8 or more and 20 or less carbon atoms, and X^{4a} may be substituted with at least one selected from the group consisting of an alkyl group having 1 or more and 8 or less carbon atoms, an alkoxy group having 1 or more and 8 or less carbon atoms, an aryl group having 6 or more and 10 or less carbon atoms, a hydroxyl group, a cyano group, a nitro group, and halogen atoms. X^{5a} represents —O—, —S—, —SO—, —SO₂—, —NH—, —NR^{2a}—, —CO—, —COO—, —CONH—, an alkylene group having 1 or more and 3 or less carbon atoms, or a phenylene group. h represents the number of repeating units of the structure in parentheses. X^{4a}s in the number of h+1 and X^{5a}s in the number of h may be identical to or different from each other. R^{2a} has the same definition as described above.

X^{3a-} represents a counterion of an onium, and examples thereof include a fluorinated alkylfluorophosphoric acid anion represented by the following formula (a17) or a borate anion represented by the following formula (a18).

[(R^{3a})^{j}PF₆₋ⱼ]⁻ (a17)

In the formula (a17), R^{3a} represents an alkyl group having 80% or more of the hydrogen atoms substituted with fluorine atoms. j represents the number of R^{3a}s and is an integer of 1 or more and 5 or less. R^{3a}s in the number of j may be respectively identical to or different from each other.

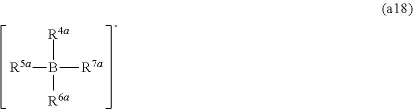

In the formula (a18), R^{4a} to R^{7a} each independently represents a fluorine atom or a phenyl group, and a part or all of the hydrogen atoms of the phenyl group may be substituted with at least one selected from the group consisting of a fluorine atom and a trifluoromethyl group.

Examples of the onium ion in the compound represented by the above formula (a1) include triphenylsulfonium, tri-p-tolylsulfonium, 4-(phenylthio)phenyldiphenylsulfonium, bis[4-(diphenylsulfonio)phenyl] sulfide, bis[4-{bis[4-(2-hydroxyethoxy)phenyl]sulfonio}phenyl] sulfide, bis{4-[bis(4-fluorophenyl)sulfonio]phenyl} sulfide, 4-(4-benzoyl-2-chlorophenylthio)phenylbis(4-fluorophenyl)sulfonium, 7-isopropyl-9-oxo-10-thia-9,10-dihydroanthracen-2-yldi-p-tolylsulfonium, 7-isopropyl-9-oxo-10-thia-9,10-dihydroanthracen-2-yldiphenylsulfonium, 2-[(diphenyl)sulfonio]thioxanthone, 4-[4-(4-tert-butylbenzoyl)phenylthio]phenyldi-p-tolylsulfonium, 4-(4-benzoylphenylthio)phenyldiphenylsulfonium, diphenylphenacylsulfonium, 4-hydroxyphenylmethylbenzylsulfo-nium, 2-naphthylmethyl(1-ethoxycarbonyl)ethylsulfonium, 4-hydroxyphenylmethylphenacylsulfonium, phenyl[4-(4-biphenylthio)phenyl]-4-biphenylsulfonium, phenyl[4-(4-biphenylthio)phenyl]-3-biphenylsulfonium, [4-(4-acetophenylthio)phenyl]diphenylsulfonium, octadecylmethylphenacylsulfonium, diphenyliodonium, di-p-tolyliodonium, bis(4-dodecylphenyl)iodonium, bis(4-methoxyphenyl)iodonium, (4-octyloxyphenyl)phenyliodonium, bis(4-decyloxy)phenyliodonium, 4-(2-hydroxytetradecyloxy)phenylphenyliodonium, 4-isopropylphenyl(p-tolyl)iodonium, 4-isobutylphenyl(p-tolyl)iodonium, or the like.

Among the onium ions in the compound represented by the above formula (a1), a preferred onium ion may be a sulfonium ion represented by the following formula (a19).

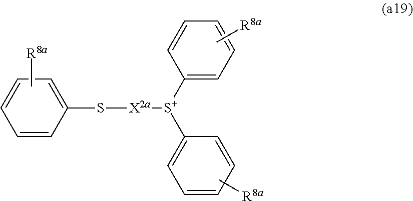

In the above formula (a19), R^{8a}s each independently represents a hydrogen atom or a group selected from the group consisting of alkyl, hydroxyl, alkoxy, alkylcarbonyl, alkylcarbonyloxy, alkyloxycarbonyl, a halogen atom, an aryl, which may be substituted, and arylcarbonyl. X^{2a} has the same definition as X²a in the above formula (a1)

Specific examples of the sulfonium ion represented by the above formula (a19) include 4-(phenylthio)phenyldiphenylsulfonium, 4-(4-benzoyl-2-chlorophenylthio)phenylbis(4-fluorophenyl)sulfonium, 4-(4-benzoylphenylthio)phenyldiphenylsulfonium, phenyl[4-(4-biphenylthio)phenyl]-4-biphenylsulfonium, phenyl[4-(4-biphenylthio)phenyl]-3-biphenylsulfonium, [4-(4-acetophenylthio)phenyl]diphenylsulfonium, and diphenyl[4-(p-terphenylthio)phenyl]diphenylsulfonium.

In regard to the fluorinated alkylfluorophosphoric acid anion represented by the above formula (a17), R^{3a} represents an alkyl group substituted with a fluorine atom, and a preferred number of carbon atoms is 1 or more and 8 or less, while a more preferred number of carbon atoms is 1 or more and 4 or less. Specific examples of the alkyl group include linear alkyl groups such as methyl, ethyl, propyl, butyl, pentyl and octyl; branched alkyl groups such as isopropyl, isobutyl, sec-butyl and tert-butyl; and cycloalkyl groups such as cyclopropyl, cyclobutyl, cyclopentyl, and cyclohexyl. The proportion of hydrogen atoms substituted with fluorine atoms in the alkyl groups is usually 80% or more, preferably 90% or more, and even more preferably 100%. If the substitution ratio of fluorine atoms is less than 80%, the acid strength of the onium fluorinated alkylfluorophosphate represented by the above formula (a1) decreases.

A particularly preferred example of R^{3a} is a linear or branched perfluoroalkyl group having 1 or more and 4 or less carbon atoms and a substitution ratio of fluorine atoms of 100%. Specific examples thereof include CF₃, CF₃CF₂, (CF₃)₂CF, CF₃CF₂CF₂, CF₃CF₂CF₂CF₂, (CF₃)₂CFCF₂, CF₃CF₂(CF₃)CF, and (CF₃)₃C. j which is the number of R^{3a}s represents an integer of 1 or more and 5 or less, and is preferably 2 or more and 4 or less, and particularly preferably 2 or 3.

Preferred specific examples of the fluorinated alkylfluorophosphoric acid anion include [(CF₃CF₂)₂PF₄]—, [(CF₃CF₂)₃PF₃]⁻, [((CF₃)₂CF)₂PF₄]⁻, [((CF₃)₂CF)₃PF₃]⁻, [(CF₃CF₂CF₂)₂PF₄]⁻, [(CF₃CF₂CF₂)₃PF₃]⁻, [((CF₃)₂CFCF₂)₂PF₄]⁻, [((CF₃)₂CFCF₂)₃PF₃]⁻, [(CF₃CF₂CF₂CF₂)₂PF₄]⁻, or [(CF₃CF₂CF₂)₃PF₃]⁻. Among these, [(CF₃CF₂)₃PF₃]⁻, [(CF₃CF₂CF₂)₃PF₃]⁻, [((CF₃)₂CF)₃PF₃]⁻, [((CF₃)₂CF)₂PF₄]⁻, [((CF₃)₂CFCF₂)₃PF₃]⁻, or [((CF₃)₂CFCF₂)₂PF₄]⁻ are particularly preferred.

Preferred specific examples of the borate anion represented by the above formula (a18) include tetrakis(pentafluorophenyl) borate ([B(C₆F₅)₄]⁻), tetrakis [(trifluoromethyl)phenyl]borate ([B(C₆H₄CF₃)₄]⁻), difluorobis(pentafluorophenyl) borate ([(C₆F₅)₂BF₂]⁻), trifluoro(pentafluorophenyl)borate ([(C₆F₅)BF₃]⁻), and tetrakis(difluorophenyl) borate ([B(C₆H₃F₂)₄]⁻). Among these, tetrakis(pentafluorophenyl) borate ([B(C₆F₅)₄]⁻) is particularly preferred.

The second aspect of the acid generator (A) include halogen-containing triazine compounds such as 2,4-bis(trichloromethyl)-6-piperonyl-1,3,5-triazine, 2,4-bis(trichloromethyl)-6-[2-(2-furyl)ethenyl]-s-triazine, 2,4-bis(trichloromethyl)-6-[2-(5-methyl-2-furyl)ethenyl]-s-triazine, 2,4-bis(trichloromethyl)-6-[2-(5-ethyl-2-furyl)ethenyl]-s-triazine, 2,4-bis(trichloromethyl)-6-[2-(5-propyl-2-furyl)ethenyl]-s-triazine, 2,4-bis(trichloromethyl)-6-[2-(3,5-dimethoxyphenyl)ethenyl]-s-triazine, 2,4-bis(trichloromethyl)-6-[2-(3,5-diethoxyphenyl)ethenyl]-s-triazine, 2,4-bis(trichloromethyl)-6-[2-(3,5-dipropoxyphenyl)ethenyl]-s-triazine, 2,4-bis(trichloromethyl)-6-[2-(3-methoxy-5-ethoxyphenyl)ethenyl]-s-triazine, 2,4-bis(trichloromethyl)-6-[2-(3-methoxy-5-propoxyphenyl)ethenyl]-s-triazine, 2,4-bis(trichloromethyl)-6-[2-(3,4-methylenedioxyphenyl)ethenyl]-s-triazine, 2,4-bis(trichloromethyl)-6-(3,4-methylenedioxyphenyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(2-bromo-4-methoxy)styrylphenyl-s-triazine, 2,4-bis-trichloromethyl-6-(3-bromo-4-methoxy)styrylphenyl-s-triazine, 2-(4-methoxyphenyl)-4,6-bis(trichloromethyl)-1,3,5-triazine, 2-(4-methoxynaphthyl)-4,6-bis(trichloromethyl)-1,3,5-triazine, 2-[2-(2-furyl)ethenyl]-4,6-bis(trichloromethyl)-1,3,5-triazine, 2-[2-(5-methyl-2-furyl)ethenyl]-4,6-bis(trichloromethyl)-1,3,5-triazine, 2-[2-(3,5-dimethoxyphenyl)ethenyl]-4,6-bis(trichloromethyl)-1,3,5-triazine, 2-[2-(3,4-dimethoxyphenyl)ethenyl]-4,6-bis(trichloromethyl)-1,3,5-triazine, 2-(3,4-methylenedioxyphenyl)-4,6-bis(trichloromethyl)-1,3,5-triazine, tris(1,3-dibromopropyl)-1,3,5-triazine and tris(2,3-dibromopropyl)-1,3,5-triazine, and halogen-containing triazine compounds represented by the following formula (a3) such as tris(2,3-dibromopropyl)isocyanurate.

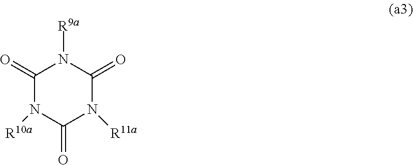

In the above formula (a3), R^{9a}, R^{10a}, and R^{11a} each independently represent a halogenated alkyl group.

Further, the third aspect of the acid generator (A) include α-(p-toluenesulfonyloxyimino)-phenylacetonitrile, α-(benzenesulfonyloxyimino)-2,4-dichlorophenylacetonitrile, α-(benzenesulfonyloxyimino)-2,6-dichlorophenylacetonitrile, α-(2-chlorobenzenesulfonyloxyimino)-4-methoxyphenylacetonitrile and α-(ethylsulfonyloxyimino)-1-cyclopentenylacetonitrile, and compounds represented by the following formula (a4) having an oximesulfonate group.

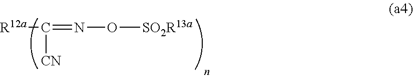

In the above formula (a4), R^{12a} represents a monovalent, bivalent or trivalent organic group, R^{13a} represents a substituted or unsubstituted saturated hydrocarbon group, an unsaturated hydrocarbon group, or an aromatic group, and n represents the number of repeating units of the structure in the parentheses.

In the formula (a4), examples of the aromatic group include aryl groups such as a phenyl group and a naphthyl group, and heteroaryl groups such as a furyl group and a thienyl group. These may have one or more appropriate substituents such as halogen atoms, alkyl groups, alkoxy groups and nitro groups on the rings. It is particularly preferable that R^{13a} is an alkyl group having 1 or more and 6 or less carbon atoms such as a methyl group, an ethyl group, a propyl group, and a butyl group. In particular, compounds in which R^{12a} represents an aromatic group, and R^{13a} represents an alkyl group having 1 or more and 4 or less carbon atoms are preferred.

Examples of the acid generator represented by the above formula (a4) include compounds in which R^{12a} is any one of a phenyl group, a methylphenyl group and a methoxyphenyl group, and R^{13a} is a methyl group, provided that n is 1, and specific examples thereof include α-(methylsulfonyloxyimino)-1-phenylacetonitrile, α-(methylsulfonyloxyimino)-1-(p-methylphenyl)acetonitrile, α-(methylsulfonyloxyimino)-1-(p-methoxyphenyl)acetonitrile, [2-(propylsulfonyloxyimino)-2,3-dihydroxythiophene-3-ylidene] (o-tolyl)acetonitrile and the like. Provided that n is 2, the acid generator represented by the above formula (a4) is specifically an acid generator represented by the following formulae.

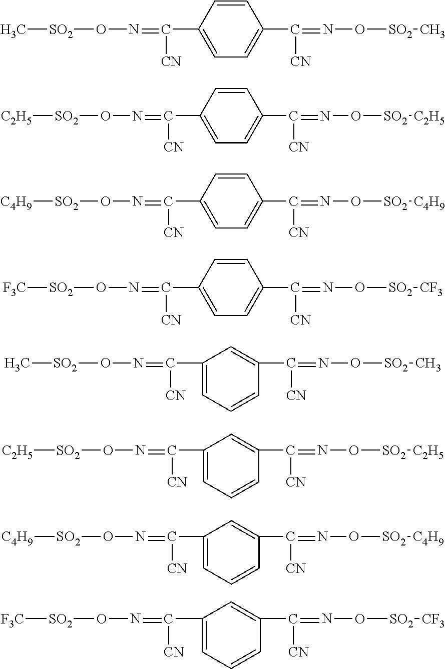

In addition, the fourth aspect of the acid generator (A) include onium salts that have a naphthalene ring at their cation moiety. The expression “have a naphthalene ring” indicates having a structure derived from naphthalene and also indicates at least two ring structures and their aromatic properties are maintained. The naphthalene ring may have a substituent such as a linear or branched alkyl group having 1 or more and 6 or less carbon atoms, a hydroxyl group, a linear or branched alkoxy group having 1 or more and 6 or less carbon atoms or the like. The structure derived from the naphthalene ring, which may be of a monovalent group (one free valence) or of a bivalent group (two free valences), is desirably of a monovalent group (in this regard, the number of free valence is counted except for the portions connecting with the substituents described above). The number of naphthalene rings is preferably 1 or more and 3 or less.

Preferably, the cation moiety of the onium salt having a naphthalene ring at the cation moiety is of the structure represented by the following formula (a5).

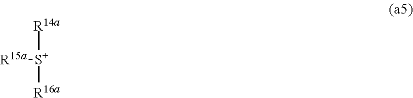

In the above formula (a5), at least one of R^{14a}, R^{15a} and R^{16a} represents a group represented by the following formula (a6), and the remaining represents a linear or branched alkyl group having 1 or more and 6 or less carbon atoms, a phenyl group optionally having a substituent, a hydroxyl group, or a linear or branched alkoxy group having 1 or more and 6 or less carbon atoms. Alternatively, one of R^{14a}, R^{15a} and R^{16a} is a group represented by the following formula (a6), and the remaining two are each independently a linear or branched alkylene group having 1 or more and 6 or less carbon atoms, and these terminals may bond to form a ring structure.

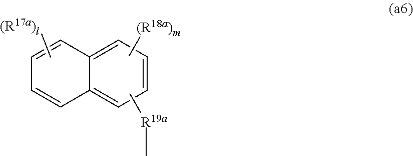

In the formula (a6), R^{17a} and R^{11a} each independently represent a hydroxyl group, a linear or branched alkoxy group having 1 or more and 6 or less carbon atoms, or a linear or branched alkyl group having 1 or more and 6 or less carbon atoms, and R^{19a} represents a single bond or a linear or branched alkylene group having 1 or more and 6 or less carbon atoms that may have a substituent. 1 and m each independently represent an integer of 0 or more and 2 or less, and 1+m is 3 or less. Herein, when there exists a plurality of R^{17a}, they may be identical to or different from each other. Furthermore, when there exists a plurality of R^{18a}, they may be identical to or different from each other.

Preferably, among R^{14a}, R^{15a} and R^{16a} as above, the number of groups represented by the above formula (a6) is one in view of the stability of the compound, and the remaining are linear or branched alkylene groups having 1 or more and 6 or less carbon atoms of which the terminals may bond to form a ring. In this case, the two alkylene groups described above form a 3 to 9 membered ring including sulfur atom(s). Preferably, the number of atoms to form the ring (including sulfur atom(s)) is 5 or more and 6 or less.

Examples of the substituent, which the alkylene group may have, include an oxygen atom (in this case, a carbonyl group is formed together with a carbon atom that constitutes the alkylene group), a hydroxyl group or the like.

Furthermore, examples of the substituent, which the phenyl group may have, include a hydroxyl group, a linear or branched alkoxy group having 1 or more and 6 or less carbon atoms, a linear or branched alkyl group having 1 or more and 6 or less carbon atoms, or the like.

Examples of suitable cations for the suitable cation moiety include cations represented by the following formulae (a7) and (a8), and the structure represented by the following formula (a8) is particularly preferable.

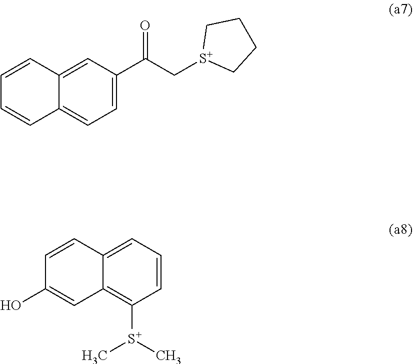 [SMILES: O=C(C[S+]1CCCC1)c1ccc2ccccc2c1 ; C[S+](C)c1cccc2ccc(O)cc12]

The cation moieties, which may be of an iodonium salt or a sulfonium salt, are desirably of a sulfonium salt in view of acid-producing efficiency.

It is, therefore, desirable that the suitable anions for the anion moiety of the onium salt having a naphthalene ring at the cation moiety is an anion capable of forming a sulfonium salt.

The anion moiety of the acid generator is exemplified by fluoroalkylsulfonic acid ions or aryl sulfonic acid ions, of which hydrogen atom(s) being partially or entirely fluorinated.

The alkyl group of the fluoroalkylsulfonic acid ions may be linear, branched or cyclic and have 1 or more and 20 or less carbon atoms. Preferably, the carbon number is 1 or more and 10 or less in view of bulkiness and diffusion distance of the produced acid. In particular, branched or cyclic alkyl groups are preferable due to shorter diffusion length. Also, methyl, ethyl, propyl, butyl, octyl groups and the like are preferable due to being inexpensively synthesizable.

The aryl group of the aryl sulfonic acid ions may be an aryl group having 6 or more and 20 or less carbon atoms, and is exemplified by a phenol group or a naphthyl group that may be unsubstituted or substituted with an alkyl group or a halogen atom. In particular, aryl groups having 6 or more and 10 or less carbon atoms are preferable due to being inexpensively synthesizable. Specific examples of preferable aryl group include phenyl, toluenesulfonyl, ethylphenyl, naphthyl, methylnaphthyl groups and the like.

When hydrogen atoms in the above fluoroalkylsulfonic acid ion or the aryl sulfonic acid ion are partially or entirely substituted with a fluorine atom, the fluorination rate is preferably 10% or more and 100% or less, and more preferably 50% or more and 100% or less; it is particularly preferable that all hydrogen atoms are each substituted with a fluorine atom in view of higher acid strength. Specific examples thereof include trifluoromethane sulfonate, perfluorobutane sulfonate, perfluorooctane sulfonate, perfluorobenzene sulfonate, and the like.

Among these, the preferable anion moiety is exemplified by those represented by the following formula (a9).

R^{20a}SO₃⁻ (a9)

In the above formula (a9), R^{20a} represents groups represented by the following formulae (a10), (all), and (a12).

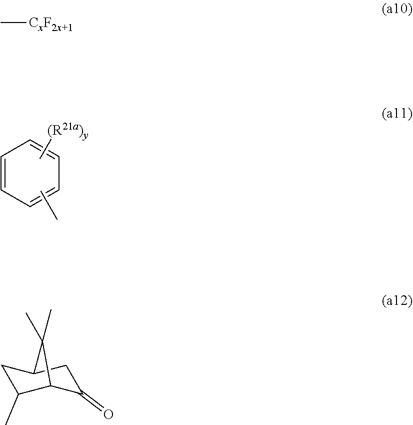

In the above formula (a10), x represents an integer of 1 or more and 4 or less. Also, in the above formula (all), R^{21a} represents a hydrogen atom, a hydroxyl group, a linear or branched alkyl group having 1 or more and 6 or less carbon atoms, or a linear or branched alkoxy group having 1 or more and 6 or less carbon atoms, and y represents an integer of 1 or more and 3 or less. Of these, trifluoromethane sulfonate, and perfluorobutane sulfonate are preferable in view of safety.

In addition, a nitrogen-containing moiety represented by the following formulae (a13) and (a14) may also be used for the anion moiety.

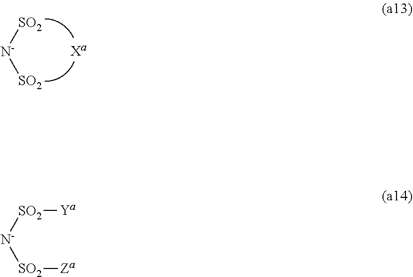

In the formulae (a13) and (a14), X^{a} represents a linear or branched alkylene group in which at least one hydrogen atom is substituted with a fluorine atom, the carbon number of the alkylene group is 2 or more and 6 or less, preferably 3 or more and 5 or less, and most preferably the carbon number is 3. In addition, Y^{a} and Z^{a} each independently represent a linear or branched alkyl group of which at least one hydrogen atom is substituted with a fluorine atom, the number of carbon atoms in the alkyl group is 1 or more and 10 or less, preferably 1 or more and 7 or less, and more preferably 1 or more and 3 or less.

The smaller number of carbon atoms in the alkylene group of X^{a}, or in the alkyl group of Y^{a} or Z^{a} is preferred since the solubility into organic solvent is preferable.

In addition, a larger number of hydrogen atoms each substituted with a fluorine atom in the alkylene group of X^{a}, or in the alkyl group of Y^{a} or Z^{a} is preferred since the acid strength becomes greater. The percentage of fluorine atoms in the alkylene group or alkyl group, i.e., the fluorination rate is preferably 70% or more and 100% or less and more preferably 90% or more and 100% or less, and most preferable are perfluoroalkylene or perfluoroalkyl groups in which all of the hydrogen atoms are each substituted with a fluorine atom.

Examples of preferable compounds for onium salts having a naphthalene ring at their cation moieties include compounds represented by the following formulae (a15) and (a16).

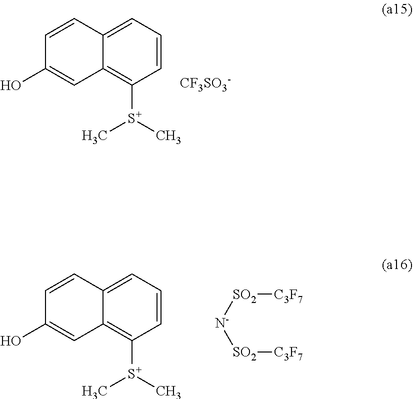

Also, the fifth aspect of the acid generator (A) include bissulfonyldiazomethanes such as bis(p-toluenesulfonyl)diazomethane, bis(1,1-dimethyl ethylsulfonyl)diazomethane, bis(cyclohexylsulfonyl)diazomethane and bis(2,4-dimethylphenylsulfonyl)diazomethane; nitrobenzyl derivatives such as 2-nitrobenzyl p-toluenesulfonate, 2,6-dinitrobenzyl p-toluenesulfonate, nitrobenzyl tosylate, dinitrobenzyl tosylate, nitrobenzyl sulfonate, nitrobenzyl carbonate and dinitrobenzyl carbonate; sulfonates such as pyrogalloltrimesylate, pyrogalloltritosylate, benzyltosylate, benzylsulfonate, N-methylsulfonyloxysuccinimide, N-trichloromethylsulfonyloxysuccinimide, N-phenylsulfonyloxymaleimide and N-methylsulfonyloxyphthalimide; trifluoromethane sulfonates such as N-(trifluoromethylsulfonyloxy)phthalimide, N-(trifluoromethylsulfonyloxy)-1,8-naphthalimide and N-(trifluoromethylsulfonyloxy)-4-butyl-1,8-naphthalimide; onium salts such as diphenyliodonium hexafluorophosphate, (4-methoxyphenyl)phenyliodonium trifluoromethanesulfonate, bis(p-tert-butylphenyl)iodonium trifluoromethanesulfonate, triphenylsulfonium hexafluorophosphate, (4-methoxyphenyl)diphenylsulfonium trifluoromethanesulfonate and (p-tert-butylphenyl)diphenylsulfonium trifluoromethanesulfonate; benzointosylates such as benzointosylate and α-methylbenzointosylate; other diphenyliodonium salts, triphenylsulfonium salts, phenyldiazonium salts, benzylcarbonates and the like.

As the acid generator (A), a naphthalic acid derivative represented by the below Formula (a21) is also preferable.

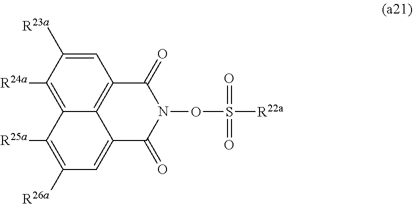

(In the formula (a21), R^{22a} is a monovalent organic group, R^{23a}, R^{24a}, R^{25a} and R^{26a} are each independently a hydrogen atom or a monovalent organic group, R^{23a} and R^{24a}, R^{24a} and R^{25a}, or R^{25a} and R^{26a} may respectively bind to each other to form a ring.)

The organic group as R^{22a} is not particularly limited in a scope not inhibiting the object of the present invention. This organic group may be a hydrocarbon group, or may include a heteroatom such as O, N, S, P and halogen atoms. In addition, the structure of this organic group may be linear, may be branched, may be cyclic, or may be a combination of these structures.

Examples of the preferable organic group as R^{22a} include an aliphatic hydrocarbon group having 1 or more and 18 or less carbon atoms which may be substituted by a halogen atom, and/or an alkylthio group; an aryl group having 6 or more and 20 or less carbon atoms which may have a substituent; an aralkyl group having 7 or more and 20 or less carbon atoms which may have a substituent; an alkylaryl group having 7 or more and 20 or less carbon atoms which may have a substituent, a camphor-10-yl group; and a group represented by the formula (a21a) below.

—R^{27a}—(O)ₐ—R^{28a}—(O)_{b}—Y¹—R^{29a} (a21a)

(In the formula (a21a), Y¹ is a single bond or an alkanediyl group having 1 or more and 4 or less carbon atoms. R^{27a} and R^{28a} are each an alkanediyl group having 2 or more and 6 or less carbon atoms which may be substituted by a halogen atom, or an arylene group having 6 or more and 20 or less carbon atoms which may be substituted by a halogen atom. R^{29a} is an alkyl group having 1 or more and 18 or less carbon atoms which may be substituted by a halogen atom, am alicyclic hydrocarbon group having 3 or more and 12 or less carbon atoms, an aryl group having 6 or more and 20 or less carbon atoms which may be substituted by a halogen atom, or an aralkyl group having 7 or more and 20 or less carbon atoms which may be substituted by a halogen atom. a and b are each 0 or 1, and at least one of a and b is 1.)

When the organic group as R^{22a} has a halogen atom as the substituent, examples of the halogen atom include a chlorine atom, a bromine atom, an iodine atom, and a fluorine atom.

When the organic group as R^{22a} is the alkyl group having 1 or more and 18 or less carbon atoms and substituted by an alkylthio group, the number of carbon atoms in the alkylthio group is preferably 1 or more and 18 or less. Examples of the alkylthio group having 1 or more and 18 or less carbon atoms include a methylthio group, an ethylthio group, an n-propylthio group, an isopropylthio group, an n-butylthio group, a sec-butylthio group, a tert-butylthio group, an isobutylthio group, an n-pentylthio group, an isopentylthio group, an n-pentylthio group, an isopentylthio group, a tert-pentylthio group, an n-hexylthio group, an n-heptylthio group, an isoheptylthio group, a tert-heptylthio group, an n-octylthio group, an isooctylthio group, a tert-octylthio group, a 2-ethylhexylthio group, an n-nonylthio group, an n-decylthio group, an n-undecylthio group, an n-dodecylthio group, an n-tridecylthio group, an n-tetradecylthio group, an n-pentadecylthio group, an n-hexadecylthio group, an n-heptadecylthio group, and an n-octadecylthio group.

When the organic group as R^{22a} is the aliphatic hydrocarbon group having 1 or more and 18 or less carbon atoms which may be substituted by a halogen atom and/or alkylthio group, the aliphatic hydrocarbon group may include an unsaturated double bond. In addition, the structure of this aliphatic hydrocarbon group is not particularly limited, and may be linear, may be branched, may be cyclic, or may be a combination of these structures.

When the organic group as R^{22a} is the alkenyl group, suitable examples include an allyl group and a 2-methyl-2-propenyl group.

When the organic group as R^{22a} is the alkyl group, suitable examples include a methyl group, an ethyl group, an n-propyl group, an isopropyl group, an n-butyl group, a sec-butyl group, a tert-butyl group, an isobutyl group, an n-pentyl group, an isopentyl group, a tert-pentyl group, an n-hexyl group, an n-hexane-2-yl group, an n-hexane-3-yl group, an n-heptyl group, an n-heptane-2-yl group, an n-heptane-3-yl group, an isoheptyl group, a tert-heptyl group, an n-octyl group, an isooctyl group, a tert-octyl group, a 2-ethylhexyl group, an n-nonyl group, an isononyl group, an n-decyl group, an n-undecyl group, an n-dodecyl group, an n-tridecyl group, an n-tetradecyl group, an n-pentadecyl group, an n-hexadecyl group, an n-heptadecyl group and an n-octadecyl group.

When the organic group as R^{22a} is the alicyclic hydrocarbon group, examples of the alicyclic hydrocarbon constituting the main skeleton of the alicyclic hydrocarbon group include a cyclopropane, a cyclobutene, cyclopentane, a cyclohexane, cycloheptane, a cyclooctane, a cyclodecane, a bicyclo[2.1.1]hexane, a bicyclo[2.2.1]heptane, a bicyclo[3.2.1]octane, a bicyclo[2.2.2]octane, and an adamantane. As the alicyclic hydrocarbon group, a group excluding one hydrogen atom from these alicyclic hydrocarbons is preferable.

When the organic group as R^{22a} is the aliphatic hydrocarbon group substituted by a halogen atom, suitable examples include a trifluoromethyl group, a pentafluoroethyl group, a 2-chloroethyl group, a 2-bromoethyl group, a heptafluoro-n-propyl group, a 3-bromopropyl group, a nonafluoro-n-butyl group, a tridecafluoro-n-hexyl group, a heptadecafluoro-n-octyl group, a 2,2,2-trifluoroethyl group, a 1,1-difluoroethyl group, a 1,1-difluoro-n-propyl group, a 1,1,2,2-tetrafluoro-n-propyl group, a 3,3,3-trifluoro-n-propyl group, a 2,2,3,3,3-pentafluoro-n-propyl group, a 2-norbornyl-1,1-difluoroethyl group, a 2-norbornyl tetrafluoroethyl group, and a 3-adamantyl-1,1,2,2-tetrafluoropropyle group.

When the organic group as R^{22a} is the aliphatic hydrocarbon group substituted by an alkylthio group, suitable examples include a 2-methylthioethyl group, a 4-methylthio-n-butyl group and a 2-n-butylthioethyl group.

When the organic group as R^{22a} is the aliphatic hydrocarbon group substituted by a halogen atom or alkylthio group, suitable examples include a 3-methylthio-1,1,2,2-tetrafluoro-n-propyl group.

When the organic group as R^{22a} is the aryl group, suitable examples include a phenyl group, a naphthyl group and a biphenylyl group.

When the organic group as R^{22a} is the aryl group substituted by a halogen atom, suitable examples include a pentafluorophenyl group, a chlorophenyl group, a dichlorophenyl group and a trichlorophenyl group.

When the organic group as R^{22a} is the aryl group substituted by an alkylthio group, suitable examples include a 4-methylthiophenyl group, a 4-n-butylthiophenyl group, a 4-n-octylthiophenyl group and a 4-n-dodecylthiophenyl group.

When the organic group as R^{22a} is the aryl group substituted by a halogen atom and alkylthio group, suitable examples include a 1,2,5,6-tetrafluoro-4-methylthiophenyl group, a 1,2,5,6-tetrafluoro-4-n-butylthiophenyl group and a 1,2,5,6-tetrafluoro-4-n-dodecylthiophenyl group.

When the organic group as R^{22a} is the aralkyl group, suitable examples include a benzyl group, a phenethyl group, a 2-phenylpropane-2-yl group, a diphenylmethyl group and a triphenylmethyl group.

When the organic group as R^{22a} is the aralkyl group substituted by a halogen atom, suitable examples include a pentafluorophenylmethyl group, a phenyldifluoromethyl group, a 2-phenyltetrafluoroethyl group and a 2-(pentafluorophenyl)ethyl group.

When the organic group as R^{22a} is the aralkyl group substituted by an alkylthio group, suitable examples include a p-methylthiobenzyl group.

When the organic group as R^{22a} is the aralkyl group substituted by a halogen atom and alkylthio group, suitable examples include a 2-(2,3,5,6-tetrafluoro-4-methylthiophenyl)ethyl group.

When the organic group as R^{22a} is the alkylaryl group, suitable examples thereof includes 2-methylphenyl group, 3-methylphenyl group, 4-methylphenyl group, 3-isopropylphenyl group, 4-isopropylphenyl group, 4-n-butylphenyl group, 4-isobutylphenyl group, 4-tert-butylphenyl group, 4-n-hexylphenyl group, 4-cyclohexylphenyl group, 4-n-octylphenyl group, 4-(2-ethyl-n-hexyl)phenyl group, 2,3-dimethylphenyl group, 2,4-dimethylphenyl group, 2,5-dimethylphenyl group, 2,6-dimethylphenyl group, 3,4-dimethylphenyl group, 3,5-dimethylphenyl group, 2,4-di-tert-butylphenyl group, 2,5-di-tert-butylphenyl group, 2,6-di-tert-butylphenyl group, 2,4-di-tert-pentylphenyl group, 2,5-di-tert-pentylphenyl group, 2,5-di-tert-octylphenyl group, 2-cyclohexylphenyl group, 3-cyclohexylphenyl group, 4-cyclohexylphenyl group, 2,4,5-trimethylphenyl group, 2,4,6-trimethylphenyl group and 2,4,6-triisopropylphenyl group.

The group represented by the formula (a21a) is an ether-group containing group. In the formula (a21a), examples of the alkanediyl group having 1 or more and 4 or less carbon atoms and represented by Y¹ include methylene group, ethane-1,2-diyl group, ethane-1,1-diyl group, propane-1,3-diyl group, propane-1,2-diyl group, butane-1,4-diyl group, butane-1,3-diyl group, butane-2,3-diyl group and butane-1,2-diyl group. In the formula (a21a), examples of the alkanediyl group having 2 or more and 6 or less carbon atoms and represented by R^{27a} or R^{2a} include ethane-1,2-diyl group, propane-1,3-diyl group, propane-1,2-diyl group, butane-1,4-diyl group, butane-1,3-diyl group, butane-2,3-diyl group, butane-1,2-diyl group, pentane-1,5-diyl group, pentane-1,3-diyl group, pentane-1,4-diyl group, pentane-2,3-diyl group, hexane-1,6-diyl group, hexane-1,2-diyl group, hexane-1,3-diyl group, hexane-1,4-diyl group, hexane-2,5-diyl group, hexane-2,4-diyl group and hexane-3,4-diyl group.

In the formula (a21a), when R^{27a} or R^{2a} are alkanediyl groups having 2 or more and 6 or less carbon atoms and substituted by a halogen atom, examples of the halogen atom include a chlorine atom, a bromine atom, an iodine atom and a fluorine atom can. Examples of the alkanediyl group substituted by a halogen atom include tetrafluoroethane-1,2-diyl group, 1,1-difluoroethane-1,2-diyl group, 1-fluoroethane-1,2-diyl group, 1,2-difluoroethane-1,2-diyl group, hexafluoropropane-1,3-diyl group, 1,1,2,2-tetrafluoropropane-1,3-diyl group, and 1,1,2,2-tetrafluoropentane-1,5-diyl group.

In the formula (a21a), when R^{27a} or R^{28a} is the arylene group, examples thereof include 1,2-phenylene group, 1,3-phenylene group, 1,4-phenyl group, 2,5-dimethyl-1,4-phenylene group, biphenyl-4,4′-diyl group, diphenylmethane-4,4′-diyl group, 2,2-diphenylpropane-4,4′-diyl group, naphthalene-1,2-diyl group, naphthalene-1,3-diyl group, naphthalene-1,4-diyl group, naphthalene-1,5-diyl group, naphthalene-1,6-diyl group, naphthalene-1,7-diyl group, naphthalene-1,8-diyl group, naphthalene-2,3-diyl group, naphthalene-2,6-diyl group and naphthalene-2,7-diyl group.

In the formula (a21a), when R^{27a} or R^{28a} are arylene groups substituted by a halogen atom, examples of the halogen atom include a chlorine atom, a bromine atom, an iodine atom and a fluorine atom. Examples of the arylene group substituted by a halogen atom include 2,3,5,6-tetrafluoro-1,4-phenylene group.

In the formula (a21a), examples of the optionally branched alkyl group having 1 or more and 18 or less carbon atoms and represented by R^{29a} include methyl group, ethyl group, n-propyl group, isopropyl group, n-butyl group, sec-butyl group, tert-butyl group, isobutyl group, n-pentyl group, isopentyl group, tert-pentyl group, n-hexyl group, n-hexane-2-yl group, n-hexane-3-yl group, n-heptyl group, n-heptane-2-yl group, n-heptane-3-yl group, isoheptyl group, tert-heptyl group, n-octyl group, isooctyl group, tert-octyl group, 2-ethylhexyl group, n-nonyl group, isononyl group, n-decyl group, n-undecyl group, n-dodecyl group, n-tridecyl group, n-tetradecyl group, n-pentadecyl group, n-hexadecyl group, n-heptadecyl group and n-octadecyl group.

In the formula (a21a), when R^{29a} is the alkyl group having 1 or more and 18 or less carbon atoms and substituted by a halogen atom, examples of the halogen atom include a chlorine atom, a bromine atom, an iodine atom and a fluorine atom. Examples of the alkyl group substituted by a halogen atom include trifluoromethyl group, pentafluoroethyl group, heptafluoro-n-propyl group, nonafluoro-n-butyl group, tridecafluoro-n-hexyl group, heptadecafluoro-n-octyl group, 2,2,2-trifluoroethyl group, 1,1-difluoroethyl group, 1,1-difluoro-n-propyl group, 1,1,2,2-tetrafluoro-n-propyl group, 3,3,3-trifluoro-n-propyl group, 2,2,3,3,3-pentafluoro-n-propyl group, and 1,1,2,2-tetrafluoropropyl group.

In the formula (a21a), when R^{29a} is the alicyclic hydrocarbon group having 3 or more and 12 or less carbon atoms, examples of the alicyclic hydrocarbon constituting the main skeleton of this alicyclic hydrocarbon group include cyclopropane, cyclobutene, cyclopentane, cyclohexane, cycloheptane, cyclooctane, cyclodecane, bicyclo[2.1.1]hexane, bicyclo[2.2.1]heptane, bicyclo[3.2.1]octane, bicyclo[2.2.2]octane, and adamantane.

In the formula (a21a), in the case of R^{29a} being an aryl group, halogenated aryl group, aralkyl group or halogenated aralkyl group, suitable examples of these groups are the same as the case of R^{22a} being these groups.

A suitable group among these groups represented by the formula (a21a) is a group in which the carbon atom bonded to a sulfur atom among the groups represented by R^{27a} is substituted by a fluorine atom. The number of carbon atoms in such suitable groups is preferably at 2 or more and 18 or less.

As R^{22a}, a perfluoroalkyl group having 1 or more and 8 or less carbon atoms is preferred. In addition, due to tending to form a highly detailed patterned resist film, camphor-10-yl group is also preferable as R^{22a}.

In the formula (a21), R^{23a} to R^{26a} is a hydrogen atom or a monovalent organic group. In addition, R^{23a} and R^{24a}, R^{24a} and R^{25a}, or R^{25a} and R^{26a} may form a ring by bonding to each other. For example, by forming a 5-member ring with naphthalene ring by R^{25a} and R^{26a} bonding, it may form acenaphthene skeleton.

As the monovalent organic group, an alkyl group having 4 or more and 18 or less carbon atoms which may be substituted by an alicyclic hydrocarbon group, a heterocyclic group (heterocyclyl group) or a halogen atom and may have a branch, an alkoxy group; a heterocyclyloxy group; an alkylthio group having 4 or more and 18 or less carbon atoms which may be substituted by an alicyclic hydrocarbon group, a heterocyclic group (heterocyclyl group) or a halogen atom, and may have a branch; and a heterocyclylthio group are preferable. In addition, a group in which the methylene group at any position not adjacent to the carbon atom of this alkoxy group is substituted by —CO— is preferable. A group in which this alkoxy group is interrupted by a —O—CO— bond or —O—CO—NH— bond is also preferable. It should be noted that the right end of the —O—CO— bond and —O—CO—NH— bond is the side close to the naphthalic acid mother nucleus in the alkoxy group. Furthermore, an alkylthio group having 4 or more and 18 or less carbon atoms which may be substituted by an alicyclic hydrocarbon group, heterocyclic group or halogen atom, and may have a branch is also preferable as R^{23a} to R^{26a}. A group in which a methylene group at a position not adjacent to the sulfur atom of this alkylthio group is substituted by —CO— is also preferable. A group in which this alkylthio group is interrupted by a —O—CO— bond or —O—CO—NH— bond is also preferable. It should be noted that the left end of the —O—CO— bond and —O—CO—NH— bond is a side closer to the naphthalic acid mother nucleus in the alkylthio group.

As R^{23a} to R^{26a}, it is preferable for R^{23a} to be an organic group, R^{24a} to R^{26a} to be hydrogen atoms, or R^{24a} to be an organic group, and R^{23a}, R^{25a} and R^{26a} to be hydrogen atoms. In addition, R^{23a} to R^{26a} may all be hydrogen atoms.

When R^{23a} to R^{26a} are unsubstituted alkyl groups, examples thereof include n-butyl group, sec-butyl group, tert-butyl group, isobutyl group, n-pentyl group, isopentyl group, tert-pentyl group, n-hexyl group, n-heptyl group, isoheptyl group, tert-heptyl group, n-octyl group, isooctyl group, tert-octyl group, 2-ethylhexyl group, n-nonyl group, n-decyl group, n-undecyl group, n-dodecyl group, n-tridecyl group, n-tetradecyl group, n-pentadecyl group, n-hexadecyl group, n-heptadecyl group, and n-octadecyl group.

When R^{23a} to R^{26a} are unsubstituted alkoxy groups, examples thereof include n-butyloxy group, sec-butyloxy group, tert-butyloxy group, isobutyloxy group, n-pentyloxy group, isopentyloxy group, tert-pentyloxy group, n-hexyloxy group, n-heptyloxy group, isoheptyloxy group, tert-heptyloxy group, n-octyloxy group, isooctyloxy group, tert-octyloxy group, 2-ethylhexyl group, n-nonyloxy group, n-decyloxy group, n-undecyloxy group, n-dodecyloxy group, n-tridecyloxy group, n-tetradecyloxy group, n-pentadecyloxy group, n-hexadecyloxy group, n-heptadecyloxy group and n-octadecyloxy group.

When R^{23a} to R^{26a} are unsubstituted alkylthio groups, examples thereof include n-butylthio group, sec-butylthio group, tert-butylthio group, isobutylthio group, n-pentylthio group, isopentylthio group, tert-pentylthio group, n-pentylthio group, n-heptylthio group, isoheptylthio group, tert-heptylthio group, n-octylthio group, isooctylthio group, tert-octylthio group, 2-ethylhexylthio group, n-nonylthio group, n-decylthio group, n-undecylthio group, an n-dodecylthio group, n-tridecylthio group, n-tetradecylthio group, n-pentadecylthio group, n-hexadecylthio group, n-heptadecylthio group and n-octadecylthio group.

When R^{23a} to R^{26a} are alkyl groups, alkoxy groups or alkylthio groups substituted by an alicyclic hydrocarbon group, examples of the alicyclic hydrocarbon constituting the main skeleton of the alicyclic hydrocarbon group include cyclopropane, cyclobutene, cyclopentane, cyclohexane, cycloheptane, cyclooctane, cyclodecane, bicyclo[2.1.1]hexane, bicyclo[2.2.1]heptane, bicyclo[3.2.1]octane, bicyclo[2.2.2]octane, and adamantane.

When R^{23a} to R^{26a} are an alkyl group, alkoxy group or alkylthio group substituted by heterocyclic group, or when R^{23a} to R^{26a} are heterocyclyloxy groups, examples of the heterocyclic ring constituting the main skeleton of the heterocyclic group or heterocyclyloxy group include pyrrole, thiophene, furan, pyran, thiopyran, imidazole, pyrazole, thiazole, isothiazole, oxazole, isoxazole, pyridine, pyrazine, pyrimidine, pyridazine, pyrrolidine, pyrazolidine, imidazolidine, isooxazolidine, isothiazolidine, piperidine, piperazine, morpholine, thiomorpholine, chroman, thiochroman, isochroman, isothiochroman, indoline, isoindolin, pyridine, indolizine, indole, indazole, purine, quinolizine, isoquinoline, quinoline, naphthyridine, phthalazine, quinoxaline, quinazoline, chinnoline, pteridine, acridine, perimidine, phenanthroline, carbazole, carboline, phenazine, anthyridine, thiadiazole, oxadiazole, triazine, triazole, tetrazole, benzimidazole, benzoxazole, benzothiazole, benzothiadiazole, benzofuroxan, naphthimidazole, benzotriazole and tetraazaindene. In addition, among these heterocycles, saturated hetereocycles hydrogenating a ring having conjugated bonds are also preferable. As the heterocyclic group substituting the alkyl group, alkoxy group or alkylthio group, or the heterocyclic group included in the heterocyclyloxy group, groups excluding one hydrogen atom from the above-mentioned heterocycle is preferable.

When R^{23a} to R^{26a} are an alkoxy groups including an alicyclic hydrocarbon group, examples thereof include cyclopentyloxy group, methylcyclopentaoxy group, cyclohexyloxy group, fluorocyclohexyloxy group, chlorocylcohexyloxy group, cyclohexylmethyloxyl group, methylcylcohexyloxy group, norbornyloxy group, ethylcyclohexyloxy group, cyclohexylethyloxy group, dimethylcyclohexyloxy group, methylcyclohexylmethyloxy group, norbornylmethyloxy group, trimethylcyclohexyloxy group, 1-cyclohexylbutyloxy group, adamantyloxy group, methyloxy group, n-butylcyclohexyloxy group, tert-butylcyclohexyloxy group, bornyloxy group, isobornyloxy group, decahydronaphthyloxy group, dicyclopentadienoxy group, 1-cyclohexylpentyloxy group, methyladamantylmethyloxy group, 4-pentylcyclohexyloxy group, cyclohexylcyclohexyloxy group, adamantylethyloxy group, and dimethyladamantyloxy group.

When R^{23a} to R^{26a} are heterocyclyloxy groups, examples thereof include tetrahydrofuranyloxy group, furfuryloxyl group, tetrahydrofurfuryloxy group, tetrahydropyranyloxy group, butyrolactonyloxy group, and indoyloxy group.

When R^{23a} to R^{26a} are alkylthio groups including an alicyclic hydrocarbon group, examples thereof include cyclopentylthio group, cyclohexylthio group, cyclohexylmethylthio group, norbornylthio group, and isonorbornylthio group.

When R^{23a} to R^{26a} are heterocyclylthio groups, examples thereof include furfuylthio group and tetrahydrofurfurylthio group can be exemplified.

When R^{23a} to R^{26a} are groups in which a methylene group at any position not adjacent to an oxygen atom of the alkoxy group is substituted by —CO—, examples thereof include 2-ketobutyl-1-oxy group, 2-ketopentyl-1-oxy group, 2-ketohexyl-1-oxy group, 2-ketoheptyl-1-oxy group, 2-ketooctyl-1-oxy group, 3-ketobutyl-1-oxy group, 4-ketopentyl-1-oxy group, 5-ketohexyl-1-oxy group, 6-ketoheptyl-1-oxy group, 7-ketooctyl-1-oxy group, 3-methyl-2-ketopentane-4-oxy group, 2-ketopentane-4-oxy group, 2-methyl-2-ketopentane-4-oxy group, 3-ketoheptane-5-oxy group and 2-adamantanone-5-oxy group.

When R^{23a} to R^{26a} are groups in which a methylene group at any position not adjacent to a sulfur atom of the alkylthio group is substituted by —CO— include 2-ketobutyl-1-thio group, 2-ketopentyl-1-thio group, 2-ketohexyl-1-thio group, 2-ketoheptyl-1-thio group, 2-ketoocyl-1-thio group, 3-ketobutyl-1-thio group, 4-ketopentyl-1-thio group, 5-ketohexyl-1-thio group, 6-ketoheptyl-1-thio group, 7-ketoocyl-1-thio group, 3-methyl-2-ketopentan-4-thio group, 2-ketopentan-4-thio group, 2-methyl-2-ketopentan-4-thio group and 3-ketoheptan-5-thio group.

Specific examples of the compound represented by the formula (a21) include the following compounds.

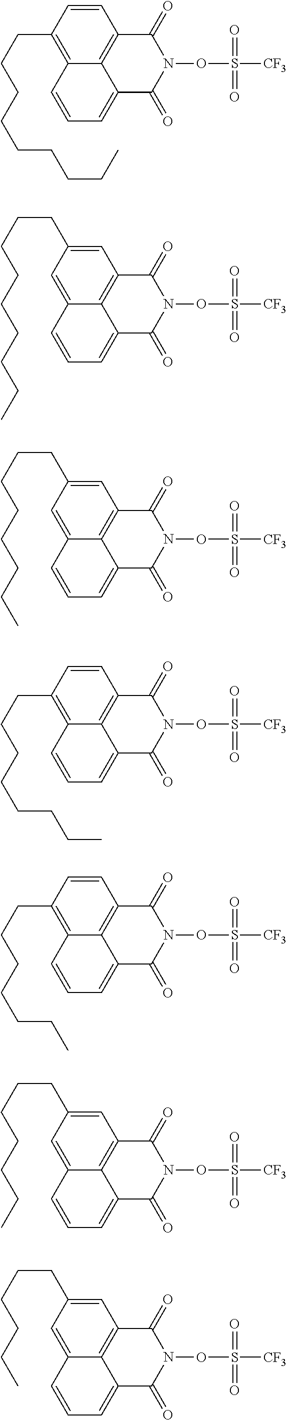

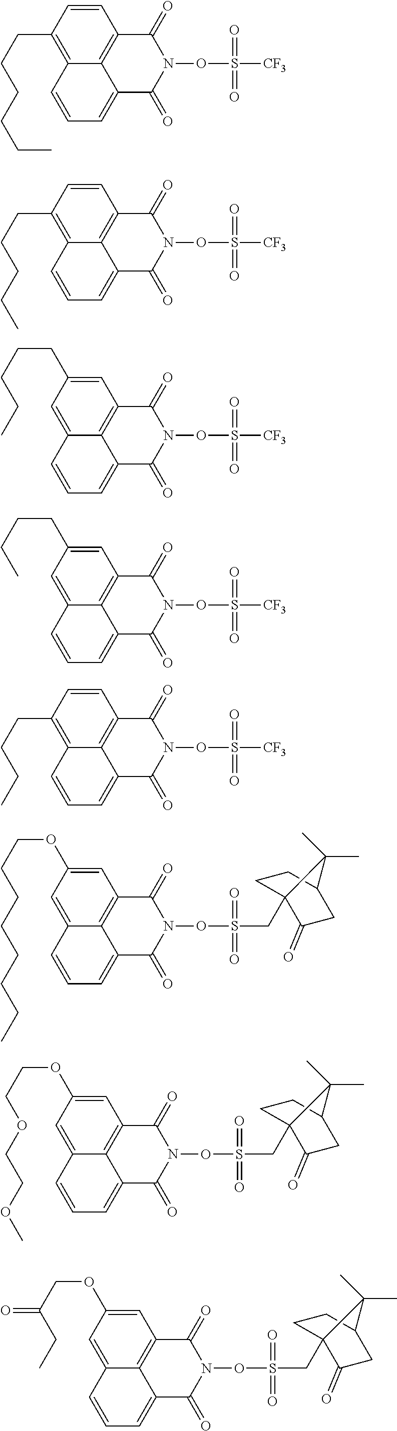

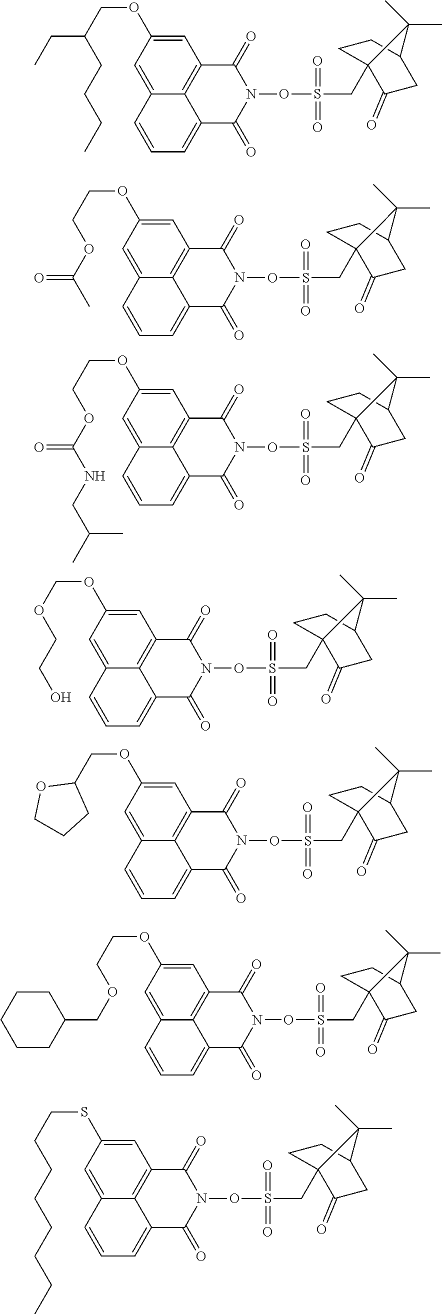

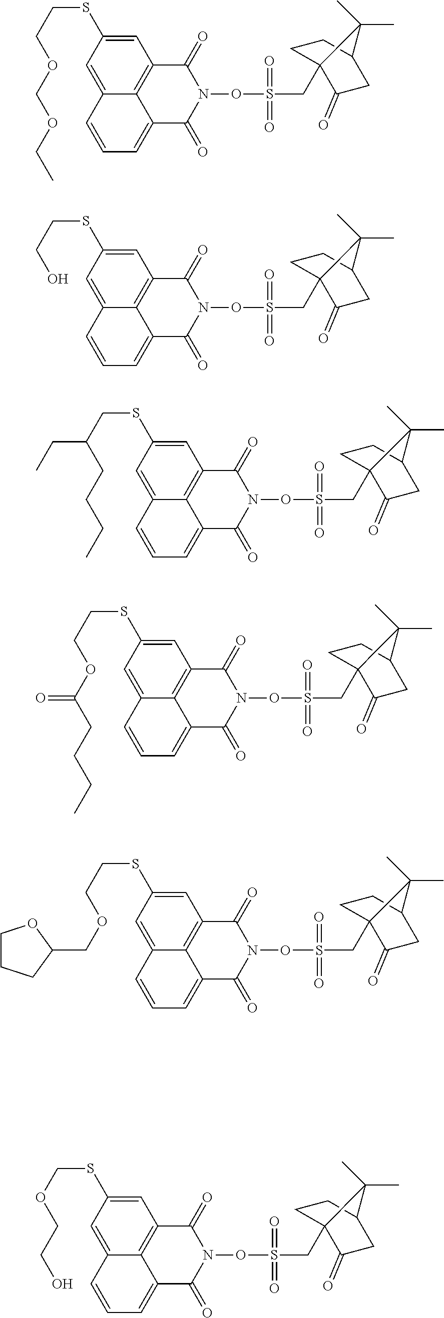

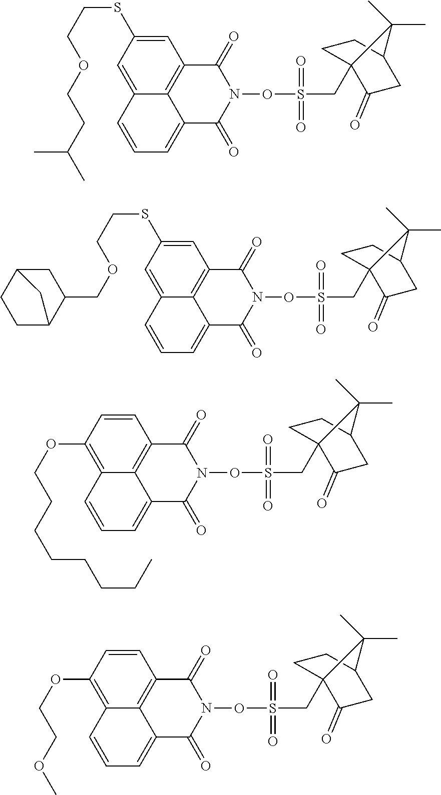

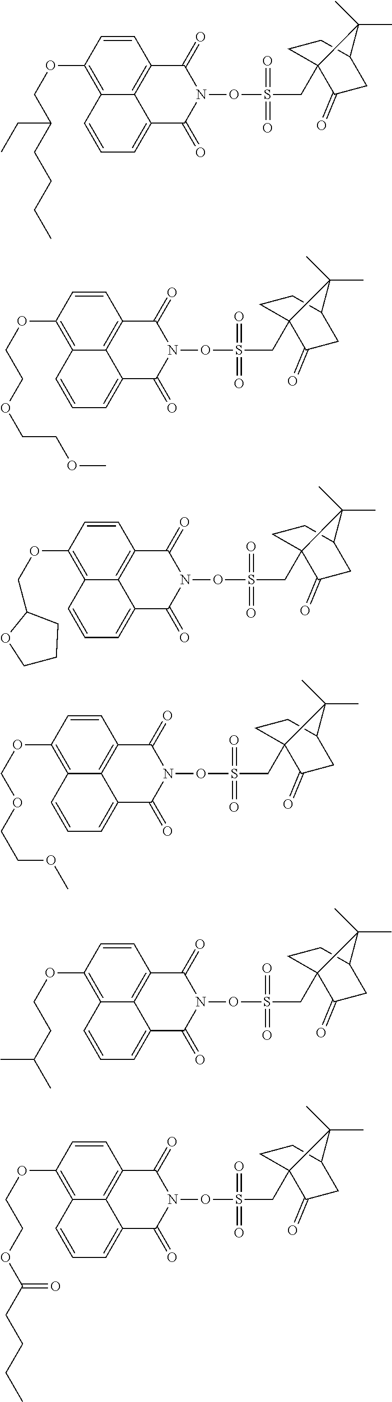

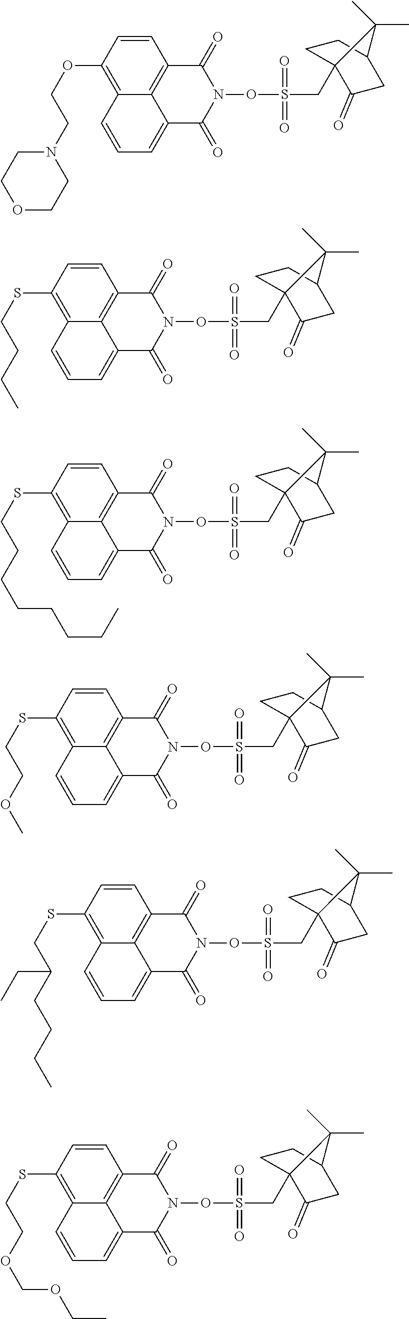

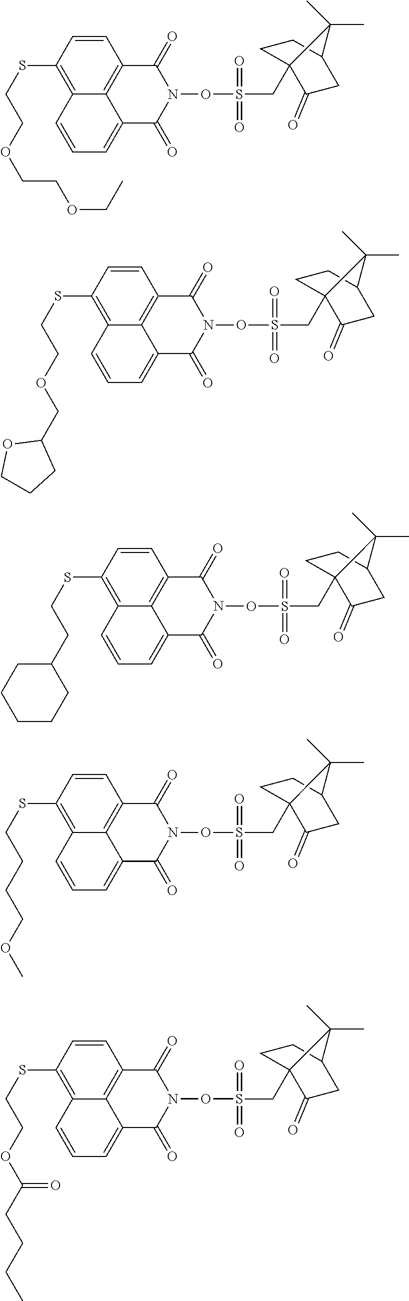 [SMILES: CCOCCOCCSc1ccc2c3c(cccc13)C(=O)N(OS(=O)(=O)CC13CCC(CC1=O)C3(C)C)C2=O ; CC1(C)C2CCC1(CS(=O)(=O)ON1C(=O)c3cccc4c(SCCOCC5CCCO5)ccc(c34)C1=O)C(=O)C2 ; CC1(C)C2CCC1(CS(=O)(=O)ON1C(=O)c3cccc4c(SCCC5CCCCC5)ccc(c34)C1=O)C(=O)C2 ; COCCCCSc1ccc2c3c(cccc13)C(=O)N(OS(=O)(=O)CC13CCC(CC1=O)C3(C)C)C2=O ; CCCCC(=O)OCCSc1ccc2c3c(cccc13)C(=O)N(OS(=O)(=O)CC13CCC(CC1=O)C3(C)C)C2=O]

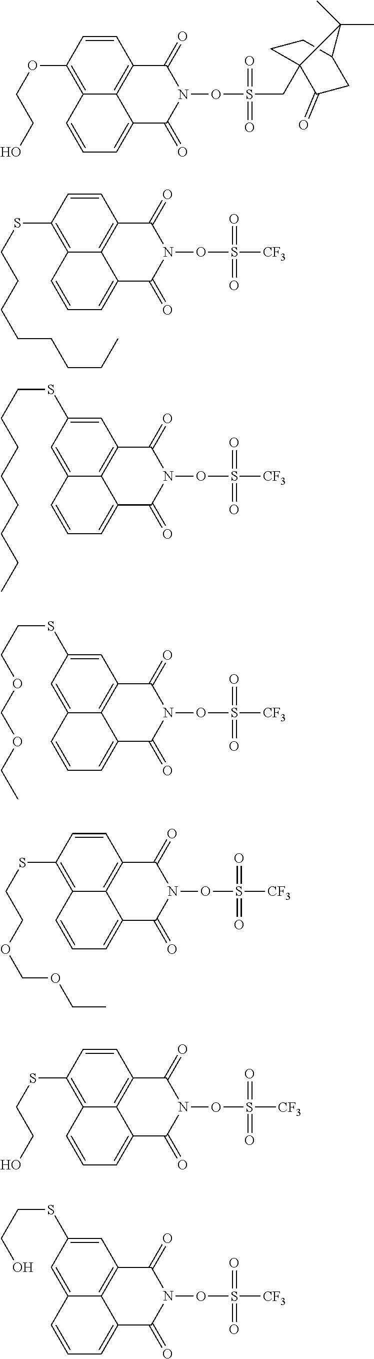

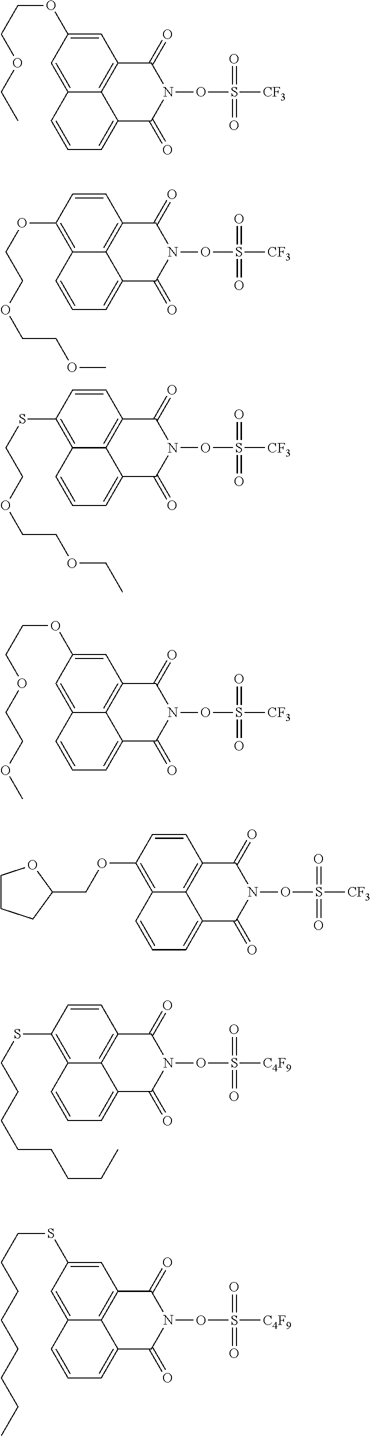

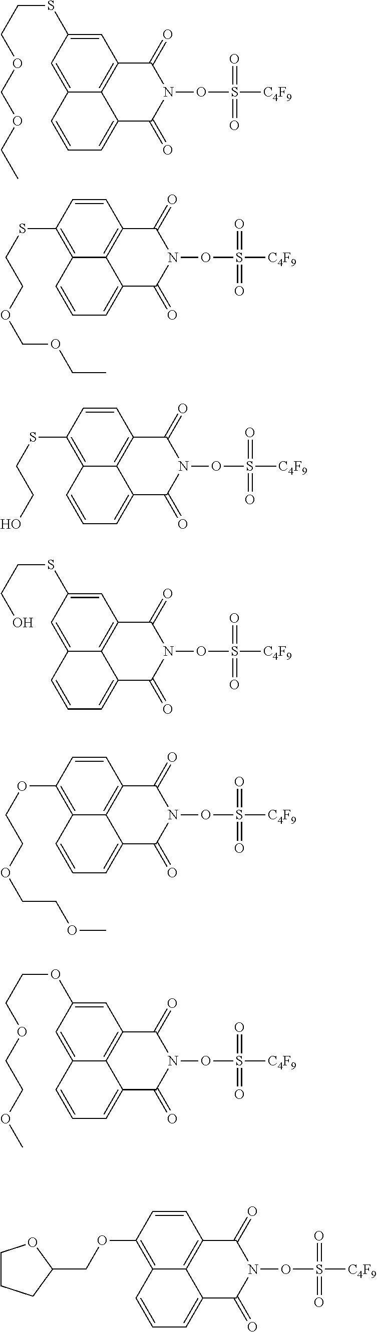

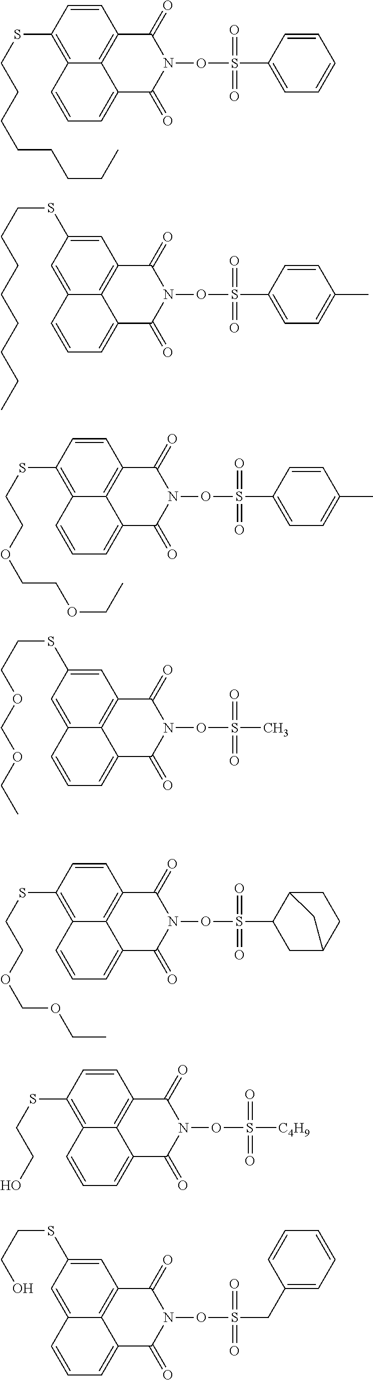

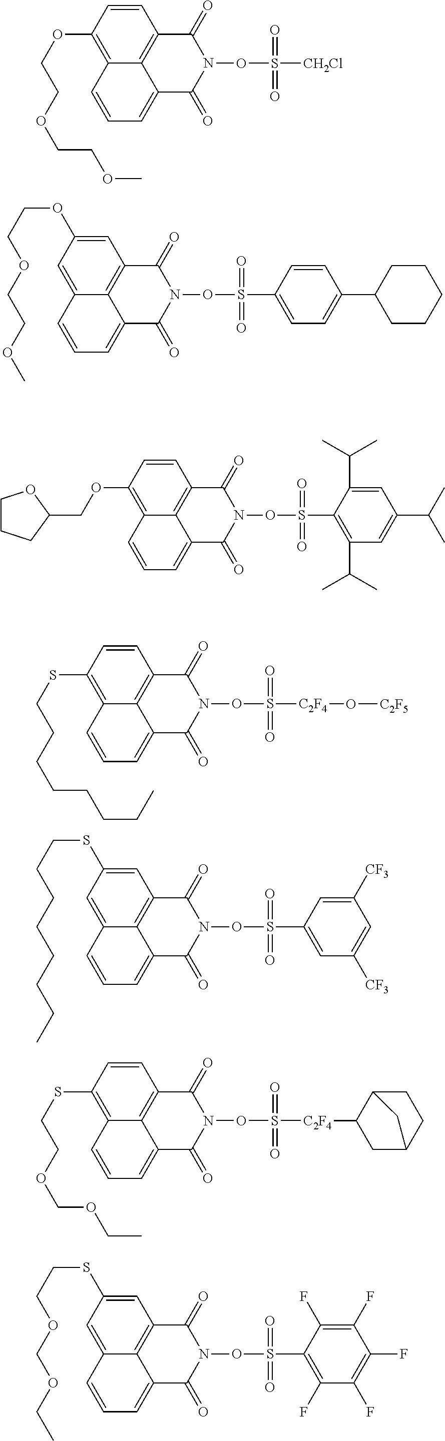

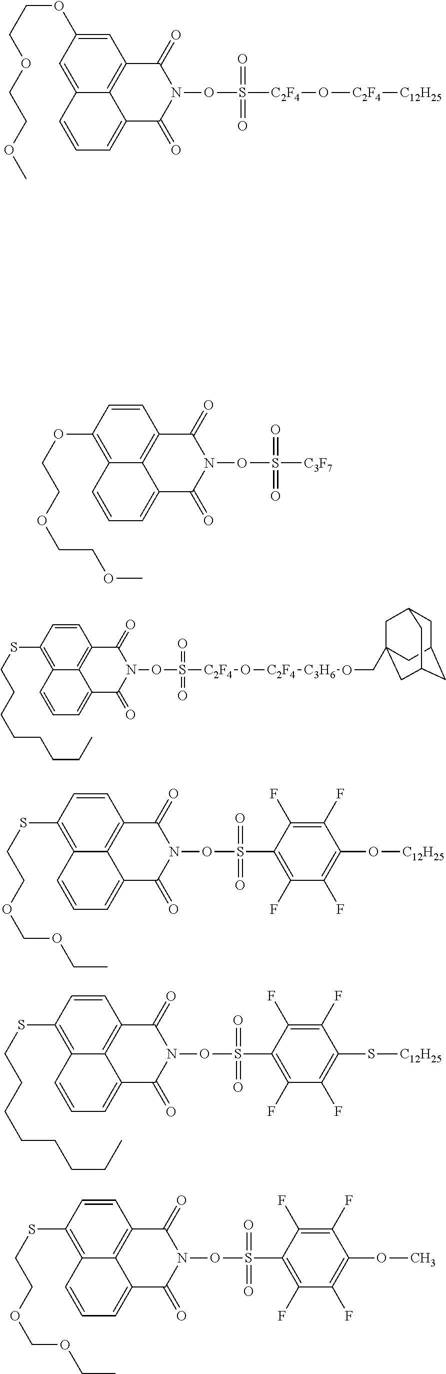

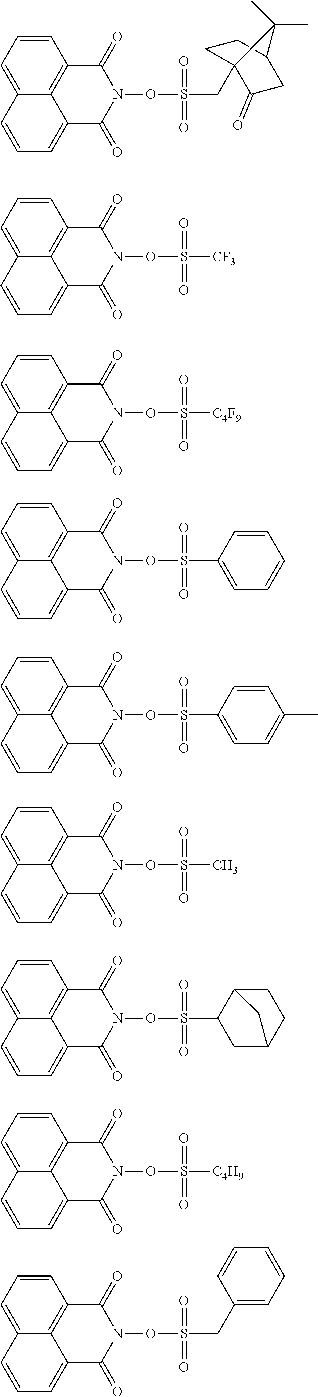

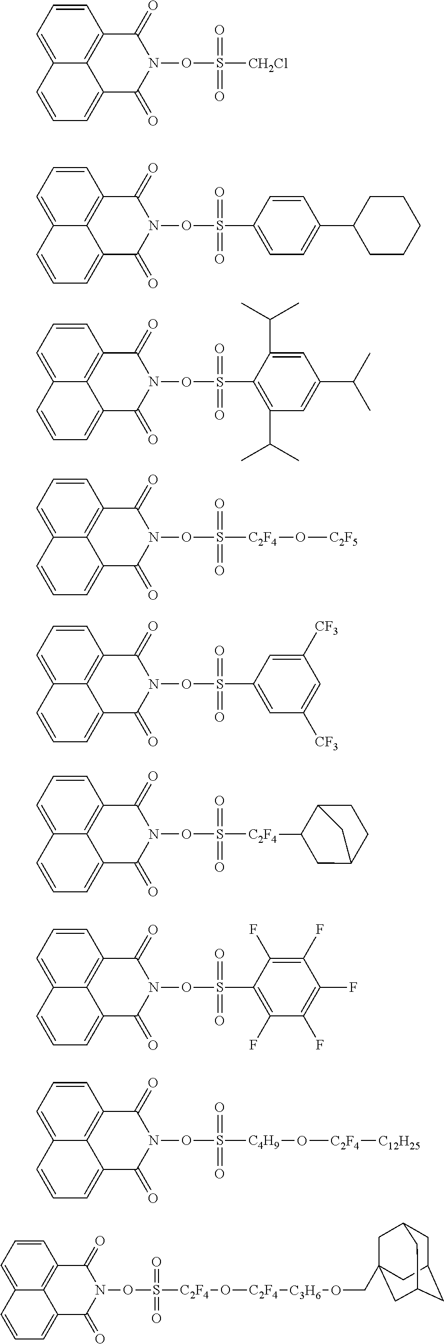

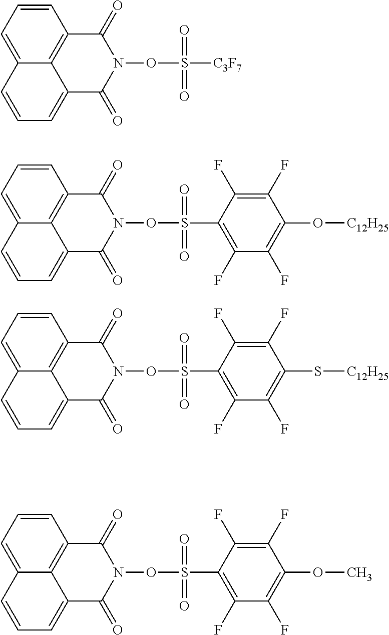

As the acid generator (A), a naphthalic acid derivative represented by the formula (a22) below is also preferred.

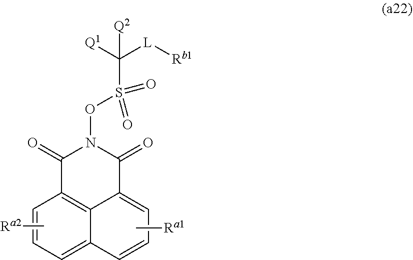

In the formula (a22), R^{b1} is a hydrocarbon group having 1 or more and 30 or less carbon atoms. When the hydrocarbon group as R^{b1} includes at least one methylene group, at least part of the methylene group may be substituted by a group selected from the group consisting of —O—, —S—, —CO—, —CO—O—, —SO—, —SO₂—, —CR^{b4}R^{b5}—, and —NR^{b6}—. When the hydrocarbon group as R^{b1} includes a hydrocarbon ring, at least one of the carbon atoms constituting the hydrocarbon ring may be substituted by a heteroatom selected from the group consisting of N, O, P, S and Se, or an atomic group including this heteroatom. R^{b4} and R^{b5} are each independently a hydrogen atom or halogen atom, and at least one of R^{b4} and R^{b5} is a halogen atom. R^{b6} is a hydrogen atom or a hydrocarbon group having 1 or more and 6 or less carbon atoms. R^{a1} and R^{2a} are each independently a hydrogen atom, an aliphatic hydrocarbon group having 1 or more and 20 or less carbon atoms which may have a substituent, an aromatic group having 5 or more and 20 or less annular atoms which may have a substituent, or a group represented by —R^{a3}—R^{a4}. R^{a1} and R^{a2} are not simultaneously hydrogen atoms. When the aliphatic hydrocarbon group as Rai or R^{a2} includes at least one methylene group, at least part of the methylene group may be substituted by a group selected from the group consisting of —O—, —S—, —CO—, —CO—O—, —SO—, —SO₂—, and —NR^{a5}. R^{a5} is a hydrogen atom, or a hydrocarbon group having 1 or more and 6 or less carbon atoms. R^{a3} is a methylene group, —O—, —CO—, —CO—O—, —SO—, —SO₂—, or —NR^{a6}—. R^{a6} is a hydrogen atom or a hydrocarbon group having 1 or more and 6 or less carbon atoms. R^{a4} is an aromatic group having 5 or more and 20 or less annular atoms which may have a substituent, a perfluoroalkyl group having 1 or more and 6 or less carbon atoms, an aralkyl group having 7 or more and 20 or less carbon atoms which may have a substituent, or a heteroarylalkyl group including an aromatic heterocyclic group having 5 or more and 20 or less annular atoms which may have a substituent. Q¹ and Q² are each independently a fluorine atom, or a perfluoroalkyl group having 1 or more and 6 or less carbon atoms. L is an ester bond.

In the formula (a22), the aliphatic hydrocarbon group having 1 or more and 20 or less carbon atoms as R^{a1} and R^{a2} may be linear, may be a branched chain, may be cyclic, or may be a combination of these structures. An alkyl group is preferable as the aliphatic hydrocarbon group. Suitable specific examples of the alkyl group include methyl group, ethyl group, n-propyl group, isopropyl group, n-butyl group, isobutyl group, sec-butyl group, tert-butyl group, n-pentyl group, n-hexyl group, n-heptyl group, n-octyl group, 2-ethylhexyl group, n-nonyl group and n-decyl group. As the substituent which may be possessed by the aliphatic hydrocarbon group having 1 or more and 20 or less carbon atoms as R^{a1} and R^{a2}, hydroxyl group, mercapto group, amino group, halogen atom, oxygen atom, nitro group, cyano group, etc. can be exemplified. The number of substituents is arbitrary. As the aliphatic hydrocarbon group having 1 or more and 20 or less carbon atoms and having a substituent as R^{a1} and R^{a2}, for example, a perfluoroalkyl group having 1 or more and 6 or less carbon atoms can be exemplified. Specific examples thereof include CF₃—, CF₃CF₂—, (CF₃)₂CF—, CF₃CF₂CF₂—, CF₃CF₂CF₂CF₂—, (CF₃)₂CFCF₂—, CF₃CF₂ (CF₃)CF— and (CF₃)₃C—.

In the formula (a22), the aromatic group having 5 or more and 20 or less annular atoms which may have a substituent as R^{a1} and R^{a2} may be an aromatic hydrocarbon group, or an aromatic heterocyclic group. As the aromatic group, an aryl group such as a phenyl group and a naphthyl group, and a heteroaryl group such as a furyl group and thienyl group can be exemplified. The substituent which may be possessed by the aromatic group having 5 or more and 20 or less annular atoms is the same as the substituent which may possessed by the aliphatic hydrocarbon group having 1 or more and 20 or less carbon atoms having a substituent as R^{a1} and R^{a2},

In the formula (a22), the aromatic group having 5 or more and 20 or less annular atoms which may have a substituent as R^{a4} is same as the aromatic group having 5 or more and 20 or less annular atoms which may have a substituent explained for R^{a1} and R^{a2}. In the formula (a22), the perfluoroalkyl group having 1 or more and 6 or less carbon atoms as R^{a4} is same as the perfluoroalkyl group having 1 or more and 6 or less carbon atoms explained as R^{a1} and R^{a2}. In the formula (a22), Specific examples of the aralkyl group having 7 or more and 20 or less carbon atoms which may have a substituent as R^{a4} include benzyl group, phenethyl group, α-naphthylmethyl group, β-naphthylmethyl group, 2-α-naphthylethyl group, 2-β-naphthylethyl group, and the like. In the formula (a22), a heteroarylalkyl group is a group in which part of the carbon atoms constituting the aromatic hydrocarbon ring in the arylalkyl group is substituted by a heteroatom such as N, O, S, etc. Specific examples of the heteroarylalkyl group including an aromatic heterocyclic group having 5 or more and 20 or less annular atoms which may have a substituent as R^{a4} include pyridine-2-ylmethyl group, pyridine-3-ylmethyl group, pyridine-4-ylmethyl group, and the like.

In the formula (a22), the hydrocarbon group having 1 or more and 6 or less carbon atoms as R^{a5} may be an aliphatic hydrocarbon group, aromatic hydrocarbon group, or a combination of these. The aliphatic hydrocarbon group may be linear, may be a branched chain, may be cyclic, or may be a combination of these structures. As the aliphatic hydrocarbon group, alkyl groups such as a methyl group, an ethyl group, an n-propyl group, an isopropyl group, an n-butyl group, an isobutyl group, a sec-butyl group, a tert-butyl group, an n-pentyl group and an n-hexyl group can be exemplified. As the aromatic hydrocarbon group, a phenyl group can be exemplified.

In the formula (a22), the hydrocarbon group having 1 or more and 6 or less carbon atoms as R^{a6} is same as the hydrocarbon groups having 1 or more and 6 or less carbon atoms explained for R^{a5}.

In the formula (a22), the hydrocarbon group having 1 or more and 30 or less carbon atoms as R^{b1} may be an aliphatic hydrocarbon group, aromatic hydrocarbon group, or a combination of these. The aliphatic hydrocarbon group may be linear, may be a branched chain, may be cyclic, or may be a combination of these structures. As the aliphatic hydrocarbon group, a linear aliphatic hydrocarbon group such as methyl group, ethyl group, n-propyl group, isopropyl group, n-butyl group, isobutyl group, sec-butyl group, tert-butyl group, n-pentyl group and n-hexyl group; and cyclic aliphatic hydrocarbon group (hydrocarbon ring) such as cyclopropyl group, cyclobutyl group, cyclopentyl group, cyclohexyl group, adamantyl group and norbornyl group can be exemplified. As the aliphatic hydrocarbon group, phenyl group and naphthyl group can be exemplified. As a group in which an aliphatic hydrocarbon group and aromatic hydrocarbon group are combined, benzyl group, phenethyl group and furylmethyl group can be exemplified. When the hydrocarbon group as R^{b1} includes a hydrocarbon ring, examples of an atomic group including a heteroatom substituting at least one of the carbon atoms constituting the hydrocarbon ring include —CO—, —CO—O—, —SO—, —SO₂—, —SO₂—O—, and —P(═O)—(OR^{b7})₃. R^{b7} is a hydrocarbon group having 1 or more and 6 or less carbon atoms, and is same as the hydrocarbon group having 1 or more and 6 or less carbon atoms explained for R^{a5}.

In the formula (a22), specific examples of the halogen atom as R^{b4} and R^{b5} include a chlorine atom, a fluorine atom, a bromine atom and an iodine atom.

In the formula (a22), the hydrocarbon group having 1 or more and 6 or less carbon atoms as R^{b6} is same as the hydrocarbon group having 1 or more and 6 or less carbon atoms explained as R^{a5} in the formula (a22)

In the formula (a22), the perfluoroalkyl group having 1 or more and 6 or less carbon atoms as Q¹ and Q² is same as the perfluoroalkyl group having 1 or more and 6 or less carbon atoms explained as R^{a1} and R^{a2} in the formula (a22).

In the compound represented by the formula (a22), the orientation of the ester bond as L is not particularly limited, and may be either of —CO—O— and —O—CO—.

The compound represented by the formula (a22) is preferably a compound represented by the following formula (a22-1).

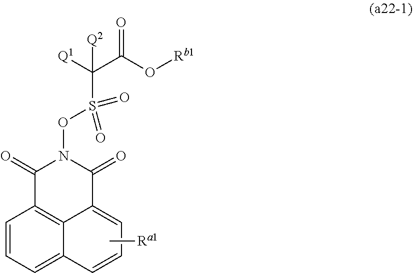

R^{b1}, R^{a1}, Q¹ and Q² in the formula (a22-1) are same as those in the formula (a22).

When the R^{a1} in the formula (a22-1) is an aliphatic hydrocarbon group having 1 or more and 20 or less carbon atoms which may have a substituent, and when the aliphatic hydrocarbon group as R^{a1} includes at least one methylene group, a compound represented by the formula (a22-1) in which at least part of the methylene group may be substituted by a group selected from the group consisting of —O—, —S—, —CO—, —CO—O—, —SO—, —SO₂— and —NR^{a5}— is preferable.

The compound represented by the formula (a22) can be produced by a production method of the N-organosulfonyloxy compound below. The production method of the N-organosulfonyloxy compound which can produce the compound represented by the formula (a22) is a production method of a N-organosulfonyloxy compound, including a step of reacting the N-hydroxy compound (a′) and sulfonic acid fluoride compound (b′) under the presence of the basic compound (d′), characterized by a silylating agent (c′) being present in the system upon reacting the N-hydroxy compound (a′) and sulfonic acid fluoride compound (b′), the sulfonic acid fluoride compound (b′) being represented by the formula (b1-1) below, the silylating agent (c′) being able to convert a hydroxy group on a nitrogen atom possessed by the N-hydroxy compound (a′) into a silyloxy group represented by the Formula (ac1) below.

—O—Si(R^{c1})₃ (ac1)

(In the formula (ac1), R^{c1} are each independently a hydrocarbon group having 1 or more and 10 or less carbon atoms.)

R^{b1}-L-CQ¹Q²-SO₂—F (b1-1)

(In the formula (b1-1), R^{b1}, L, Q¹ and Q² are each same as those in the above formula (a22).)

In addition, the production method of the N-organosulfonyloxy compound which can produce the compound represented by the formula (a22) is a production method of N-organosulfonyloxy compound including: a silylation step of silylating a N-hydroxy compound (a′) by a silylating agent (c′); and a condensation step of condensing the silylation product of the N-hydroxy compound (a′) generated in the silylation step, with a sulfonic acid fluoride compound (b′) under the presence of a basic compound (d′), in which the sulfonic acid fluoride (b′) is represented by the above formula (b1-1), the silylating agent can convert a hydroxy group on a nitrogen atom possessed by the N-hydroxy compound (a′) to a silyloxy group represented by the above formula (ac1).

The N-hydroxy compound (a′) is a compound represented by the formula (a22-2) below.

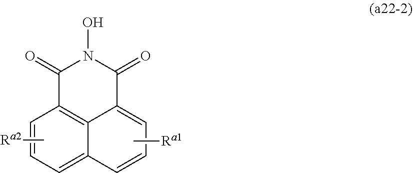

R^{a1} and R^{a2} in the formula (a22-2) are same as those in the above formula (a22).

The N-hydroxy compound (a′) can be synthesized by a known method such as that disclosed in the pamphlet of PCT International Publication No. WO2014/084269 or Japanese Unexamined Patent Application (Translation of PCT Publication), Publication No. 2017-535595, for example. For example, the compound represented by the formula (a22-1) in which R^{a2} is a hydrogen atom can be synthesized by converting the bromo group on the naphthalic anhydride to Rai, by the reaction shown in the following formula with a commercially available bromide as the starting material, and then forming a N-hydroxyimide by action of a hydroxylamine compound such as hydroxylamine hydrochloride on the acid anhydride group. In addition, a commercial product may be used as the N-hydroxy compound (a′).

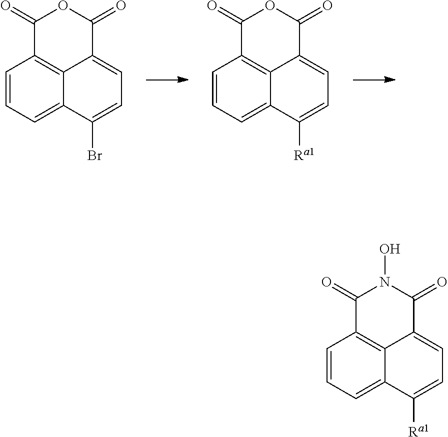

The sulfonic acid fluoride compound (b′) can be synthesized by a known method. For example, the compound of (b1-1) in which Q¹ and Q² are fluorine atoms can be synthesized by the reaction represented by the following formula. In addition, a commercial product may be used as the sulfonic acid fluoride compound (b′).

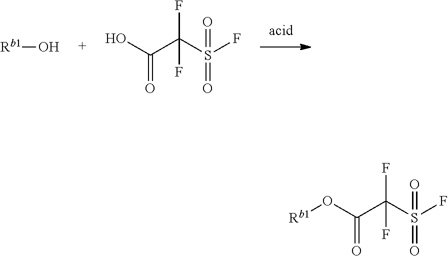

In the formula (ac1), the hydrocarbon group having 1 or more and 10 or less carbon atoms as R^{c1} may be an aliphatic hydrocarbon group, aromatic hydrocarbon group, or a combination of these. The aliphatic hydrocarbon group may be linear, may be a branched chain, may be cyclic, or may be a combination of these structures. Examples of the aliphatic hydrocarbon group include an alkyl group such as methyl group, ethyl group, n-propyl group, isopropyl group, n-butyl group, isobutyl group, sec-butyl group, tert-butyl group, n-pentyl group, n-hexyl group, n-heptyl group, n-octyl group, 2-ethylhexyl group, n-nonyl group and n-decyl group. Examples of the aromatic hydrocarbon group include a phenyl group and a naphthyl group.

As the silylating agent (c′), a compound represented by the formula (c′₁) below can be exemplified.

X—Si(R^{c1})₃ (c′1)

(In the formula (c′1), R^{c1} is the same as R^{c1} in the formula (ac1), and X is a halogen atom.)

As specific examples of the halogen atom as X in the formula (c′₁), a chlorine atom, fluorine atom, bromine atom and iodine atom can be exemplified.

As specific examples of the silylating agent (c′), trimethylsilyl chloride, trimethylsilyl fluoride, trimethylsilyl bromide, t-butyldimethylsilyl chloride, ethyldimethylsilyl chloride, and isopropyldimethylsilyl chloride can be exemplified.

The basic compound (d′) may be an organic base or an inorganic base. As the organic base, for example, a nitrogen-containing basic compound can be exemplified, and as specific examples, amines such as methylamine, ethylamine, n-propylamine, isopropylamine, n-butylamine, dimethylamine, diethylamine, di-n-propylamine, diisopropylamine, di-n-butylamine, trimethylamine, triethylamine, methyldiethylamine, N-ethyldiisopropylamine, tri-n-propylamine, triisopropylamine, monoethanolamine, diethanolamine and triethanolamine; cyclic basic compounds such as pyrrole, piperidine, 1,8-diazabicyclo[5,4,0]-7-undecene, and 1,5-diazabicyclo[4,3,0]-5-nonane; quaternary ammonium salts such as tetramethylammonium hydroxide (TMAH), tetraethylammonium hydroxide, tetrapropylammonium hydroxide (TPAH), tetrabutylammonium hydroxide, methyltripropylammonium hydroxide, methyltributylammonium hydroxide, benzyltriethylammonium hydroxide and trimethyl(2-hydroxyethyl)ammonium hydroxide; etc. can be exemplified. As the inorganic base, for example, metal hydroxides, metal hydrogen carbonates and metal bicarbonates can be exemplified. Specific examples of the inorganic base include metal hydroxides such as lithium hydroxide, potassium hydroxide, sodium hydroxide, rubidium hydroxide, cesium hydroxide, magnesium hydroxide, calcium hydroxide, strontium hydroxide and barium hydroxide; metal hydrogen carbonates such as lithium carbonate, potassium carbonate, sodium carbonate, rubidium carbonate, cesium carbonate, magnesium carbonate, calcium carbonate, strontium carbonate and barium carbonate; metal bicarbonates such as lithium hydrogencarbonate, potassium bicarbonate, sodium bicarbonate, rubidium hydrogencarbonate and cesium hydrogencarbonate; and the like.

The production method of the N-organosulfonyloxy compound causes such an N-hydroxy compound (a′) and sulfonic acid fluoride compound (b′) to react under the presence of the silylating agent (c′) and basic compound (d′). In this way, upon reacting the N-hydroxy compound (a′) and sulfonic acid fluoride compound (b′) under the presence of the basic compound (d′), it is possible to produce the N-organosulfonyloxy compound efficiently, by having the silylating agent (c′) present. For example, it is possible to obtain at least 65% N-organosulfonyloxy compound relative to the raw materials of the N-hydroxy compound (a′) and sulfonic acid fluoride compound (b′).

A N-organosulfonyloxy compound having a structure in which a group in which a hydrogen atom of the hydroxy group bonded to the nitrogen atom of the N-hydroxy compound (a′) is eliminated, and R^{b1}—SO₂— derived from the sulfonic acid fluoride compound (b′) are bonded is obtained by the production method of the N-organosulfonyloxy compound.

In the production method of the N-organosulfonyloxy compound, upon reacting the N-hydroxy compound (a′) and sulfonic acid fluoride compound (b′) under the presence of the basic compound (d′), so long as the silylating agent (c′) is present in the system, it may simultaneously mix the N-hydroxy compound (a′), sulfonic acid fluoride compound (b′), silylating agent (c′) and basic compound (d′), or may add the sulfonic acid fluoride compound (b′) and basic compound (d′), after partial reaction between the N-hydroxy compound (a′) and silylating agent (c′), or after completing the reaction between the N-hydroxy compound (a′) and silylating agent (c′).

When reacting such an N-organosulfonyloxy compound (a′) and sulfonic acid fluoride compound (b′) under the presence of the silylating agent (c′) and basic compound (d′), the N-organosulfonyloxy compound (a′) is silylated by the silylating agent (c′), and the hydroxy group on the nitrogen atom is converted to the silyloxy group represented by the above Formula (ac1) (Step 1: silylation step). Then, the silylated product of the N-organosulfonyloxy compound (a′) generated in the silylation step condenses with the sulfonic acid fluoride compound (b′) affected by the basic compound (d′) (Step 2: condensation step). The N-organosulfonyloxy compound is thereby obtained.

As an example of the production method of N-organosulfonyloxy compound, below shows a reaction formula in the case of using the compound represented by the above Formula (a22-2) as the N-organosulfonyloxy compound (a′), a compound of the above Formula (b1-1) in which Q¹ and Q² are fluorine atoms as the sulfonic acid fluoride compound (b′), trimethylsilyl chloride as the silylating agent (c′), and triethylamine as the basic compound (d′). It should be noted that what is shown below is not the reaction mechanism which has been analytically confirmed, but rather the reaction mechanism assumed from the raw materials and their behavior during reaction.

### Step-1

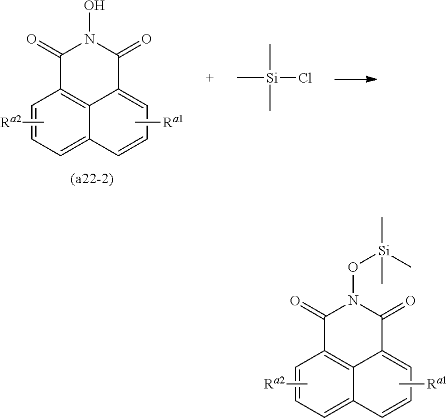

### Step-2

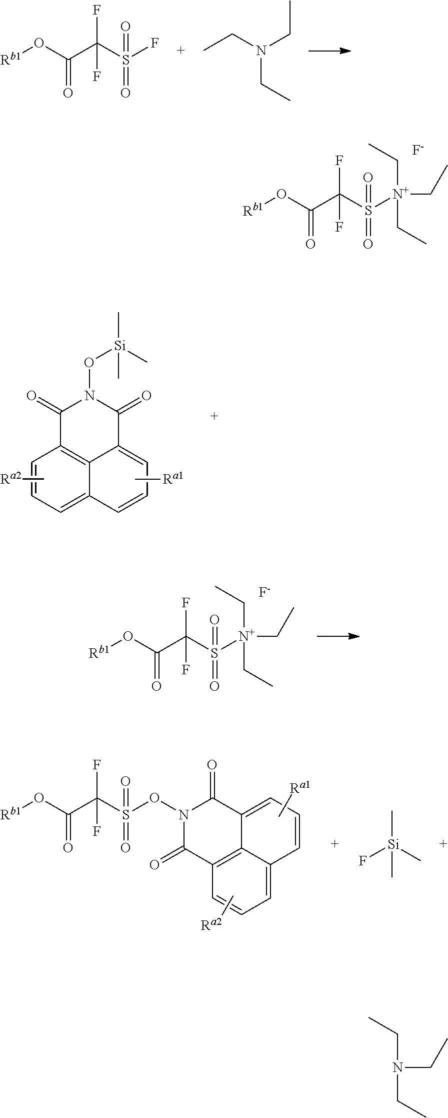

As organic solvents which can be used in reaction, for example, esters such as ethyl acetate, butyl acetate and cellosolve acetate; ketones such as acetone, methylethyl ketone, isobutyl ketone and methylisobutyl ketone; esters such as ethyl acetate, butyl acetate and diethyl malonate; amides such as N-methylpyrrolidone and N,N-dimethylformamide; ethers such as diethyl ether, ethylcyclopentyl ether, tetrahydrofuran and dioxane; aromatic hydrocarbons such as toluene and xylene; aliphatic hydrocarbons such as chloroform, dicyclomethane, methylene chloride and ethylene chloride; nitrile-based solvents such as acetonitrile and propionitrile; dimethyl sulfoxide; dimethyl sulfoamide; etc. can be exemplified. The organic solvent used may adopt one type of solvent, or may adopt any combination of two or more types. The reaction temperatures which can be adopted, for example, are a range of 10° C. to 200° C., preferably a range of 0° C. to 150° C., and more preferably 5° C. to 120° C. The reaction times which can be adopted, for example, are 5 minutes to 20 hours, 10 minutes to 15 hours, and 30 minutes to 12 hours.

It is preferable to use excess of each of the sulfonic acid fluoride compound (b′), silylating agent (c′), and basic compound (d′) relative to the N-organosulfonyloxy compound (a′). For example, it is preferable to use 1.1 moles to 2.5 moles of the sulfonic acid fluoride compound (b′), 1.1 moles to 2.5 moles of the silylating agent (c′) and 1.1 moles to 2.5 moles of the basic compound (d′) relative to 1.0 mole of the N-organosulfonyloxy compound (a′).

This acid generator (A) may be used alone, or two or more types may be used in combination. Furthermore, the content of the acid generator (A) is adjusted to preferably 0.1% by mass or more and 10% by mass or less, more preferably 0.2% by mass or more and 6% by mass or less, and particularly preferably 0.5% by mass or more and 3% by mass or less, relative to the total mass of the solid component of the first photosensitive composition. When the amount of the acid generator (A) used is adjusted to the range mentioned above, it is easy to prepare the first photosensitive composition which is a uniform solution having satisfactory sensitivity and excellent storage stability.

### {Resin (B)}

A resin (B) whose solubility in alkali increases under an action of acid includes an acrylic resin (B1a) including a constituent unit (bL1) derived form a crosslinkable monomer represented by formula (BL1):

R^{B1}—O—R^{B3}—O—R^{B2} (BL1)

in which, in the formula (BL1), R^{B1} and R^{B2} are each independently a (meth)acryloyl group or a vinylphenyl group, R^{B3} is a divalent bridging group, and at least one of two O—R^{B3} bonds in the formula (BL1) generates a carboxy group or a phenolic hydroxy group by cleavage by an action of acid. A molar ratio of the constituent unit (bL1) is 1% by mole or more and 10% by mole or less relative to all constituent units of the acrylic resin (B1a). In addition, a calculated value of glass transition temperature of hypothetical non-crosslinked acrylic resin which the constituent unit (bL1) is excluded from the acrylic resin (B1a) is 90° C. or higher and 120° C. or lower.

The glass transition temperature of the hypothetical non-crosslinked acrylic resin can be calculated according to Bicerano's method (the method of Bicerano) shown in Prediction of polymer properties, Marcel Dekker Inc, New York (1993).

The glass transition temperature of the hypothetical non-crosslinked acrylic resin calculated according to the above method can be adjusted by adjusting ratios of constituent units constituting the acrylic resin (B1a). In particular, the glass transition temperature of the hypothetical non-crosslinked acrylic resin calculated according to the above method can be adjusted in the range of 90° C. or higher and 120° C. or lower by adjusting a ratio of a constituent unit that increase the glass transition temperature. As a constituent unit that increase the glass transition temperature, a constituent unit (bL3) described below that is a constituent unit derived from a (meth)acrylate (BL3) including an alicyclic hydrocarbon group or an aromatic group can be exemplified.

By inclusion of the constituent unit (bL1) derived from the crosslinkable monomer at a ratio within the above predetermined range relative to all constituent units of the acrylic resin (B1a), the first photosensitive composition is given good developability and resolution property. In addition, by inclusion of the constituent unit (bL1) at a ratio within the above predetermined range in the acrylic resin (B1a), and the calculated value of the glass transition temperature of the hypothetical non-crosslinked acrylic resin within the above range, a patterned resist film with an excellent balance of flexibility and hardness, as well as excellent heat resistance can be formed.

Therefore, a resist film having a nonresist portion with rectangular cross-sectional shape and high resistance to a plating liquid can be formed by using the above-described first photosensitive composition.

The resin (B) may include other resin that is a resin whose solubility in alkali increases under an action of acid other than the acrylic resin (B1a) with the acrylic resin (B1a) as long as the objects of the present invention are not impaired. As other resin as the resin (B), an acrylic resin (B1A) that is an acrylic resin other than the acrylic resin (B1a), a novolak resin (B2), and a polyhydroxystyrene resin (B3) are preferred. The resin (B) may include two or more above-described other resins in combination. Hereinafter, above-described various resins that can be used as the resin (B) will be described.

### [Acrylic Resin (B1a)]

The first photosensitive composition includes the acrylic resin (B1a) as the resin (B). It should be noted that a resin including one or more unit selected from the group consisting of a constituent unit derived from (meth)acrylic acid ester ((meth)acrylate), a constituent unit derived from (meth)acrylamide which may have a substituent on a nitrogen atom constituting an amide group, and (meth)acrylic acid is defined as “acrylic resin”, in the present specification and

(Constituent Unit (bL1))

As mentioned above, the acrylic resin (B1a) includes a constituent unit (bL1) derived from a crosslinkable monomer represented by the following formula (BL1):

R^{B1}—O—R^{B3}—O—R^{B2} (BL1)

in which, in the formula (BL1), R^{B1} and R^{B2} are each independently a (meth)acryloyl group or a vinylphenyl group, R^{B3} is a divalent bridging group, and at least one of two O—R^{B3} bonds in the formula (BL1) generates a carboxy group or a phenolic hydroxy group by cleavage by an action of acid.

As mentioned above, in the formula (BL1), R^{B1} and R^{B2} are each independently the (meth)acryloyl group or the vinylphenyl group. The vinylphenyl group may be any of o-vinylphenyl group, m-vinylphenyl group, and p-vinylphenyl group. The vinylphenyl group is preferably the p-vinylphenyl group.

In the formula (BL1), R^{B3} is the divalent bridging group. It should be noted that at least one of two O—R^{B3} bonds in the formula (BL1) generates a carboxy group or a phenolic hydroxy group by cleavage by an action of acid.

As R^{B3} that meets above requirements, a group represented by the formula (BL1-A), a group represented by the formula (BL1-B), a group represented by the formula (BL1-C), and a group represented by the formula (BL1-D) are preferred.

—CR^{B4}R^{B5}—R^{B8}—CR^{B6}R^{B7}— (BL1-A)

(In the formula (BL1-A), R^{B4}, R^{B5}, R^{B6}, and R^{B7} are each independently an alkyl group having 1 or more and 4 or less carbon atoms, R^{B8} is a single bond or a divalent organic group, R^{B4} or R^{B5} may form a ring with R^{B8}, R^{B6} or R^{B7} may form a ring with R^{B8}, and a carbon atom to which R^{B4} and R^{B5} bond, and a carbon atom to which R^{B6} and R^{B7} bond are both tertiary carbon atoms having sp³ hybrid orbitals.)

Specific examples of the alkyl group as R^{B4}, R^{B5}, R^{B6}, and R^{B7} include methyl group, ethyl group, n-propyl group, isopropyl group, n-butyl group, isobutyl group, sec-butyl group and tert-butyl group. Among these, the methyl group and the ethyl group are preferred, and the methyl group is more preferred. It is most preferable that all of R^{B4}, R^{B5}, R^{B6}, and R^{B7} are the methyl groups.

The divalent organic group as R^{B8} may include a hetero atom such as O, N, S, P, B, Si, and halogen atom as long as a carbon atom to which R^{B4} and R^{B5} bond, and a carbon atom to which R^{B6} and R^{B7} bond are both tertiary carbon atoms having sp³ hybrid orbitals. R^{B8} is preferably a hydrocarbon group having 1 or more and 10 or less carbon atoms. The hydrocarbon group is preferably an aliphatic hydrocarbon group, and more preferably an alkylene group. Specific examples of the alkylene group include methylene group, ethane-1,2-diyl group (ethylene group), ethane-1,1-diyl group, propane-1,3-diyl group, butane-1,4-diyl group, pentane-1,5-diyl group, hexane-1,6-diyl group, heptane-1,7-diyl group, octane-1,8-diyl group, nonane-1,9-diyl group, and decane-1,10-diyl group. Among the alkylene groups as R^{B8}, the methylene group, the ethane-1,2-diyl group (ethylene group), the propane-1,3-diyl group, and the butane-1,4-diyl group are preferred, and the methylene group, the ethane-1,2-diyl group (ethylene group), and the propane-1,3-diyl group are more preferred.

In other words, as the group represented by the formula (BL1-A), groups represented by the following formulae (BL1-A-1) to (BL1-A-3) are preferred.

—C(CH₃)₂—CH₂—C(CH₃)₂— (BL1-A-1)

—C(CH₃)₂—CH₂CH₂—C(CH₃)₂— (BL1-A-2)

—C(CH₃)₂—CH₂CH₂CH₂—C(CH₃)₂— (BL1-A-3)

—CR^{B4}R^{B5}—R^{B9}— (BL1-B)

(In the formula (BL1-B), R^{B4} and R^{B5} are each independently an alkyl group having 1 or more and 4 or less carbon atoms, R^{B9} is a divalent organic group, R^{B4} or R^{B5} may form a ring with R^{B8}, and a carbon atom to which R^{B4} and R^{B5} bond is a tertiary carbon atom having an sp³ hybrid orbital.)

R^{B4} and R^{B5} in the formula (BL1-B) are the same as R^{B4} and R^{B5} in the formula (BL1-A). The divalent organic group as R^{B9} may include a hetero atom such as O, N, S, P, B, Si, and halogen atom as long as a carbon atom to which R^{B4} and R^{B5} bond is a tertiary carbon atom having sp³ hybrid orbital. R^{B9} is preferably a hydrocarbon group having 1 or more and 10 or less carbon atoms. Such hydrocarbon group is preferably an aliphatic hydrocarbon group, and more preferably an alkylene group. Specific examples of the alkylene group are the same as the specific examples explained for the alkylene group as R^{B8} in the formula (BL1-A).

As a group represented by the formula (BL1-B), groups represented by the following formulae (BL1-B-1) to (BL1-B-3) are preferred.

—C(CH₃)₂—CH₂— (BL1-B-1)

—C(CH₃)₂—CH₂CH₂— (BL1-B-2)

—C(CH₃)₂—CH₂CH₂— (BL1-B-3)

—CR^{B12}R^{B13}—O—R^{B10}—O—CR^{B14}R^{B15}— (BL1-C)

(In the formula (BL1-C), R^{B12}, R^{B13}, R^{B14}, and R^{B15} are each independently a hydrogen atom or an alkyl group having 1 or more and 4 or less carbon atoms, R^{B10} is a divalent organic group, two bonds possessed by R^{B10} respectively bond to a carbon atom constituting the organic group as R^{B10}.)

The alkyl group having 1 or more and 4 or less carbon atoms as R^{B12}, R^{B13}, R^{B14}, and R^{B15} in the formula (BL1-C) is the same as the alkyl group having 1 or more and 4 or less carbon atoms as R^{B4} and R^{B5} in the formula (BL1-A). Preferably, a group represented by —CR^{B12}R^{B13}— and a group represented by —CR^{B14}R^{B15}— are each independently —CH₂— and —C(CH₃)H—.

The divalent group as R^{B10} in the formula (BL1-C) may include a hetero atom such as O, N, S, P, B, Si, and halogen atom as long as the two bonds possessed by R^{B10} respectively bond to a carbon atom constituting the organic group as R^{B10}.

Suitable specific examples of R^{B10} in the formula (BL1-C) include following alkylene groups which may be interrupted by an ether bond and may be substituted with a hydroxy group:

—CH₂CH₂—;

—CH₂CH₂—O—CH₂CH₂—;

—CH₂CH₂—O—CH₂CH₂—O—CH₂CH₂—;

—(CH₂CH₂—O)_{nc}—CH₂CH₂—;

—CH₂C(CH₃)H—;

—CH₂C(CH₃)H—O—CH₂C(CH₃)H—;

—CH₂C(CH₃)H—O—CH₂C(CH₃)H—O—CH₂C(CH₃)H—;

—(CH₂C(CH₃)H—O)_{nc}—CH₂C(CH₃)H—;

—(CH₂)₃—;

—(CH₂)₄—;

—(CH₂)₅—;

—(CH₂)₆—;

—(CH₂)₈—;

—(CH₂)₁₀—;

—CH₂C(CH₃)₂CH₂—;

—CH₂C(CH₂CH₃)(CH₂OH)CH₂—; and

—CH₂C(CH₂OH)₂CH₂—.

In addition, other suitable examples of R^{B10} include p-phenylene group, m-phenylene group, o-phenylene group, naphthalene-1,4-diyl group, naphthalene-1,3-diyl group, naphthalene-1,2-diyl group, naphthalene-1,5-diyl group, naphthalene-1,6-diyl group, naphthalene-1,7-diyl group, naphthalene-1,8-diyl group, naphthalene-2,3-diyl group, naphthalene-2,6-diyl group, naphthalene-2,7-diyl group, biphenyl-4,4′-diyl group, biphenyl-3,3′-diyl group, biphenyl-2,2′-diyl group, biphenyl-3,4′-diyl group, biphenyl-2,3′-diyl group, and biphenyl-2,4′-diyl group.

Furthermore, divalent groups having the following structure and including a cyclic group are preferred as R^{B10}.

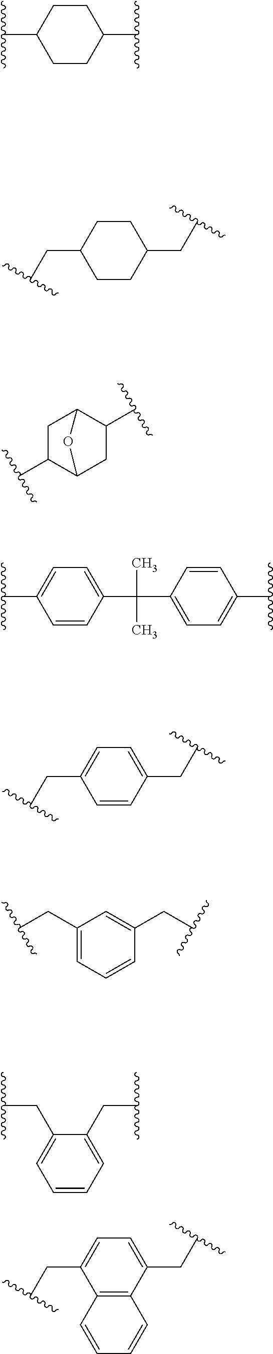

—CR^{B12}R^{B13}—O—R^{B11}— (BL1-D)

(In the formula (BL1-D), R^{B12} and R^{B13} are each independently a hydrogen atom or an alkyl group having 1 or more and 4 or less carbon atoms, R^{B10} is a divalent organic group, and two bonds possessed by R^{B10} respectively bond to a carbon atom constituting the organic group as R^{B10}.)

The alkyl group having 1 or more and 4 or less carbon atoms as R^{B12} and R^{B13} in the formula (BL1-D) is the same as the alkyl group having 1 or more and 4 or less carbon atoms as R^{B4} and R^{B5} in the formula (BL1-A). As groups represented by —CR^{B12}R^{B13}—, —CH₂— and —C(CH₃)H— are respectively preferred. The divalent organic group as R^{B11} in the formula (BL1-D) is the same as the divalent organic group as R^{B10} in the formula (BL1-C).

Among the group represented by the formula (BL1-A), the group represented by the formula (BL1-B), the group represented by the formula (BL1-C), and the group represented by the formula (BL1-D) described above, the group represented by the formula (BL1-A) is preferred, in view of ease of achieving good balance of a good shape of a patterned resist film and plating solution resistance of the resist film.

As mentioned above, a molar ratio of the constituent unit (bL1) is 1% by mole or more and 10% by mole or less relative to all constituent units of the acrylic resin (B1a). The molar ratio of the constituent unit (bL1) is preferably 1% by mole or more and 7% by mole or less, and more preferably 1% by mole or more and 5% by mole or less relative to all constituent units of the acrylic resin (B1a).

(Constituent unit (bL2) and constituent unit (bL3)) Preferably, the acrylic resin (B1a) further includes a constituent unit (bL2) derived from an alkyl (meth)acrylate (BL2) and a constituent unit (bL3) derived from a (meth)acrylate (BL3) including an alicyclic hydrocarbon group or an aromatic group. In the (meth)acrylate (BL2), an alkyl group optionally substituted with a hydroxy group or an alkoxy group and having 1 or more and 10 or less carbon atoms bonds to a (meth)acryloyloxy group, and a carbon atom which bonds to the (meth)acryloyloxy group does not correspond to a tertiary carbon atom having an sp³ hybrid orbital. In the (meth)acrylate (BL3) including the alicyclic hydrocarbon group or the aromatic group, the alicyclic hydrocarbon group or the aromatic group bonds to a (meth)acryloyloxy group, the alicyclic hydrocarbon group or the aromatic group may be substituted with one or more substituents selected from the group consisting of an alkyl group, an alkoxy group and a hydroxy group, and a carbon atom to which the (meth)acryloyloxy group bonds does not correspond to a tertiary carbon atom having an sp³ hybrid orbital.

Suitable examples of the alkyl (meth)acrylate (BL2) include alkyl (meth)acrylates such as methyl (meth)acrylate, ethyl (meth)acrylate, n-propyl (meth)acrylate, isopropyl (meth)acrylate, n-butyl (meth)acrylate, isobutyl (meth)acrylate, sec-butyl (meth)acrylate, n-pentyl (meth)acrylate, n-hexyl (meth)acrylate, n-heptyl (meth)acrylate, n-octyl (meth)acrylate, 2-ethylhexyl (meth)acrylate, n-nonyl (meth)acrylate, and n-decyl (meth)acrylate; hydroxyalkyl (meth)acrylates such as hydroxymethyl (meth)acrylate, 2-hydroxyethyl (meth)acrylate, (meth)acrylate, 3-hydroxypropyl (meth)acrylate, 4-hydroxybutyl (meth)acrylate, (meth)acrylate, 5-hydroxypentyl (meth)acrylate, 6-hydroxyhexyl (meth)acrylate, (meth)acrylate, 7-hydroxyheptyl (meth)acrylate, 8-hydroxyoctyl (meth)acrylate, (meth)acrylate, 9-hydroxynonyl (meth)acrylate, and 10-hydroxydecyl (meth)acrylate; alkoxyalkyl (meth)acrylates such as 2-methoxyethyl (meth)acrylate, (meth)acrylate, 3-methoxypropyl (meth)acrylate, 4-methoxybutyl (meth)acrylate, 5-methoxypentyl (meth)acrylate, 6-methoxyhexyl (meth)acrylate, (meth)acrylate, 7-methoxyheptyl (meth)acrylate, 8-methoxyoctyl (meth)acrylate, (meth)acrylate, 9-methoxynonyl (meth)acrylate, (meth)acrylate, 10-methoxydecyl (meth)acrylate, 2-ethoxyethyl (meth)acrylate, (meth)acrylate, 3-ethoxypropyl (meth)acrylate, 4-ethoxybutyl (meth)acrylate, (meth)acrylate, 5-ethoxypentyl (meth)acrylate, 6-ethoxyhexyl (meth)acrylate, (meth)acrylate, 7-ethoxyheptyl (meth)acrylate, 8-ethoxyoctyl (meth)acrylate, 9-ethoxynonyl (meth)acrylate, (meth)acrylate, and 10-ethoxydecyl (meth)acrylate.

Among these, methyl (meth)acrylate, ethyl (meth)acrylate, n-propyl (meth)acrylate, isopropyl (meth)acrylate, n-butyl (meth)acrylate, isobutyl (meth)acrylate, sec-butyl (meth)acrylate, hydroxymethyl (meth)acrylate, 2-hydroxyethyl (meth)acrylate, 3-hydroxypropyl 4-hydroxybutyl (meth)acrylate, 2-methoxyethyl (meth)acrylate, 3-methoxypropyl 4-methoxybutyl (meth)acrylate, 2-ethoxyethyl (meth)acrylate, 3-ethoxypropyl (meth)acrylate, and 4-ethoxybutyl(meth)acrylate are preferred, and methyl (meth)acrylate, ethyl (meth)acrylate, n-propyl (meth)acrylate, n-butyl (meth)acrylate, 2-hydroxyethyl (meth)acrylate, 3-hydroxypropyl (meth)acrylate, 4-hydroxybutyl (meth)acrylate, 2-methoxyethyl (meth)acrylate, 3-methoxypropyl (meth)acrylate, 4-methoxybutyl (meth)acrylate, 2-ethoxyethyl (meth)acrylate, 3-ethoxypropyl (meth)acrylate, and 4-ethoxybutyl (meth)acrylate are more preferred.

A molar ratio of the constituent unit (bL2) is preferably 0.1% by mole or more and 10% by mole or less, more preferably 0.5% by mole or more and 8% by mole or less, and even more preferably 1% by mole or more and 5% by mole or less relative to all constituent units of the acrylic resin (B1a). When the acrylic resin (B1a) includes the constituent unit (bL2) in such range, a resist film with excellent adhesion to a substrate is easily formed.

In the (meth)acrylate (BL3) including the alicyclic hydrocarbon group or the aromatic group, as the alicyclic hydrocarbon group bonding to (meth)acryloyl group, cycloalkyl groups such as cyclopentyl group, cyclohexyl group, cycloheptyl group and cyclooctyl group; and tricyclodecanyl group, adamantyl group, tetracyclododecanyl group, isobornyl group, norbornyl group, and the like are preferred in view easy industrial availability and the like. Examples of the aromatic group bonding to the (meth)acryloyl group in the (meth)acrylate (BL3) including the alicyclic hydrocarbon group or the aromatic group include phenyl group, naphthalene-1-yl group, naphthalene-2-yl group, o-phenylphenyl group, m-phenylphenyl group, p-phenylphenyl group, and the like.

In the (meth)acrylate (BL3) including the alicyclic hydrocarbon group or the aromatic group, the alicyclic hydrocarbon group or the aromatic group may be substituted with one or more substituents selected from the group consisting of an alkyl group, an alkoxy group and a hydroxy group. Numbers of carbon atoms of the alkyl group and the alkoxy group are not particularly limited. Numbers of carbon atoms of the alkyl group and the alkoxy group is preferably 1 or more and 4 or less. A number of substituents which the alicyclic hydrocarbon group or the aromatic group may have is not particularly limited. For example, a number of substituents is preferably 0 is more and 5 or less, more preferably 0 or more and 3 or less, and even more preferably 0 or more and 2 or less.

Suitable specific examples of the constituent unit (bL3) derived from the (meth)acrylate (BL3) including the alicyclic hydrocarbon group or the aromatic group include constituent units represented by the following formulae (bL3-1) to (bL3-9).

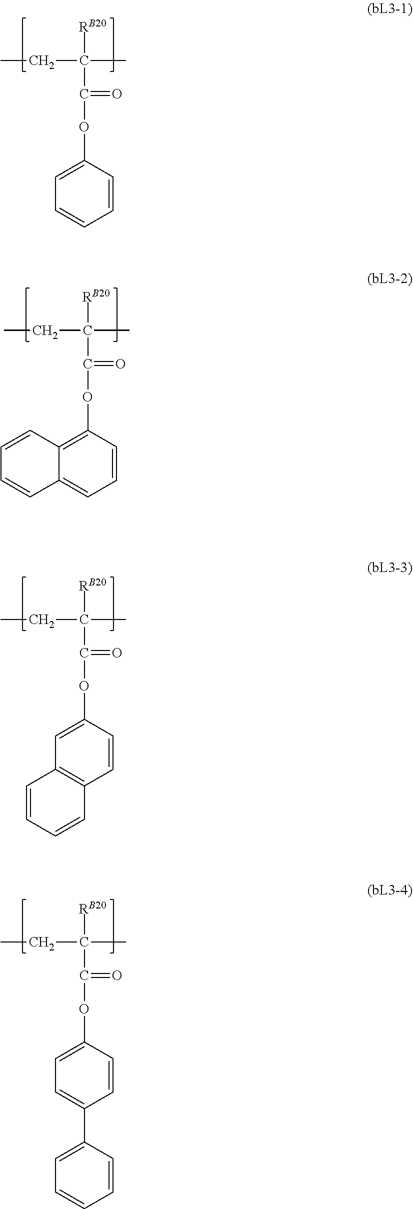

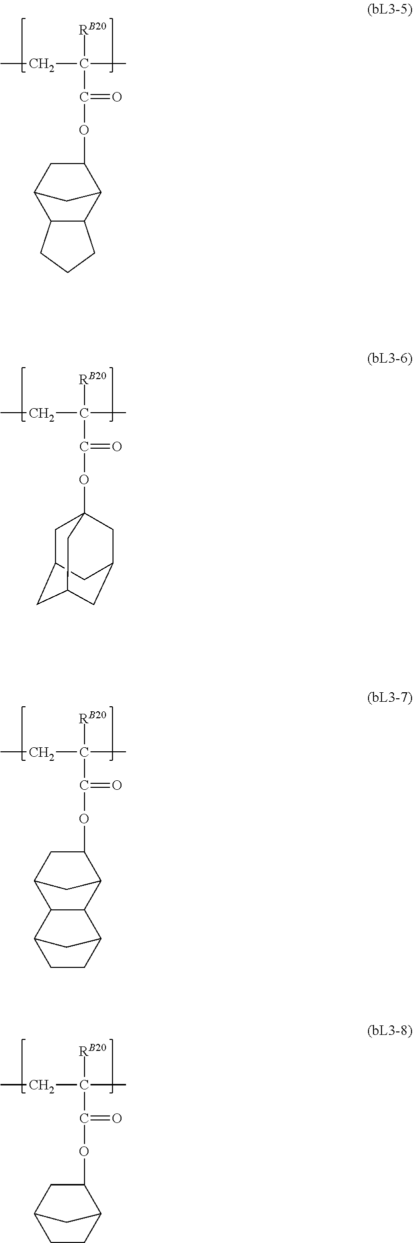

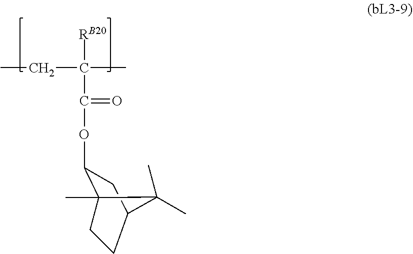

In the formulae (bL3-1) to (bL3-9), R^{B20} represents a hydrogen atom or a methyl group.

A molar ratio of the constituent unit (bL3) is preferably 25% by mole or more and 50% by mole or less, more preferably 27% by mole or more and 45% by mole or less, and even more preferably 30% by mole or more and 40% by mole or less relative to all constituent units of the acrylic resin (B1a). When the acrylic resin (B1a) includes the constituent unit (bL3) in such range, a resist film having high plating solution resistance is easily formed.

(Constituent Unit (bL4))

Preferably, the acrylic resin (B1a) includes a constituent unit (bL4) derived from, for example, an acrylic ester including an —SO₂-containing cyclic group or a lactone-containing cyclic group. In such a case, when a patterned resist film is formed, a patterned resist film having a preferable cross-sectional shape can be easily formed.

—SO₂-Containing Cyclic Group

Herein, the “—SO₂-containing cyclic group” refers to a cyclic group having a cyclic group containing a ring including —SO₂— in the ring skeleton thereof, specifically a cyclic group in which the sulfur atom (S) in —SO₂— forms a part of the ring skeleton of the cyclic group. Considering a ring including —SO₂— in the ring skeleton thereof as the first ring, a group having that ring alone is called a monocyclic group, and a group further having another ring structure is called a polycyclic group regardless of its structure. The —SO₂-containing cyclic group may be monocyclic or polycyclic.

In particular, the —SO₂-containing cyclic group is preferably a cyclic group containing —O—SO₂— in the ring skeleton thereof, i.e., a cyclic group containing a sultone ring in which —O—S— in —O—SO₂— forms a part of the ring skeleton.

The number of carbon atoms in an —SO₂-containing cyclic group is preferably 3 or more and 30 or less, more preferably 4 or more and 20 or less, even more preferably 4 or more and 15 or less, and particularly preferably 4 or more and 12 or less. The above number of carbon atoms is the number of carbon atoms constituting a ring skeleton, and shall not include the number of carbon atoms in a substituent.

The —SO₂-containing cyclic group may be an —SO₂-containing aliphatic cyclic group or an —SO₂-containing aromatic cyclic group. It is preferably an —SO₂-containing aliphatic cyclic group.

—SO₂-containing aliphatic cyclic groups include a group in which at least one hydrogen atom is removed from an aliphatic hydrocarbon ring where a part of the carbon atoms constituting the ring skeleton thereof is(are) substituted with —SO₂— or —O—SO₂—. More specifically, they include a group in which at least one hydrogen atom is removed from an aliphatic hydrocarbon ring where —CH₂— constituting the ring skeleton thereof is substituted with —SO₂— and a group in which at least one hydrogen atom is removed from an aliphatic hydrocarbon ring where —CH₂—CH₂— constituting the ring thereof is substituted with —O—SO₂—.

The number of carbon atoms in the above alicyclic hydrocarbon ring is preferably 3 or more and 20 or less, more preferably 3 or more and 12 or less. The above alicyclic hydrocarbon ring may be polycyclic, or may be monocyclic. As the monocyclic alicyclic hydrocarbon group, preferred is a group in which two hydrogen atoms are removed from monocycloalkane having 3 or more and 6 or less carbon atoms. Examples of the above monocycloalkane can include cyclopentane, cyclohexane and the like. As the polycyclic alicyclic hydrocarbon ring, preferred is a group in which two hydrogen atoms are removed from polycycloalkane having 7 or more and 12 or less carbon atoms, and specific examples of the above polycycloalkane include adamantane, norbornane, isobornane, tricyclodecane, tetracyclododecane and the like.

The —SO₂-containing cyclic group may have a substituent. Examples of the above substituent include, for example, an alkyl group, an alkoxy group, a halogen atom, a halogenated alkyl group, a hydroxyl group, an oxygen atom (═O), —COOR″, —OC(═O)R″, a hydroxyalkyl group, a cyano group and the like.

For an alkyl group as the above substituent, preferred is an alkyl group having 1 or more and 6 or less carbon atoms. The above alkyl group is preferably linear or branched. Specific examples include methyl group, ethyl group, n-propyl group, isopropyl group, n-butyl group, isobutyl group, tert-butyl group, n-pentyl group, isopentyl group, neopentyl group, n-hexyl group and the like. Among these, methyl group or ethyl group is preferred, and methyl group is particularly preferred.

For an alkoxy group as the above substituent, preferred is an alkoxy group having 1 or more and 6 or less carbon atoms. The above alkoxy group is preferably linear or branched. Specific examples include a group in which an alkyl groups recited as an alkyl group for the above substituent is attached to the oxygen atom (—O—).

Halogen atoms as the above substituent include a fluorine atom, a chlorine atom, a bromine atom, an iodine atom and the like, and a fluorine atom is preferred.

Halogenated alkyl groups for the above substituent include a group in which a part or all of the hydrogen atoms in the above alkyl group is (are) substituted with the above halogen atom(s).

Halogenated alkyl groups as the above substituent include a group in which a part or all of the hydrogen atoms in the alkyl groups recited as an alkyl group for the above substituent is(are) substituted with the above halogen atom(s). As the above halogenated alkyl group, a fluorinated alkyl group is preferred, and a perfluoroalkyl group is particularly preferred.

R″s in the aforementioned —COOR″ and —OC(═O)R″ are either a hydrogen atom or a linear, branched or cyclic alkyl group having 1 or more and 15 or less carbon atoms.

In a case where R″ is a linear or branched alkyl group, the number of carbon atoms in the above chain alkyl group is preferably 1 or more and 10 or less, more preferably 1 or more and 5 or less, and particularly preferably 1 or 2.

In a case where R″ is a cyclic alkyl group, the number of carbon atoms in the above cyclic alkyl group is preferably 3 or more and 15 or less, more preferably 4 or more and 12 or less, and particularly preferably 5 or more and 10 or less. Specific examples can include a group in which one or more hydrogen atoms are removed from monocycloalkane; and polycycloalkane such as bicycloalkane, tricycloalkane, tetracycloalkane and the like optionally substituted with a fluorine atom or a fluorinated alkyl group. More specific examples include a group in which one or more hydrogen atoms are removed from monocycloalkane such as cyclopentane and cyclohexane; and polycycloalkane such as adamantane, norbornane, isobornane, tricyclodecane and tetracyclododecane.

For a hydroxyalkyl group as the above substituent, preferred is a hydroxyalkyl group having 1 or more and 6 or less carbon atoms. Specific examples include a group in which at least one of the hydrogen atoms in the alkyl groups recited as an alkyl group for the above substituent is substituted with a hydroxyl group.

More specific examples of the —SO₂-containing cyclic group include the groups represented by the following formulae (bL4-1) to (bL-4).

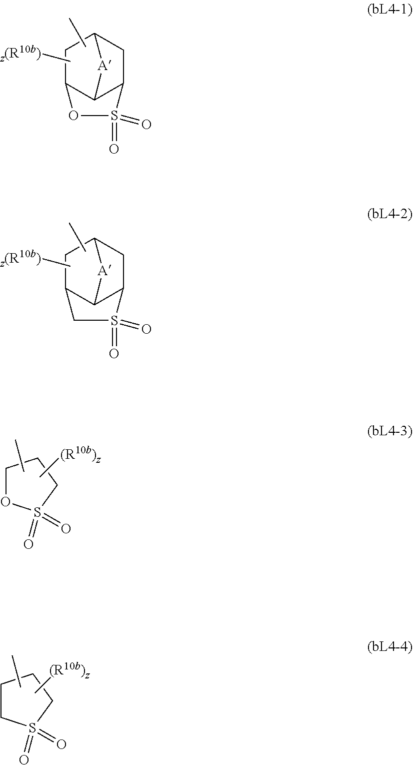

(In the formulae, A′ represents an alkylene group having 1 or more and 5 or less carbon atoms optionally including an oxygen atom or a sulfur atom, an oxygen atom or a sulfur atom; z represents an integer of 0 or more and 2 or less; R^{10b} represents an alkyl group, an alkoxy group, a halogenated alkyl group, a hydroxyl group, —COOR″, —OC(═O)R″, a hydroxyalkyl group, or a cyano group; and R″ represents a hydrogen atom or an alkyl group.)

In the above formulae (bL4-1) to (bL4-4), A′ represents an alkylene group having 1 or more and 5 or less carbon atoms optionally including an oxygen atom (—O—) or a sulfur atom (—S—), an oxygen atom or a sulfur atom. As an alkylene group having 1 or more and 5 or less carbon atoms in A′, a linear or branched alkylene group is preferred, and examples thereof include methylene group, ethylene group, n-propylene group, isopropylene group and the like.

In a case where the above alkylene group includes an oxygen atom or a sulfur atom, specific examples thereof include a group in which —O— or —S— is present at a terminal or between carbon atoms of the above alkylene group, for example, —O—CH₂—, —CH₂—O—CH₂—, —S—CH₂—, —CH₂—S—CH₂—, and the like. As A′, an alkylene group having 1 or more and 5 or less carbon atoms or —O— is preferred, and an alkylene group having 1 or more and 5 or less carbon atoms is more preferred, and a methylene group is most preferred.

z may be any of 0, 1, and 2, and is most preferably 0. In a case where z is 2, a plurality of R^{10b} may be the same, or may differ from each other.

An alkyl group, an alkoxy group, a halogenated alkyl group, —COOR″, —OC(═O)R″ and a hydroxyalkyl group in R^{10b} include those similar to the groups described above for the alkyl group, the alkoxy group, the halogenated alkyl group, —COOR″, —OC(═O)R″ and the hydroxyalkyl group, respectively, which are recited as those optionally contained in the —SO₂— containing cyclic group.

Below, specific cyclic groups represented by the above formulae (bL4-1) to (bL4-4) will be illustrated. Note here that “Ac” in the formulae represents an acetyl group.

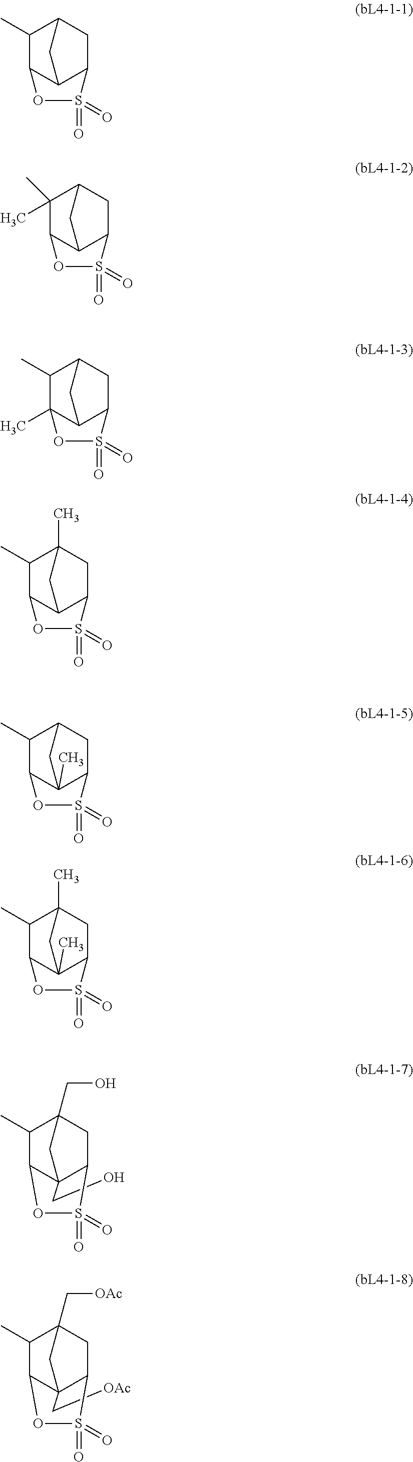

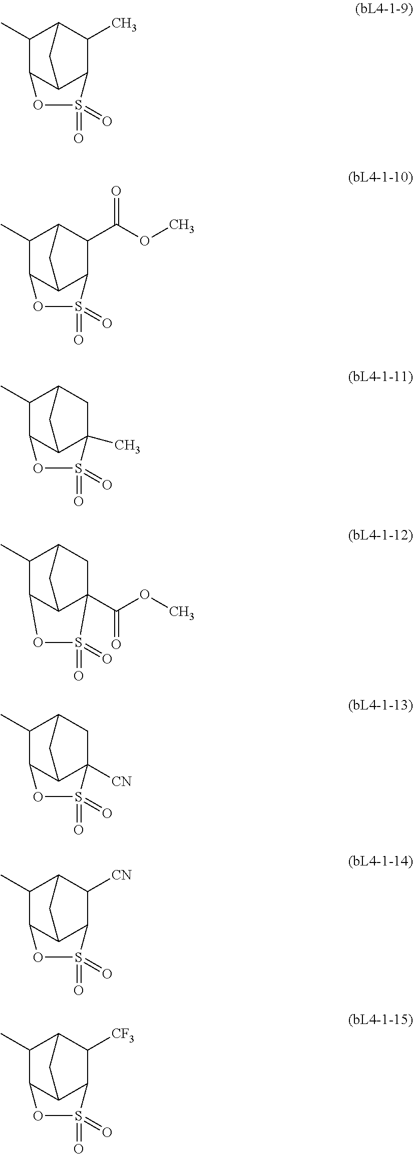

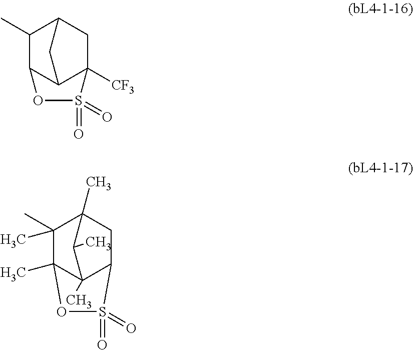 [SMILES: CC1C2CC3C1OS(=O)(=O)C3(C(F)(F)F)C2 ; CC1C2(C)CC3C1(C)C(C)(OS3(=O)=O)C2(C)C]

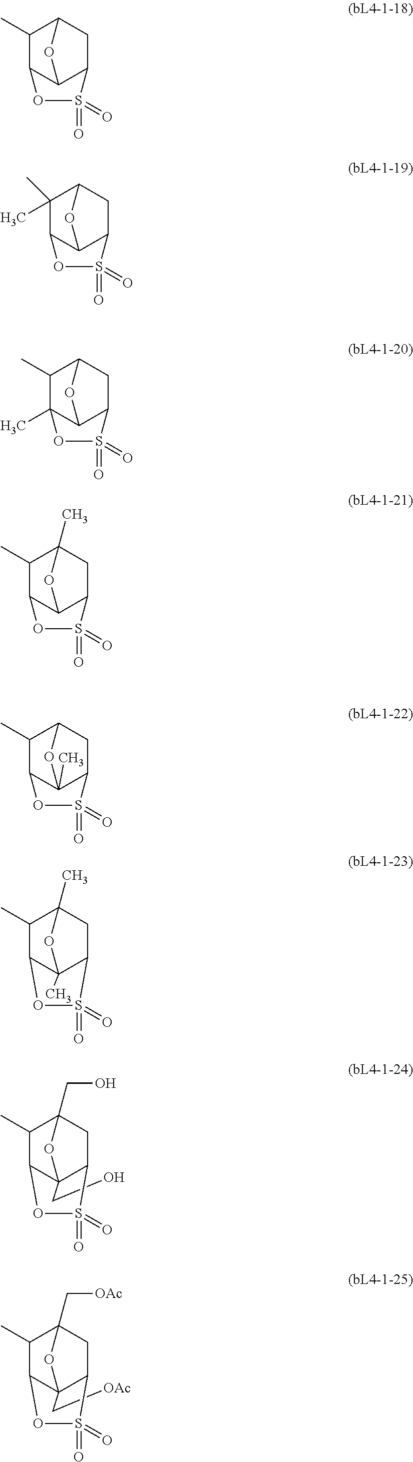

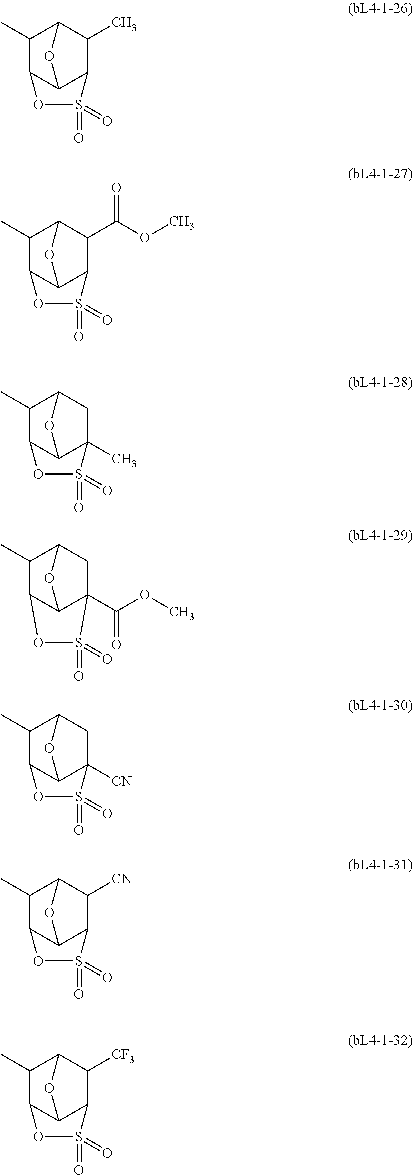

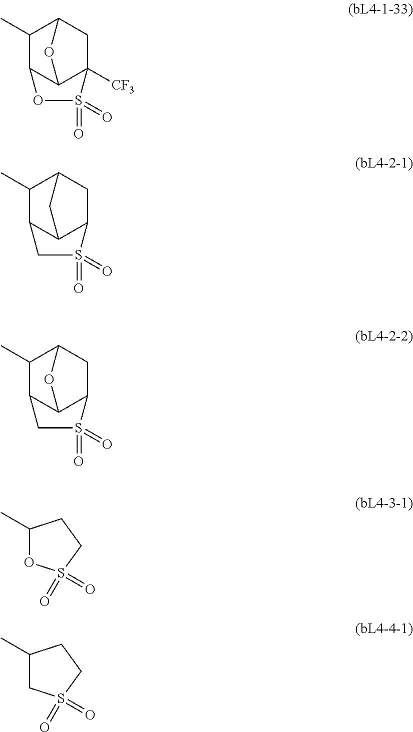

As the —SO₂-containing cyclic group, among those shown above, a group represented by the above formula (bL4-1) is preferred, and at least one selected from the group consisting of the groups represented by any of the aforementioned formulae (bL4-1-1), (bL4-1-18), (bL4-3-1) and (bL4-4-1) is more preferred, and a group represented by the aforementioned formula (bL4-1-1) is most preferred.

Lactone-Containing Cyclic Group)

The “lactone-containing cyclic group” refers to a cyclic group containing a ring (lactone ring) including —O—C(═O)— in the ring skeleton thereof. Considering the lactone ring as the first ring, a group having that lactone ring alone is called a monocyclic group, and a group further having another ring structure is called a polycyclic group regardless of its structure. The lactone-containing cyclic group may be a monocyclic group, or may be a polycyclic group.

There is no particular limitation on the lactone-containing cyclic group in the constituent unit (bL4), and any cyclic group can be used. Specifically, examples of the lactone-containing monocyclic groups include a group in which one hydrogen atom is removed from 4 to 6 membered ring lactone, for example, a group in which one hydrogen atom is removed from β-propiono lactone, a group in which one hydrogen atom is removed from γ-butyrolactone, a group in which one hydrogen atom is removed from δ-valerolactone and the like. Further, lactone-containing polycyclic groups include a group in which one hydrogen atom is removed from bicycloalkane, tricycloalkane and tetracycloalkane having a lactone ring.

As to the constituent unit (bL4), as long as the constituent unit (bL4) has an —SO₂-containing cyclic group or a lactone-containing cyclic group, the structures of other parts are not particularly limited. A preferred constituent unit (bL4) is at least one constituent unit selected from the group consisting of a constituent unit (bL4-S) derived from an acrylic acid ester including an —SO₂-containing cyclic group in which a hydrogen atom attached to the carbon atom in the a position may be substituted with a substituent; and a constituent unit (bL4-L) derived from an acrylic acid ester including a lactone-containing cyclic group in which the hydrogen atom attached to the carbon atom in the a position may be substituted with a substituent.

Constituent Unit (bL4-S)]

More specifically, examples of the constituent unit (bL4-S) include one represented by the following formula (bL4-S1).

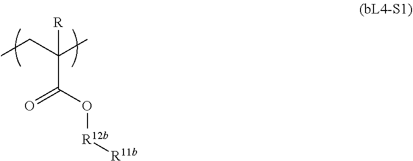

(In the formula, R represents a hydrogen atom, an alkyl group having 1 or more 5 or less carbon atoms or a halogenated alkyl group having 1 or more 5 or less carbon atoms; and R^{11b} represents an —SO₂-containing cyclic group; and R^{12b} represents a single-bond or divalent linking group.)

In the formula (bL4-S1), R is similarly defined as above. R^{11b} is similarly defined as in the —SO₂-containing cyclic group described above. R^{12b} may be either a single-bond linking group or a divalent linking group.

There is no particular limitation on the divalent linking group in R^{12b}, and suitable groups include an optionally substituted divalent hydrocarbon group, a divalent linking group including a heteroatom, and the like.

Optionally Substituted Divalent Hydrocarbon Group

The hydrocarbon group as a divalent linking group may be an aliphatic hydrocarbon group, or may be an aromatic hydrocarbon group. The aliphatic hydrocarbon group means a hydrocarbon group without aromaticity. The above aliphatic hydrocarbon group may be saturated or may be unsaturated. Usually, a saturated hydrocarbon group is preferred. More specifically, examples of the above aliphatic hydrocarbon group include a linear or branched aliphatic hydrocarbon group, an aliphatic hydrocarbon group including a ring in the structure thereof and the like.

The number of carbon atoms in the linear or branched aliphatic hydrocarbon group is preferably 1 or more and 10 or less, more preferably 1 or more and 8 or less, and even more preferably 1 or more and 5 or less.

As the linear aliphatic hydrocarbon group, a linear alkylene group is preferred. Specific examples include methylene group [—CH₂—], ethylene group [—(CH₂)₂—], trimethylene group [—(CH₂)₃—], tetramethylene group [—(CH₂)₄—], pentamethylene group [—(CH₂)₅-] and the like.

As the branched aliphatic hydrocarbon group, a branched alkylene group is preferred. Specific examples include alkyl alkylene groups such as alkyl methylene groups such as —CH(CH₃)—, —CH(CH₂CH₃)—, —C(CH₃)₂—, —C(CH₃) (CH₂CH₃)—, —C(CH₃) (CH₂CH₂CH₃)— and —C(CH₂CH₃)₂—; alkyl ethylene groups such as —CH(CH₃) CH₂—, —CH(CH₃) CH(CH₃)—, —C(CH₃)₂CH₂—, —CH(CH₂CH₃) CH₂— and —C(CH₂CH₃)₂—CH₂—; alkyl trimethylene groups such as —CH(CH₃) CH₂CH₂— and —CH₂CH(CH₃) CH₂—; alkyl tetramethylene groups such as —CH(CH₃)CH₂CH₂CH₂— and —CH₂CH(CH₃)CH₂CH₂—; and the like. As an alkyl group in the alkyl alkylene group, a linear alkyl group having 1 or more and 5 or less carbon atoms is preferred.

The above linear or branched aliphatic hydrocarbon group may or may not have a substituent (a group or atom other than a hydrogen atom) which substitutes a hydrogen atom. Examples of the substituent include a fluorine atom, a fluorinated alkyl group having 1 or more and 5 or less carbon atoms substituted with a fluorine atom, an oxo group (═O) and the like.

Examples of the above aliphatic hydrocarbon group including a ring in the structure thereof include a cyclic aliphatic hydrocarbon group optionally including a hetero atom in the ring structure (a group in which two hydrogen atoms are removed from an aliphatic hydrocarbon ring); a group in which the above cyclic aliphatic hydrocarbon group is attached to an end of a linear or branched aliphatic hydrocarbon group; a group in which the above cyclic aliphatic hydrocarbon group is present in a linear or branched aliphatic hydrocarbon group along the chain; and the like. Examples of the above linear or branched aliphatic hydrocarbon group include those similar to the above.

The number of carbon atoms in the cyclic aliphatic hydrocarbon group is preferably 3 or more and 20 or less, and more preferably 3 or more and 12 or less.

The cyclic aliphatic hydrocarbon group may be polycyclic, or may be monocyclic. As the monocyclic aliphatic hydrocarbon group, a group in which two hydrogen atoms are removed from monocycloalkane is preferred. The number of carbon atoms in the above monocycloalkane is preferably 3 or more and 6 or less. Specific examples include cyclopentane, cyclohexane and the like. As the polycyclic aliphatic hydrocarbon group, a group in which two hydrogen atoms are removed from polycycloalkane is preferred. The number of carbon atoms in the above polycycloalkane is preferably 7 or more and 12 or less. Specific examples include adamantane, norbornane, isobornane, tricyclodecane, tetracyclododecane and the like.

The cyclic aliphatic hydrocarbon group may or may not have a substituent which substitutes a hydrogen atom (a group or atom other than a hydrogen atom). Examples of the above substituent include an alkyl group, an alkoxy group, a halogen atom, a halogenated alkyl group, a hydroxyl group, an oxo group (═O) and the like.

For an alkyl group as the above substituent, an alkyl group having 1 or more and 5 or less carbon atoms is preferred, and methyl group, ethyl group, propyl group, n-butyl group and tert-butyl group are more preferred.

For an alkoxy group as the above substituent, an alkoxy group having 1 or more and 5 or less carbon atoms is preferred, and methoxy group, ethoxy group, n-propoxy group, iso-propoxy group, n-butoxy group and tert-butoxy group are more preferred, and methoxy group and ethoxy group are particularly preferred.

Halogen atoms as the above substituent include a fluorine atom, a chlorine atom, a bromine atom, an iodine atom and the like, and a fluorine atom is preferred.

Halogenated alkyl groups as the above substituent include a group in which a part or all of hydrogen atoms in the aforementioned alkyl group is(are) substituted with the above halogen atom(s).

In the cyclic aliphatic hydrocarbon group, a part of carbon atoms constituting the ring structure thereof may be substituted with —O—, or —S—. As the substituent including the above hetero atom, preferred are —O—, —C(═O)—O—, —S—, —S(═O)₂— and —S(═O)₂—O—.

The aromatic hydrocarbon group as the divalent hydrocarbon group is a divalent hydrocarbon group having at least one aromatic ring, and may have a substituent. There is no particular limitation on the aromatic ring as long as it is a cyclic conjugated system having a 4n+2 π electrons, and it may be monocyclic or may be polycyclic. The number of carbon atoms in the aromatic ring is preferably 5 or more and 30 or less, more preferably 5 or more and 20 or less, even more preferably 6 or more and 15 or less, and particularly preferably 6 or more and 12 or less. However, the number of carbon atoms in a substituent shall not be included in the above number of carbon atoms.

Specifically, aromatic rings include aromatic hydrocarbon rings such as benzene, naphthalene, anthracene and phenanthrene; aromatic heterocycles in which a part of the carbon atoms constituting the above aromatic hydrocarbon ring is(are) substituted with hetero atom(s). Hetero atoms in the aromatic heterocycle include an oxygen atom, a sulfur atom, a nitrogen atom and the like. Specifically, aromatic heterocycles include a pyridine ring, a thiophene ring, and the like.

Specific examples of the aromatic hydrocarbon group as a divalent hydrocarbon group include a group in which two hydrogen atoms are removed from the above aromatic hydrocarbon ring or the above aromatic heterocycle (an arylene group or a heteroarylene group); a group in which two hydrogen atoms are removed from an aromatic compound including two or more aromatic rings (for example, biphenyl, fluorene and the like); a group in which one hydrogen atom from a group where one hydrogen atom is removed from the above aromatic hydrocarbon ring or the above aromatic heterocycle (an aryl group or a heteroaryl group) is substituted with an alkylene group (for example, a group in which one hydrogen atom is further removed from an aryl group in an arylalkyl group such as benzyl group, phenethyl group, 1-naphthylmethyl group, 2-naphthylmethyl group, 1-naphthylethyl group and 2-naphthylethyl group); and the like.

The number of carbon atoms in the above alkylene group bonded to an aryl group or a heteroaryl group is preferably 1 or more and 4 or less, more preferably 1 or more and 2 or less, and particularly preferably 1.

In the above aromatic hydrocarbon group, a hydrogen atom of the above aromatic hydrocarbon group may be substituted with a substituent. For example, a hydrogen atom attached to an aromatic ring in the above aromatic hydrocarbon group may be substituted with a substituent. Examples of the substituent include an alkyl group, an alkoxy group, a halogen atom, a halogenated alkyl group, a hydroxyl group, an oxo group (═O) and the like.

For an alkyl group as the above substituent, an alkyl group having 1 or more and 5 or less carbon atoms is preferred, and methyl group, ethyl group, n-propyl group, n-butyl group and tert-butyl group are more preferred.

For an alkoxy group as the above substituent, an alkoxy group having 1 or more and 5 or less carbon atoms is preferred, and methoxy group, ethoxy group, n-propoxy group, iso-propoxy group, n-butoxy group and tert-butoxy group are preferred, and methoxy group and ethoxy group are more preferred.

Halogen atoms as the above substituent include a fluorine atom, a chlorine atom, a bromine atom, an iodine atom and the like, and a fluorine atom is preferred.

Halogenated alkyl groups as the above substituent include a group in which a part or all of hydrogen atoms in the aforementioned alkyl group is(are) substituted with the above halogen atom(s).

Divalent Linking Group Including Hetero Atom

A hetero atom in the divalent linking group including a hetero atom is an atom other than a carbon atom and a hydrogen atom, and examples thereof include an oxygen atom, a nitrogen atom, a sulfur atom, a halogen atom and the like.

Specific examples of the divalent linking group including a hetero atom include non-hydrocarbon based linking groups such as —O—, —C(═O)—, —C(═O)—O—, —O—C(═O)—O—, —S—, —S(═O)₂—, —S(═O)₂—O—, —NH—, —NH—C(═O)—, —NH—C(═NH)—, ═N—, and combinations of at least one of these non-hydrocarbon based linking groups and a divalent hydrocarbon group and the like. Examples of the above divalent hydrocarbon group include those similar to the aforementioned divalent hydrocarbon groups optionally having a substituent, and linear or branched aliphatic hydrocarbon groups are preferred.

Among those described above, H in —NH— in —C(═O)—NH—, —NH— and —NH—C(═NH)— may be substituted with a substituent such as an alkyl group or an acyl group, respectively. The number of carbon atoms in the above substituent is preferably 1 or more and 10 or less, more preferably 1 or more and 8 or less, and particularly preferably 1 or more and 5 or less.

As a divalent linking group in R^{12b}, a linear or branched alkylene group, a cyclic aliphatic hydrocarbon group, or a divalent linking group including a hetero atom is preferred.

In a case where the divalent linking group in R^{12b} is a linear or branched alkylene group, the number of carbon atoms in the above alkylene group is preferably 1 or more and 10 or less, more preferably 1 or more and 6 or less, particularly preferably 1 or more and 4 or less, and most preferably 1 or more and 3 or less. Specific examples include groups similar to the linear alkylene groups or branched alkylene groups recited as a linear and branched aliphatic hydrocarbon group in the description of the “divalent hydrocarbon group optionally having a substituent” as the aforementioned divalent linking group.

In a case where the divalent linking group in R^{12b} is a cyclic aliphatic hydrocarbon group, examples of the above cyclic aliphatic hydrocarbon group include groups similar to those recited as the “aliphatic hydrocarbon group including a ring in the structure” in the description of the “divalent hydrocarbon group optionally having a substituent” as the aforementioned divalent linking group.

As the above cyclic aliphatic hydrocarbon group, particularly preferred is a group in which two or more hydrogen atoms are removed from cyclopentane, cyclohexane, norbornane, isobornane, adamantane, tricyclodecane or tetracyclododecane.

In a case where the divalent linking group in R^{12b} is a divalent linking group including a hetero atom, groups preferred as the above linking groups include —O—, —C(═O)—O—, —C(═O)—, —O—C(═O)—O—, —C(═O)—NH—, —NH— (H may be substituted with a substituent such as an alkyl group or an acyl group), —S—, —S(═O)₂—, —S(═O)₂—O— and a group represented by the general formula —Y¹—O—Y²—, —[Y¹—C(═O)—O]_{m′}—Y²— or —Y¹—O—C(═O)—Y²—[wherein Y¹ and Y² are divalent hydrocarbon groups each independently, optionally having a substituent, and O represents an oxygen atom, and m′ is an integer of 0 or more and 3 or less]

In a case where the divalent linking group in R^{12b} is —NH—, the hydrogen atom in —NH— may be substituted with a substituent such as an alkyl group or an acyl group. The number of carbon atoms in the above substituent (an alkyl group, an acyl group and the like) is preferably 1 or more and 10 or less, more preferably 1 or more and 8 or less, and particularly preferably 1 or more and 5 or less.

Y₁ and Y₂ in the formula Y₁—O—Y₂—, —[Y₁—C(═O)—O]_{m′}—Y₂— or —Y₁—O—C(═O)—Y₂— are divalent hydrocarbon groups each independently, optionally having a substituent. Examples of the above divalent hydrocarbon group include groups similar to the “divalent hydrocarbon group optionally having a substituent” recited in the description of the above divalent linking group.

As Y¹, a linear aliphatic hydrocarbon group is preferred, and a linear alkylene group is more preferred, and a linear alkylene group having 1 or more and 5 or less carbon atoms is more preferred, and a methylene group and an ethylene group are particularly preferred.

As Y², a linear or branched aliphatic hydrocarbon group is preferred, and a methylene group, an ethylene group and an alkylmethylene group are more preferred. The alkyl group in the above alkylmethylene group is preferably a linear alkyl group having 1 or more and 5 or less carbon atoms, more preferably a linear alkyl group having 1 or more and 3 or less carbon atoms, and particularly preferably a methyl group.

In a group represented by the formula —[Y¹—C(═O)—O]_{m′}—Y²—, m′ is an integer of 0 or more and 3 or less, preferably an integer of 0 or more and 2 or less, more preferably 0 or 1, and particularly preferably 1. In other words, as a group represented by the formula —[Y¹—C(═O)—O]_{m′}—Y²—, a group represented by the formula —Y¹—C(═O)—O—Y²— is particularly preferred. Among these, a group represented by the formula —(CH₂)_{a′}—C(═O)—O—(CH₂)_{b′}— is preferred. In the above formula, a′ is an integer of 1 or more and 10 or less, preferably an integer of 1 or more and 8 or less, more preferably an integer of 1 or more and 5 or less, even more preferably 1 or 2, and most preferably 1. b′ is an integer of 1 or more and 10 or less, preferably an integer of 1 or more and 8 or less, more preferably an integer of 1 or more and 5 or less, even more preferably 1 or 2, and most preferably 1.

With regard to the divalent linking group in R^{12b}, an organic group including a combination of at least one non-hydrocarbon group and a divalent hydrocarbon group is preferred as the divalent linking group including a hetero atom. Among these, a linear chain group having an oxygen atom as a hetero atom, for example, a group including an ether bond or an ester bond is preferred, and a group represented by the aforementioned formula —Y¹—O—Y²—, —[Y¹—C(═O)—O]_{m′}—Y²— or —Y¹—O—C(═O)—Y²— is more preferred, and a group represented by the aforementioned formula —[Y¹—C(═O)—O]_{m′}—Y²— or —Y¹—O—C(═O)—Y²— is particularly preferred.

As the divalent linking group in R^{12b}, a group including an alkylene group or an ester bond (—C(═O)—O—) is preferred.

The above alkylene group is preferably a linear or branched alkylene group. Suitable examples of the above linear aliphatic hydrocarbon group include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—] and the like. Suitable examples of the above branched alkylene group include alkyl alkylene groups such as alkyl methylene groups such as —CH(CH₃)—, —CH(CH₂CH₃)—, —C(CH₃)₂—, —C(CH₃) (CH₂CH₃)—, —C(CH₃) (CH₂CH₂CH₃)— and —C(CH₂CH₃)₂—; alkyl ethylene groups such as —CH(CH₃) CH₂—, —CH(CH₃) CH(CH₃)—, —C(CH₃)₂CH₂—, —CH(CH₂CH₃) CH₂— and —C(CH₂CH₃)₂—CH₂—; alkyl trimethylene groups such as —CH(CH₃)CH₂CH₂— and —CH₂CH(CH₃)CH₂—; alkyl tetramethylene groups such as —CH(CH₃)CH₂CH₂CH₂— and —CH₂CH(CH₃) CH₂CH₂—.

As the divalent linking group including an ester bond, particularly preferred is a group represented by the formula: —R^{13b}—C(═O)—O—[wherein R^{13b} represents a divalent linking group.]. In other words, the constituent unit (bL4-S) is preferably a constituent unit represented by the following formula (bL4-S1-1).

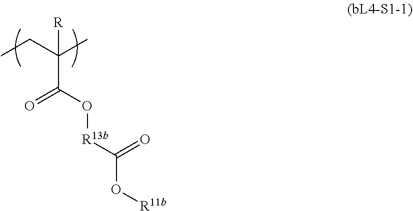

(In the formula, R and R^{11b} are each same as the above, and R^{13b} represents a divalent linking group.)

There is no particular limitation for R^{13b}, examples thereof include groups similar to the aforementioned divalent linking group in R^{12b}. As the divalent linking group in R^{13b}, a linear or branched alkylene group, an aliphatic hydrocarbon group including a ring in the structure, or a divalent linking group including a hetero atom is preferred, and a linear or branched alkylene group or a divalent linking group including an oxygen atom as a hetero atom is preferred.

As the linear alkylene group, a methylene group or an ethylene group is preferred, and a methylene group is particularly preferred. As the branched alkylene group, an alkylmethylene group or an alkylethylene group is preferred, and —CH(CH₃)—, —C(CH₃)₂— or —C(CH₃)₂CH₂— is particularly preferred.

As the divalent linking group including an oxygen atom, a divalent linking group including an ether bond or an ester bond is preferred, and the aforementioned —Y¹—O—Y²—, —[Y¹—C(═O)—O]_{m′}—Y²— or —Y¹—O—C(═O)—Y²— is more preferred. Y¹ and Y² are each independently divalent hydrocarbon groups optionally having a substituent, and m′ is an integer of 0 or more and 3 or less. Among these, —Y¹—O—C(═O)—Y²— is preferred, and a group represented by —(CH₂)_{c}—O—C(═O)—(CH₂)_{d}— is particularly preferred. c is an integer of 1 or more and 5 or less, and 1 or 2 is preferred. d is an integer of 1 or more and 5 or less, and 1 or 2 is preferred.

As the constituent unit (b-L4-S), in particular, one represented by the following formula (bL4-S1-11) or (bL4-S1-12) is preferred, and one represented by the formula (bL4-S1-12) is more preferred.

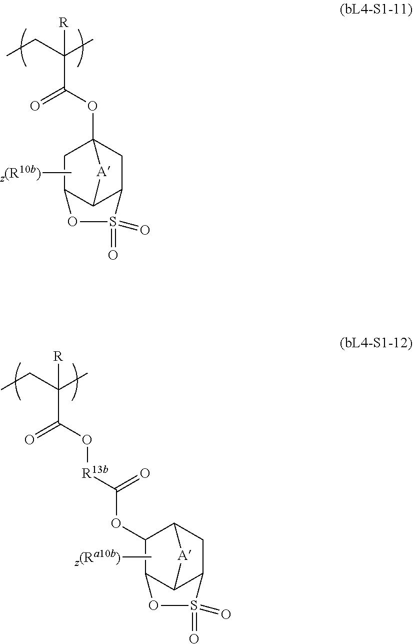

(In the formulae, R, A′, R^{10b}, z and R^{13b} are each the same as the above.)

In the formula (bL4-S1-11), A′ is preferably a methylene group, an oxygen atom (—O—) or a sulfur atom (—S—).

As R^{13b}, preferred is a linear or branched alkylene group or a divalent linking group including an oxygen atom. Examples of the linear or branched alkylene group and the divalent linking group including an oxygen atom in R^{13b} include those similar to the aforementioned linear or branched alkylene group and the aforementioned divalent linking group including an oxygen atom, respectively.

As the constituent unit represented by the formula (bL4-S1-12), particularly preferred is one represented by the following formula (bL4-S1-12a) or (bL4-S1-12b).

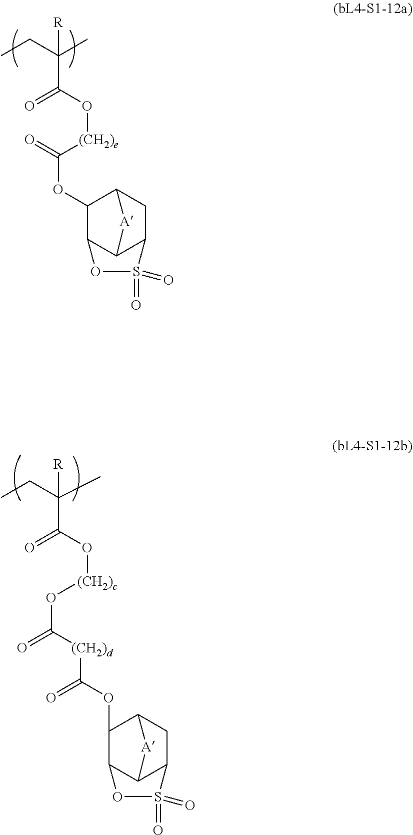

(In the formulae, R and A′ are each the same as the above, and c to e are each independently an integer of 1 or more and 3 or less.)

Constituent Unit (bL4-L)

Examples of the constituent unit (bL4-L) include, for example, a constituent unit in which R^{11b} in the aforementioned formula (bL4-S1) is substituted with a lactone-containing cyclic group. More specifically they include those represented by the following formulae (bL4-L1) to (bL4-L5).

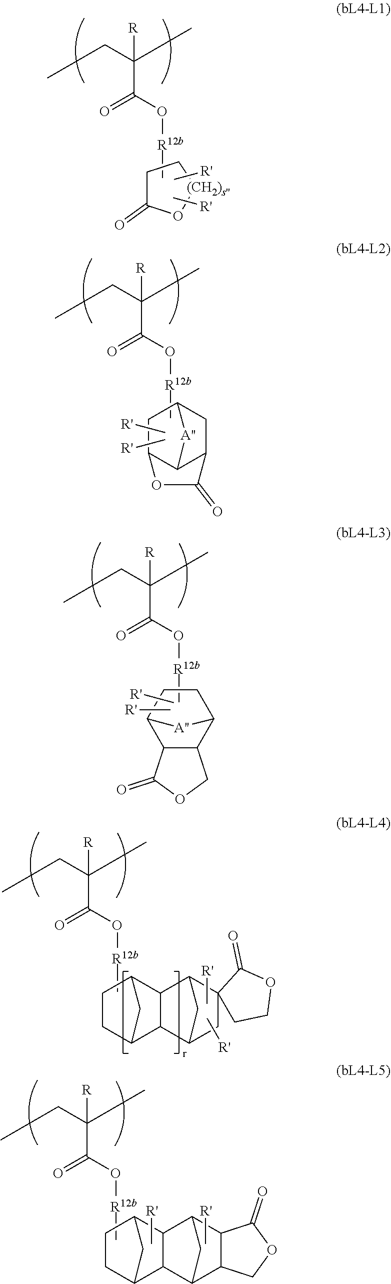

(In the formulae, R represents a hydrogen atom, an alkyl group having 1 or more and 5 or less carbon atoms or a halogenated alkyl group having 1 or more and 5 or less carbon atoms; R′ represents each independently a hydrogen atom, an alkyl group, an alkoxy group, a halogenated alkyl group, a hydroxyl group, —COOR″, —OC(═O)R″, a hydroxyalkyl group or a cyano group, and R″ represents a hydrogen atom or an alkyl group; R^{12b} represents a single bond or divalent linking group, and s″ is an integer of 0 or more and 2 or less; A″ represents an alkylene group having 1 or more and 5 or less carbon atoms optionally including an oxygen atom or a sulfur atom, an oxygen atom or a sulfur atom; and r is 0 or 1.)

R in the formulae (bL4-L1) to (bL4-L5) is the same as the above. Examples of the alkyl group, the alkoxy group, the halogenated alkyl group, —COOR″, —OC(═O)R″ and the hydroxyalkyl group in R′ include groups similar to those described for the alkyl group, the alkoxy group, the halogenated alkyl group, —COOR″, —OC(═O)R″ and the hydroxyalkyl group recited as a substituent which the —SO₂— containing cyclic group may have, respectively.

R′ is preferably a hydrogen atom in view of easy industrial availability and the like. The alkyl group in R″ may be any of a linear, branched or cyclic chain. In a case where R″ is a linear or branched alkyl group, the number of carbon atoms is preferably 1 or more and 10 or less, and more preferably 1 or more and 5 or less. In a case where R″ is a cyclic alkyl group, the number of carbon atoms is preferably 3 or more and 15 or less, more preferably 4 or more and 12 or less, and most preferably 5 or more and 10 or less. Specific examples include a group in which one or more hydrogen atoms are removed from monocycloalkane and polycycloalkane such as bicycloalkane, tricycloalkane, tetracycloalkane and the like optionally substituted with a fluorine atom or a fluorinated alkyl group. Specific examples include a group in which one or more hydrogen atoms are removed from monocycloalkane such as cyclopentane and cyclohexane; and polycycloalkane such as adamantane, norbornane, isobornane, tricyclodecane and tetracyclododecane; and the like. Examples of A″ include groups similar to A′ in the aforementioned formula (3-1). A″ is preferably an alkylene group having 1 to 5 carbon atoms, an oxygen atom (—O—) or a sulfur atom (—S—), more preferably an alkylene group having 1 or more and 5 or less carbon atoms or —O—. As the alkylene group having 1 or more and 5 or less carbon atoms, a methylene group or a dimethylmethylene group is more preferred, and a methylene group is most preferred.

R^{12b} is similar to R^{12b} in the aforementioned formula (bL4-S1). In the formula (bL4-L1), s″ is preferably 1 or 2. Below, specific examples of the constituent units represented by the aforementioned formulae (bL4-L1) to (bL4-L3) will be illustrated. In each of the following formulae, R^{α} represents a hydrogen atom, a methyl group or a trifluoromethyl group.

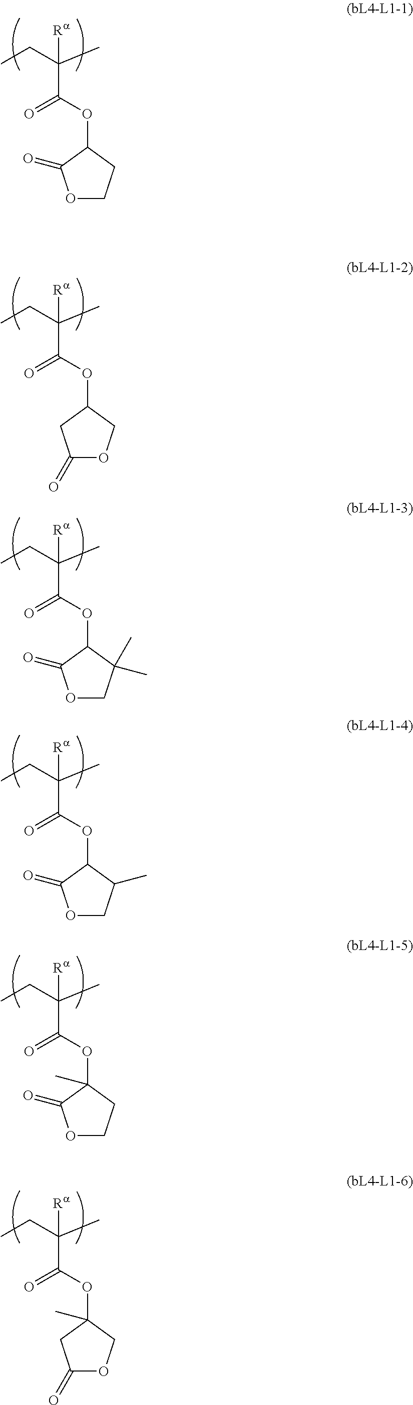

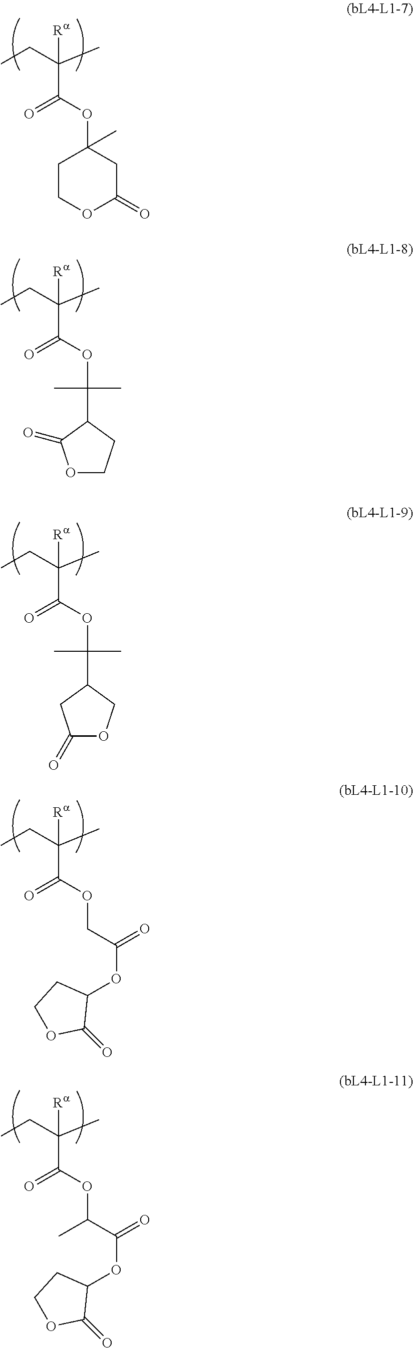

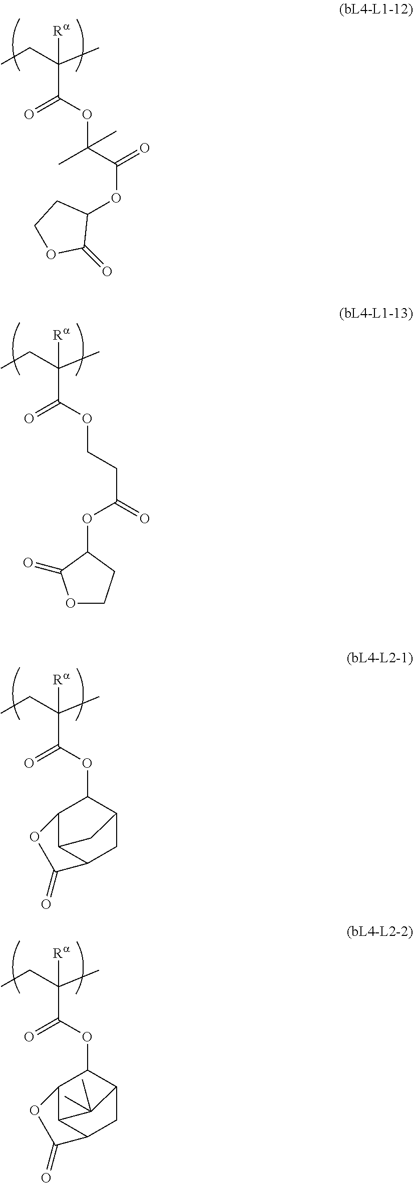

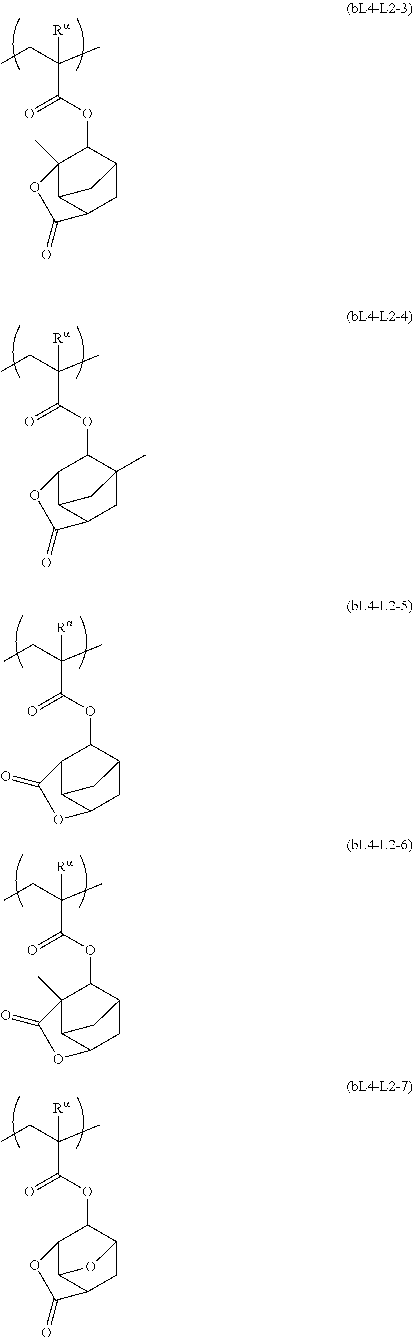

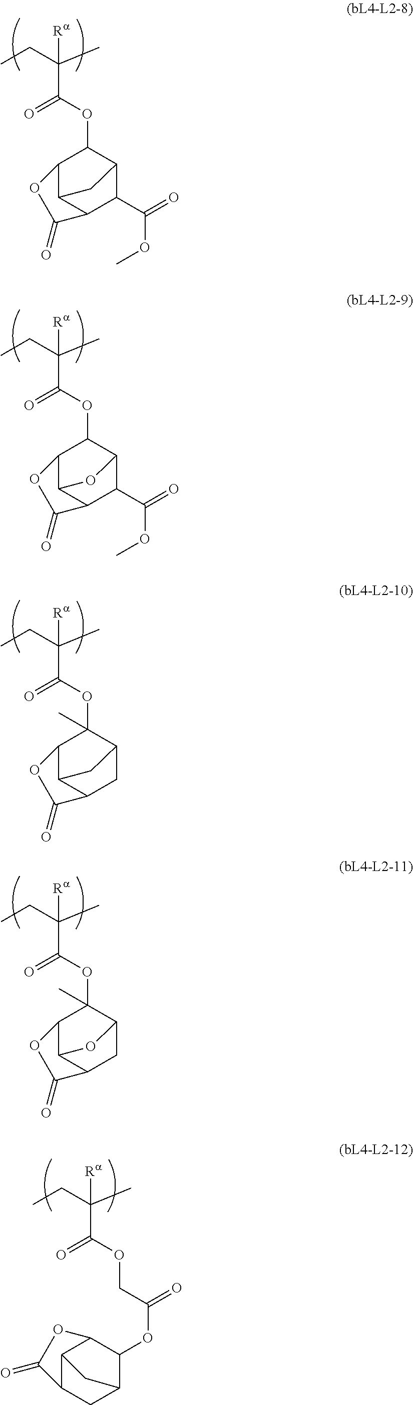

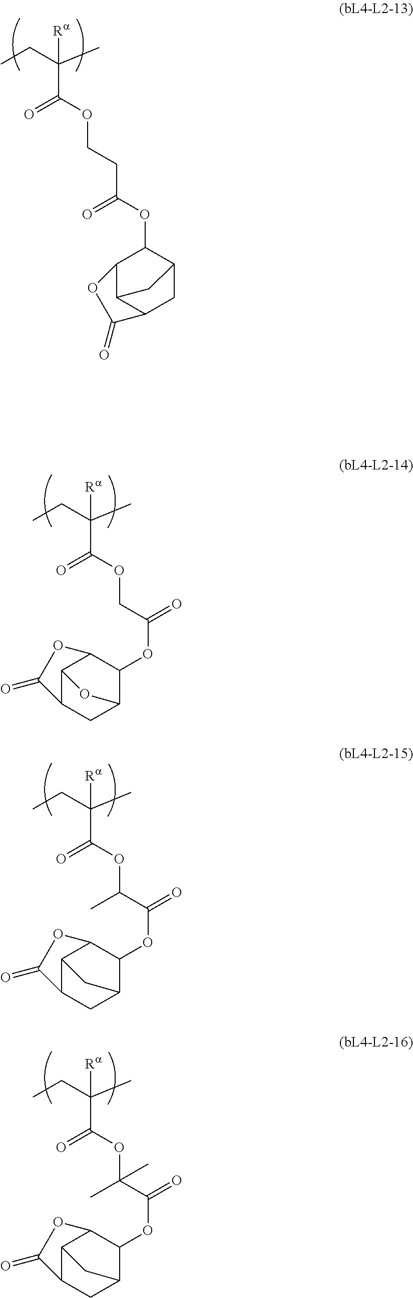

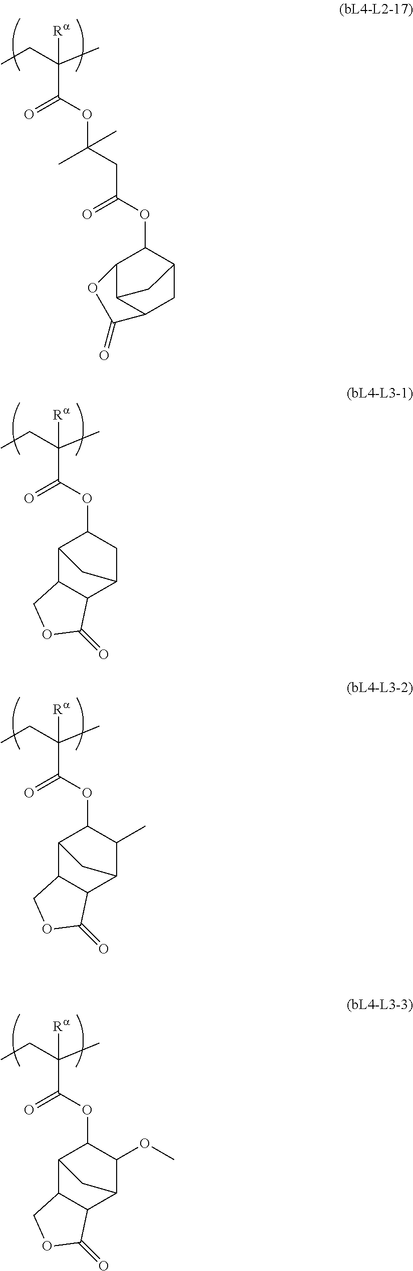

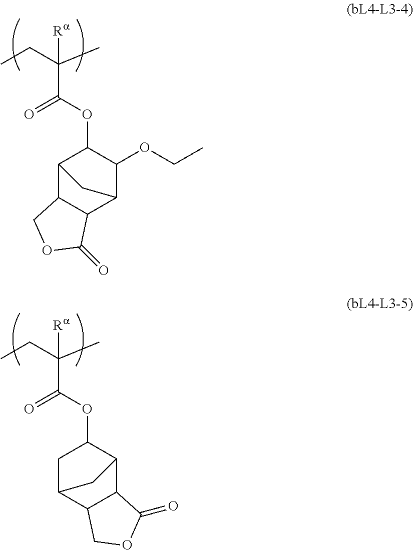

As the constituent unit (bL4-L), at least one selected from the group consisting of the constituent units represented by the aforementioned formulae (bL4-L1) to (bL4-L5) is preferred, and at least one selected from the group consisting of the constituent units represented by the formulae (bL4-L1) to (bL4-L3) is more preferred, and at least one selected from the group consisting of the constituent units represented by the aforementioned formula (bL4-L1) or (bL4-L3) is particularly preferred. Among these, at least one selected from the group consisting of the constituent units represented by the aforementioned formulae (bL4-L1-1), (bL4-L1-2), (bL4-L2-1), (bL4-L2-7), (bL4-L2-12), (bL4-L2-14), (bL4-L3-1) and (bL4-L3-5) is preferred.

Further, as the constituent unit (bL4-L), the constituent units represented by following formulae (bL4-L6) to (bL4-L7) are also preferred.

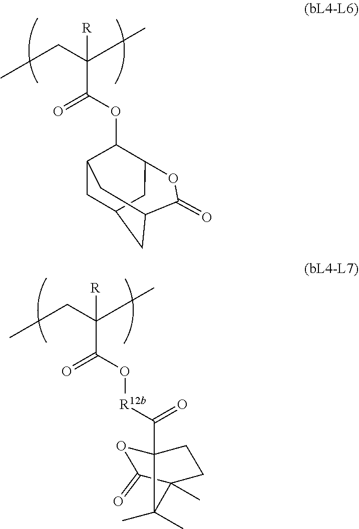

R and R^{12b} in the formulae (bL4-L6) and (bL4-L7) are the same as the above.

A molar ration of the constituent unit (bL4) is preferably 5% by mole or more and 35% by mole or less, more preferably 10% by mole or more and 30% by mole or less, and even more preferably 15% by mole or more and 25% by mole or less relative to all constituent units of the acrylic resin (B1a).

(Constituent Unit (bL5))

The acrylic resin (B1a) preferably includes a constituent unit (bL5) derived from a (meth)acrylic acid in order to adjust developability of the first photosensitive composition. A molar ratio of the constituent unit (bL5) is preferably 5% by mole or more and 30% by mole or less, more preferably 7% by mole or more and 25% by mole or less, and even more preferably 10% by mole or more and 20% by mole or less relative to all constituent units of the acrylic resin (B1a).

(Constituent Unit (bL6))

The acrylic resin (B1a) includes constituent units represented by the following formulae (bL6-1) to (bL6-3), having an acid dissociable group, as constituent units that enhance the solubility of the acrylic resin (B1a) in alkali under the action of acid.

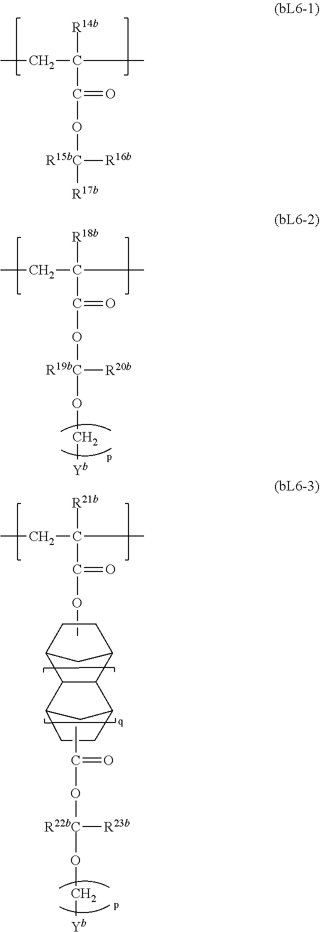

In the above formulae (bL6-1) to (bL6-2), R^{14b} and R^{18b} to R^{23b} each independently represent a hydrogen atom, a linear or branched alkyl group having 1 or more and 6 or less carbon atoms, a fluorine atom, or a linear or branched fluorinated alkyl group having 1 or more and 6 or less carbon atoms; R^{15b} to R^{17b} each independently represent a linear or branched alkyl group having 1 or more and 6 or less carbon atoms, a linear or branched fluorinated alkyl group having 1 or more and 6 or less carbon atoms, or an aliphatic cyclic group having 5 or more and 20 or less carbon atoms, and each independently represent a linear or branched alkyl group having 1 or more and 6 or less carbon atoms, or a linear or branched fluorinated alkyl group having 1 or more and 6 or less carbon atoms; and R^{16b} and R^{17b} may be bonded to each other to form a hydrocarbon ring having 5 or more and 20 or less carbon atoms together with the carbon atom to which both the groups are bonded; Yb represents an optionally substituted aliphatic group or alkyl group; p is an integer of 0 or more and 4 or less; and q is 0 or 1.

Note here that examples of the linear or branched alkyl group include methyl group, ethyl group, propyl group, isopropyl group, n-butyl group, isobutyl group, tert-butyl group, pentyl group, isopentyl group, neopentyl group, and the like. Furthermore, the fluorinated alkyl group refers to the abovementioned alkyl groups of which the hydrogen atoms are partially or entirely substituted with fluorine atoms. Specific examples of aliphatic cyclic groups include groups obtained by removing one or more hydrogen atoms from monocycloalkanes or polycycloalkanes such as bicycloalkanes, tricycloalkanes, and tetracycloalkanes. Specifically, groups obtained by removing one hydrogen atom from a monocycloalkane such as cyclopentane, cyclohexane, cycloheptane, or cyclooctane, or a polycycloalkane such as adamantane, norbornane, isobornane, tricyclodecane, or tetracyclododecane may be mentioned. In particular, groups obtained by removing one hydrogen atom from cyclohexane or adamantane (which may further be substituted) are preferred.

When R^{16b} and R^{17b} do not combine with each other to form a hydrocarbon ring, the above R^{15b}, R^{16b}, and R^{17b} represent preferably a linear or branched alkyl group having 1 or more and 4 or less carbon atoms, and more preferably a linear or branched alkyl group having 2 or more and 4 or less carbon atoms, for example, from the viewpoints of a high contrast and preferable resolution and depth of focus. The above R^{19b}, R^{20b}, R^{22b}, and R^{23b} preferably represent a hydrogen atom or a methyl group.

The above R^{16b} and R^{17b} may form an aliphatic cyclic group having 5 or more and 20 or less carbon atoms together with a carbon atom to which the both are attached. Specific examples of such an alicyclic group are the groups of monocycloalkanes and polycycloalkanes such as bicycloalkanes, tricycloalkanes and tetracycloalkanes from which one or more hydrogen atoms are removed. Specific examples thereof are the groups of monocycloalkanes such as cyclopentane, cyclohexane, cycloheptane and cyclooctane and polycycloalkanes such as adamantane, norbornane, isobornane, tricyclodecane and tetracyclododecane from which one or more hydrogen atoms are removed. Particularly preferable are the groups of cyclohexane and adamantane from which one or more hydrogen atoms are removed (that may further have a substituent).

Further, in a case where an aliphatic cyclic group to be formed with the above R^{16b} and R^{17b} has a substituent on the ring skeleton thereof, examples of the substituent include a polar group such as a hydroxyl group, a carboxyl group, a cyano group and an oxygen atom (═O), and a linear or branched alkyl group having 1 or more and 4 or less carbon atoms. As the polar group, an oxygen atom (═O) is particularly preferred.

The above Y^{b} is an alicyclic group or an alkyl group; and examples thereof are the groups of monocycloalkanes and polycycloalkanes such as bicycloalkanes, tricycloalkanes and tetracycloalkanes from which one or more hydrogen atoms are removed. Specific examples thereof are the groups of monocycloalkanes such as cyclopentane, cyclohexane, cycloheptane and cyclooctane, and polycycloalkanes such as adamantane, norbornane, isobornane, tricyclodecane and tetracyclododecane from which one or more hydrogen atoms are removed. Particularly preferable is the group of adamantane from which one or more hydrogen atoms are removed (that may further have a substituent).

When the alicyclic group of the above Y^{b} has a substituent on the ring skeleton, the substituent is exemplified by polar groups such as a hydroxyl group, carboxyl group, cyano group and oxygen atom (═O), and linear or branched alkyl groups having 1 or more and 4 or less carbon atoms. The polar group is preferably an oxygen atom (═O) in particular.

When Y^{b} is an alkyl group, it is preferably a linear or branched alkyl group having 1 or more and 20 or less carbon atoms, and more preferably 6 or more and 15 or less carbon atoms. The alkyl group is an alkoxyalkyl group particularly preferable. Examples of such an alkoxyalkyl group include a 1-methoxyethyl group, 1-ethoxyethyl group, 1-n-propoxyethyl group, 1-isopropoxyethyl group, 1-n-butoxyethyl group, 1-isobutoxyethyl group, 1-tert-butoxyethyl group, 1-methoxypropyl group, 1-ethoxypropyl group, 1-methoxy-1-methylethyl group, 1-ethoxy-1-methylethyl group, and the like.

Preferable specific examples of the constituent unit represented by the above formula (bL6-1) include constituent units represented by the following formulae (bL6-1-1) to (bL6-1-33).

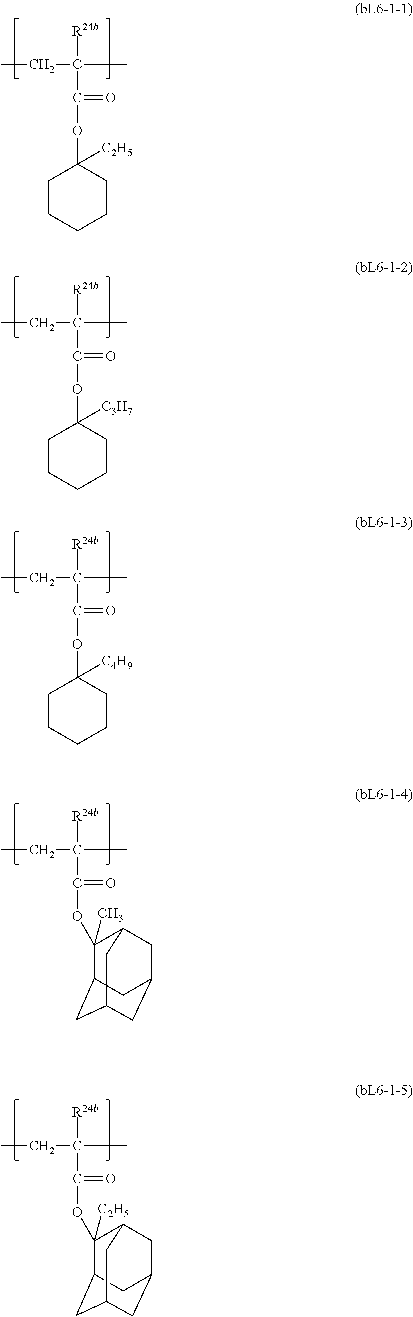

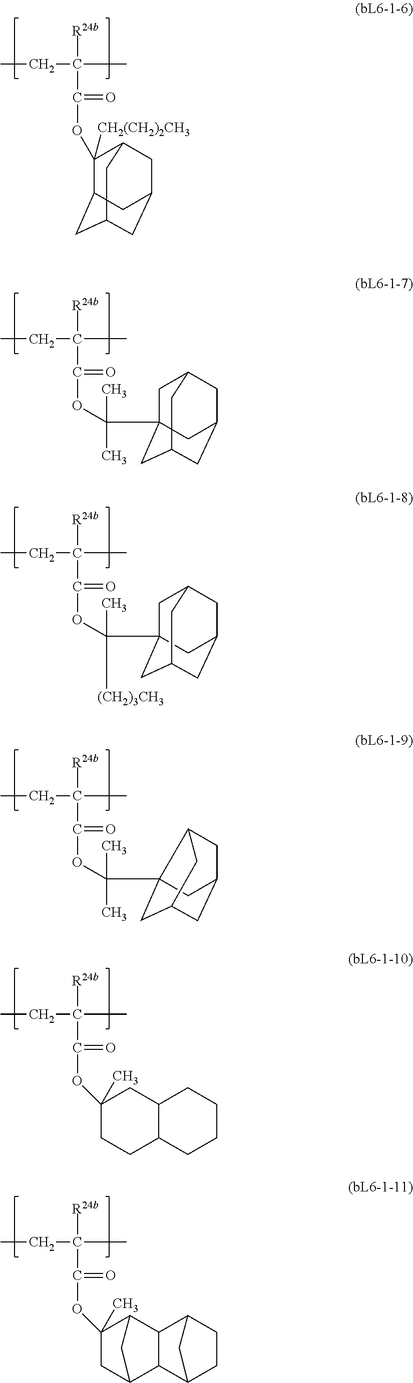

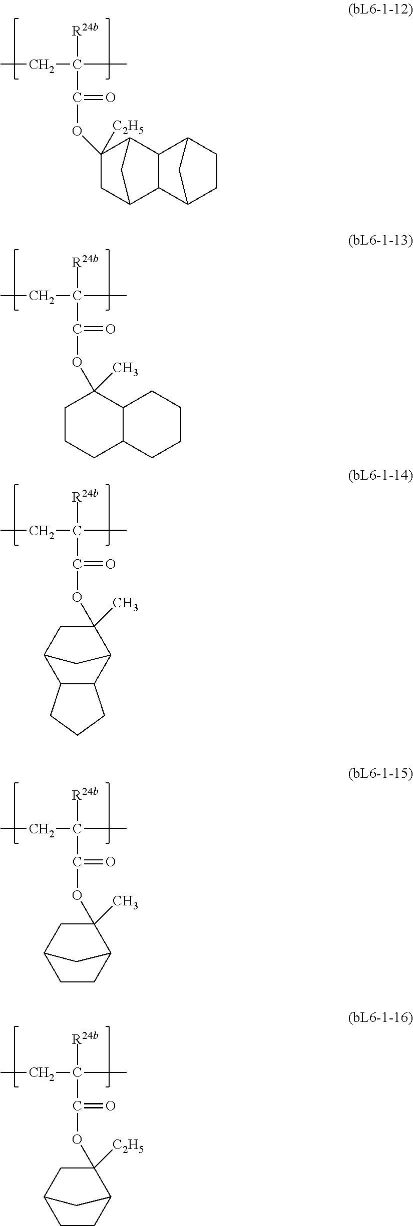

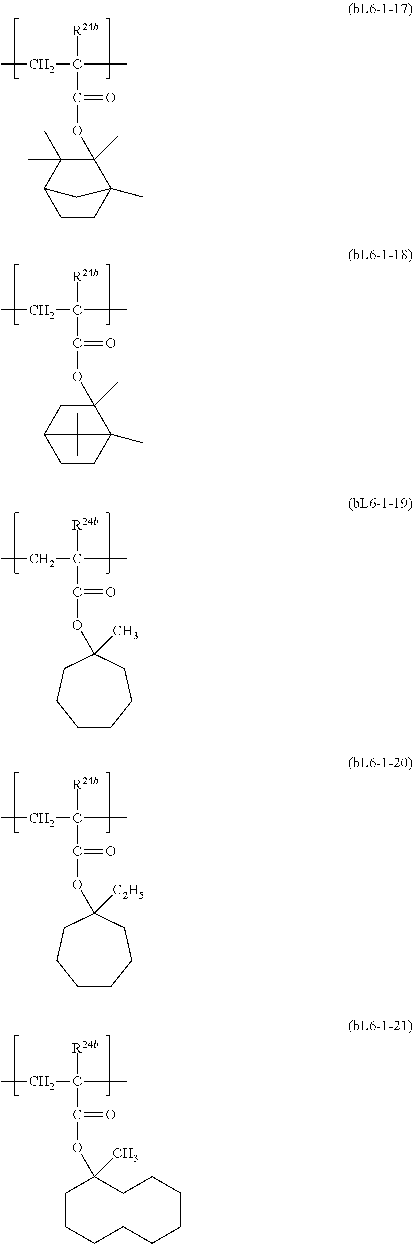

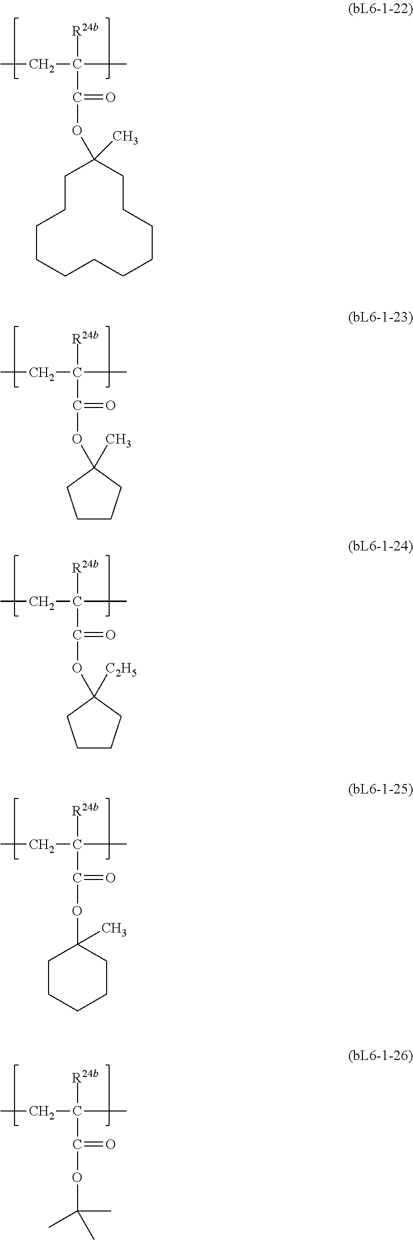

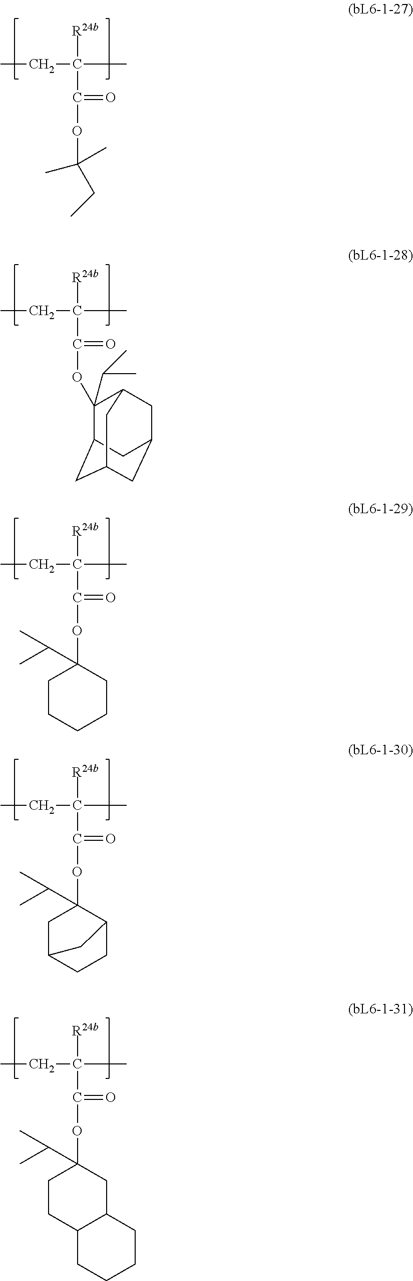

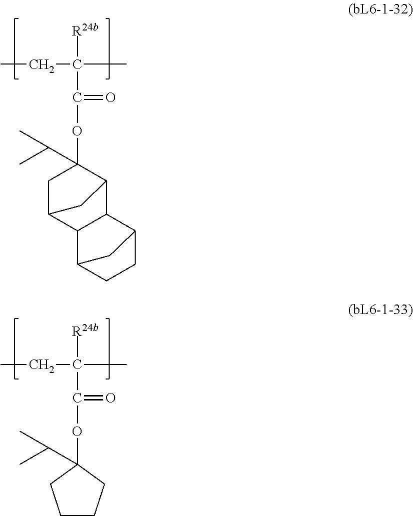

In the above formulae (bL6-1-1) to (bL6-1-33), R^{24b} represents a hydrogen atom or a methyl group.

Preferable specific examples of the constituent unit represented by the above formula (bL6-2) include constituent units represented by the following formulae (bL6-2-1) to (bL6-2-26).

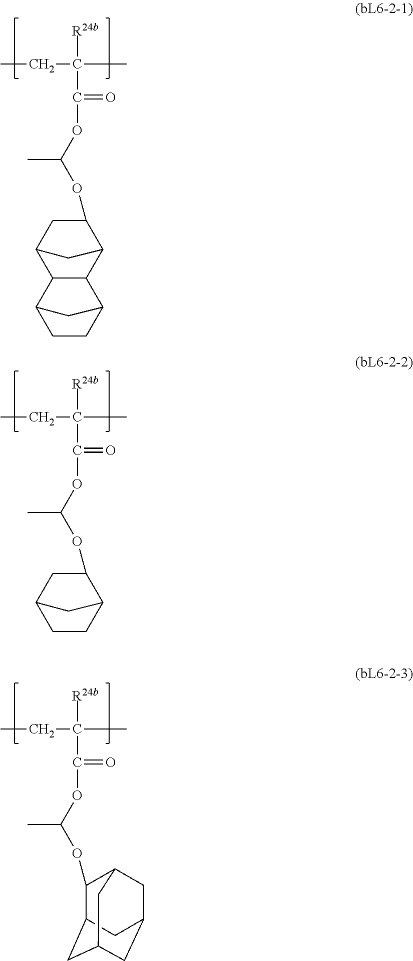

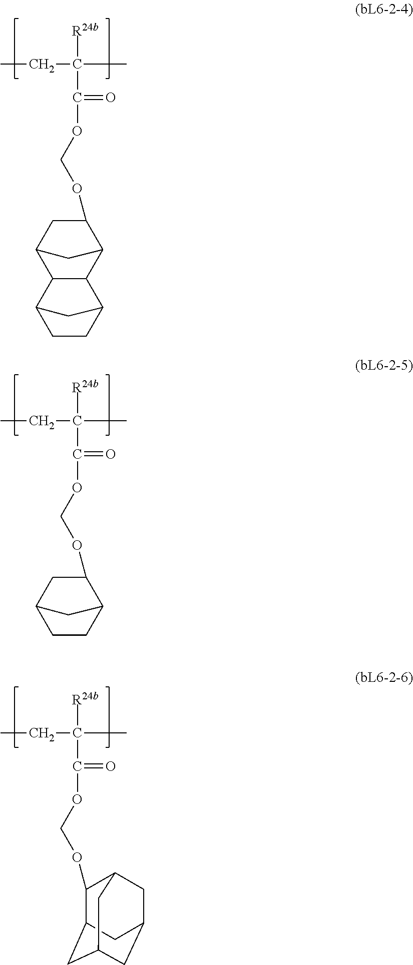

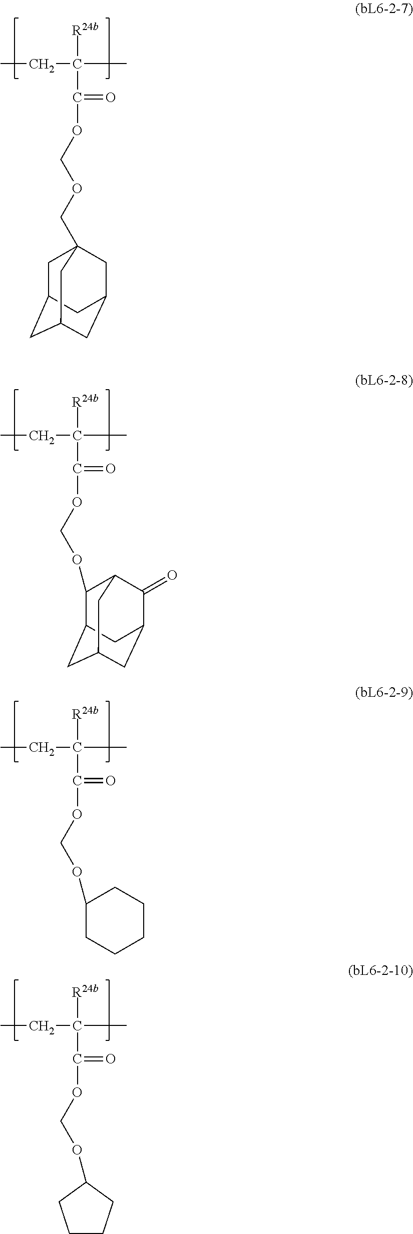

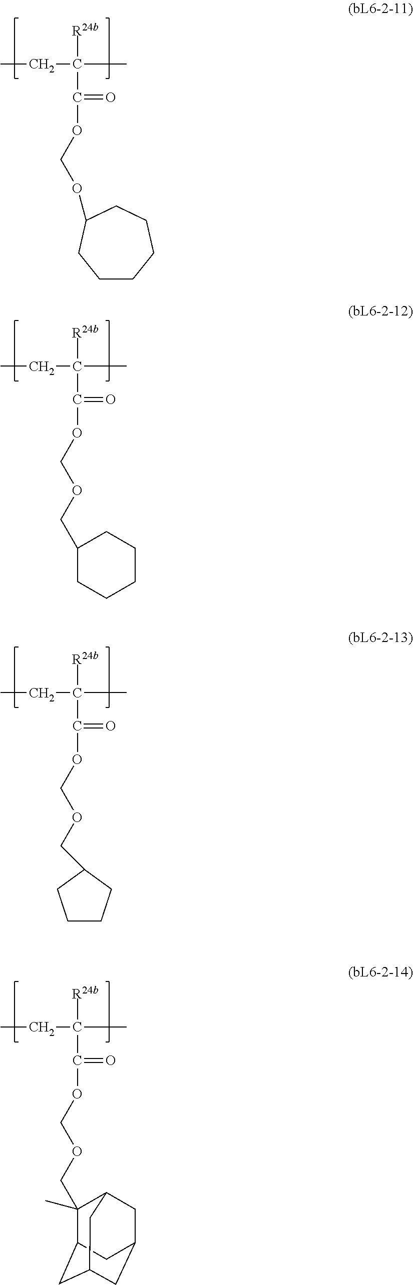

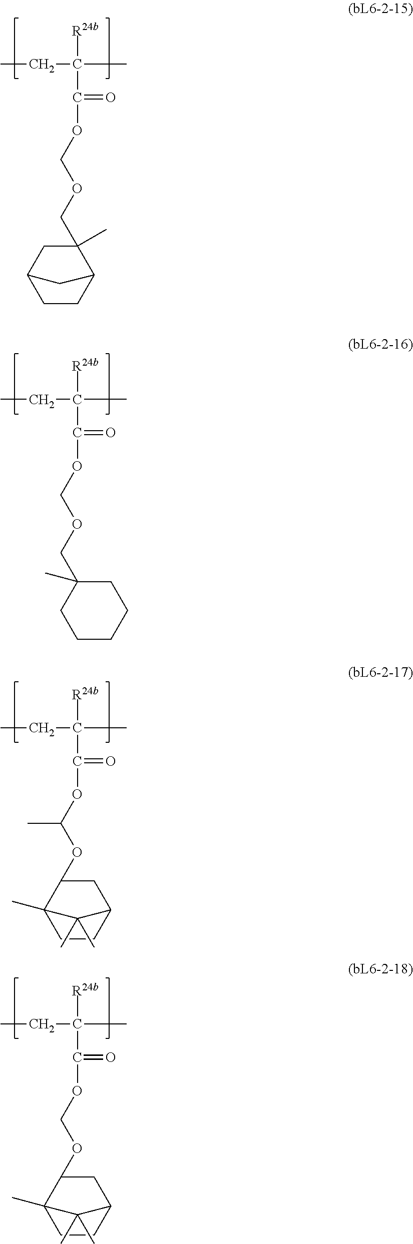

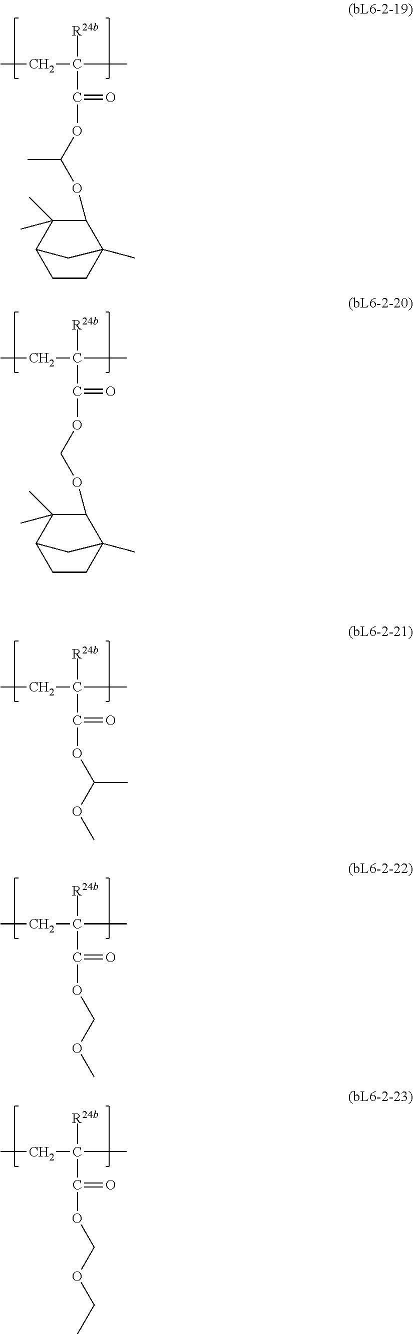

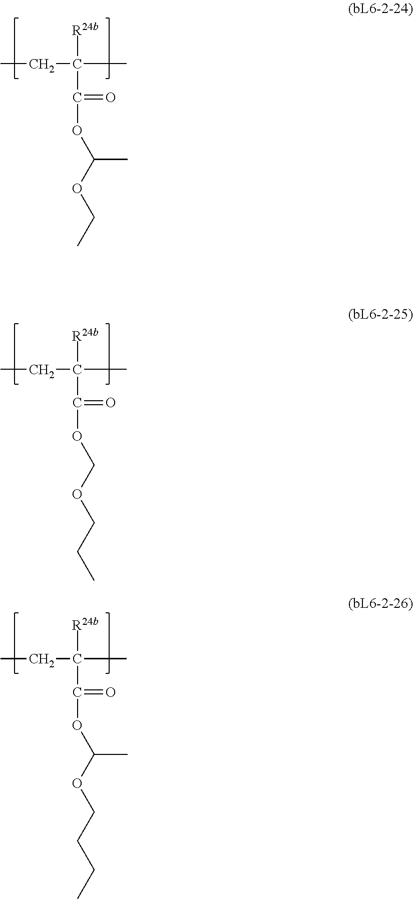

In the above formulae (bL6-2-1) to (bL6-2-26), R^{24b} represents a hydrogen atom or a methyl group.

Preferable specific examples of the constituent unit represented by the above formula (bL6-3) include constituent units represented by the following formulae (bL6-3-1) to (bL6-3-15).

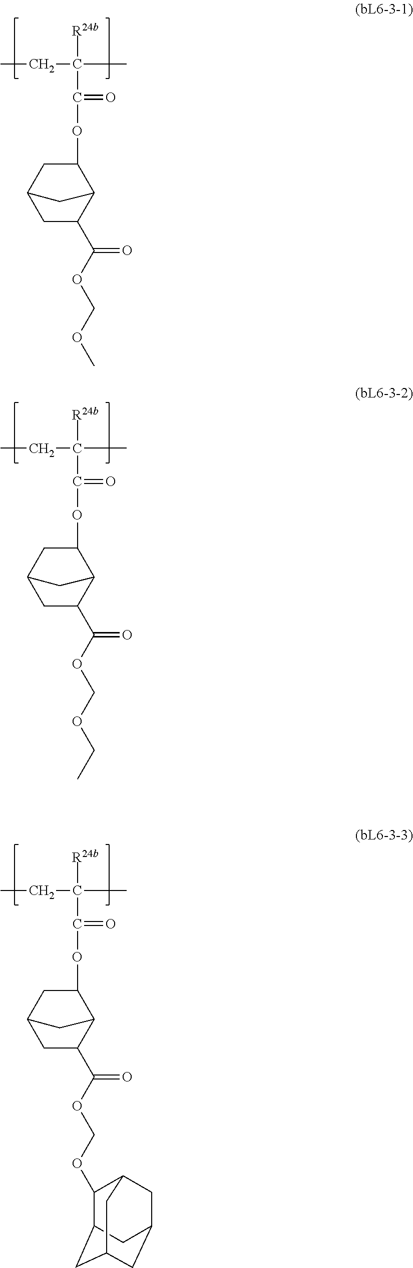

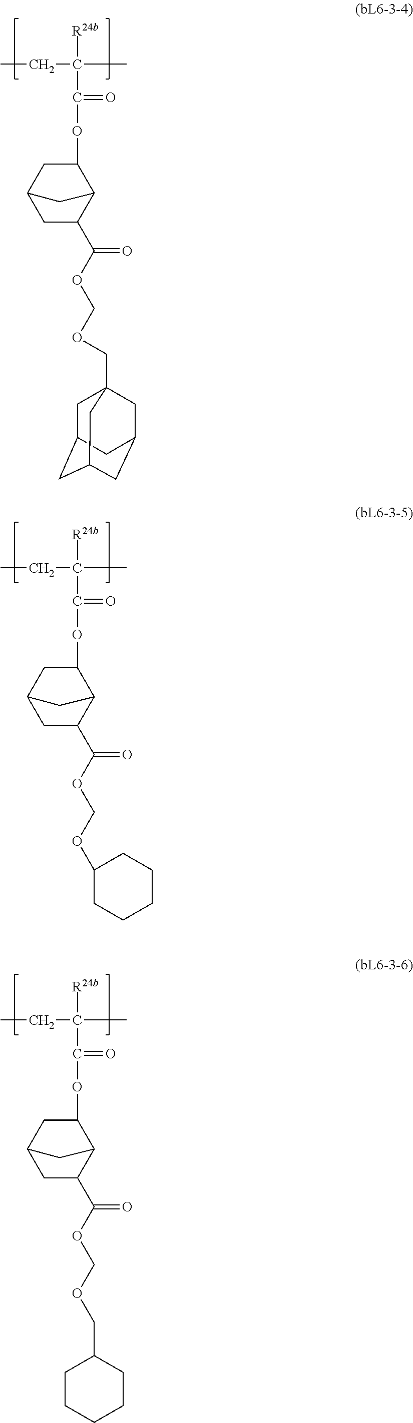

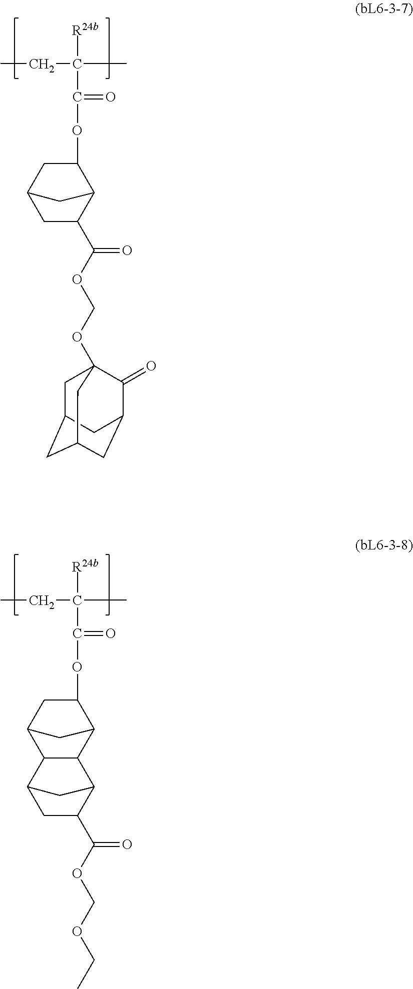

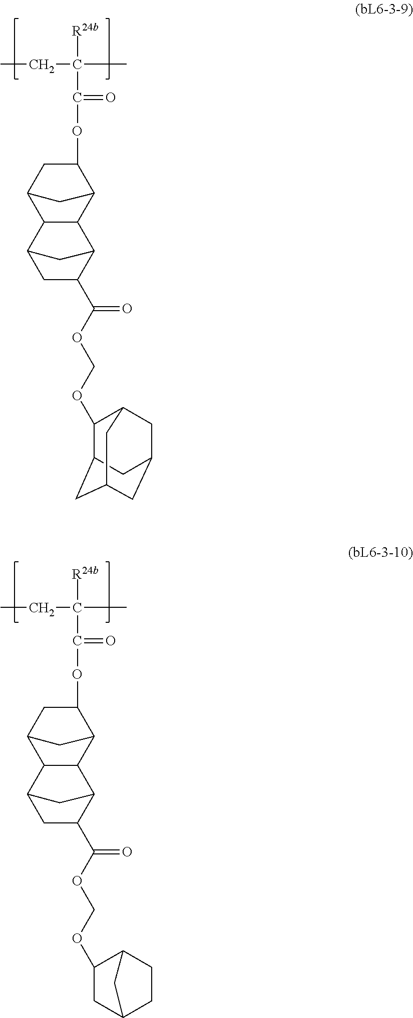

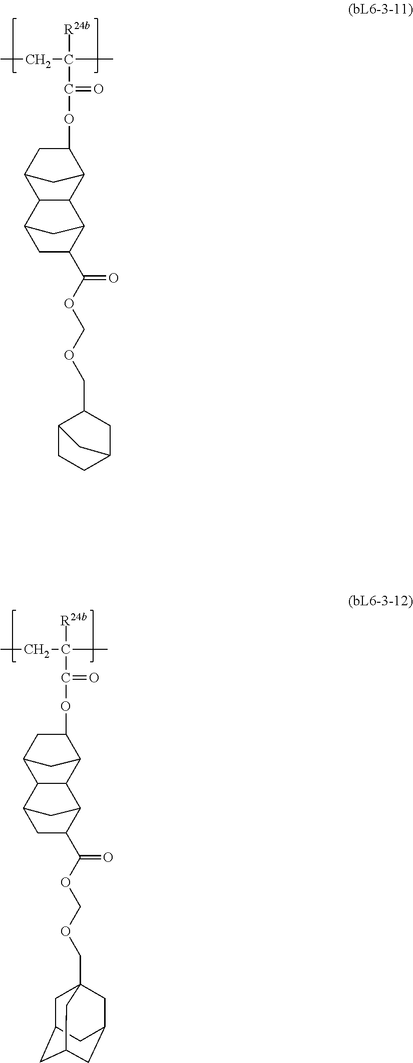

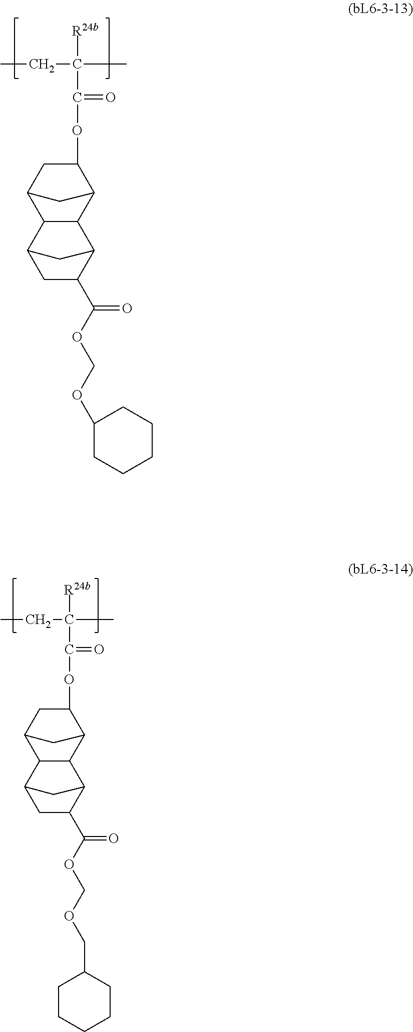

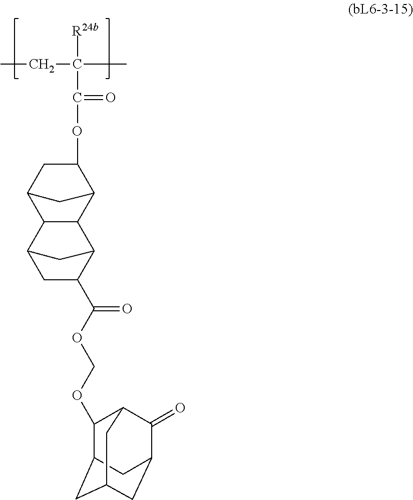

In the above formulae (bL6-3-1) to (bL6-3-15), R^{24b} represents a hydrogen atom or a methyl group.

Among the constituent units represented by the formulae (bL6-1) to (bL6-3) described above, those represented by the formula (bL6-2) are preferred in that they can be easily synthesized and relatively easily sensitized. Further, among the constituent units represented by the formula (bL6-2), those in which Y^{b} is an alkyl group are preferred, and those in which one or both of R^{19b} and R^{20b} are alkyl groups are preferred.

### (Other Constituent Unit)

Furthermore, the acrylic resin (B1a) may include other constituent unit derived from other polymerizable compound other than monomers that give the constituent unit (bL1) to the constituent unit (BL6) in order to moderately control physical or chemical properties. The polymerizable compounds that give above other constituent unit are appropriately selected from known radical polymerizable compounds and anion polymerizable compounds.

Examples of such polymerizable compounds include, for example, monocarboxylic acids such as crotonic acid; dicarboxylic acids such as maleic acid, fumaric acid, and itaconic acid; methacrylic acid derivatives having a carboxylic group and an ester bond such as 2-methacryloyloxyethyl succinate, 2-methacryloyloxyethyl maleate, 2-methacryloyloxyethyl phthalate, and 2-methacryloyloxyethyl hexahydrophthalate; (meth)acrylic acid aralkyl esters such as benzyl (meth)acrylate; dicarboxylic acid diesters such as diethyl maleate, and dibutyl fumarate; vinyl group-containing aromatic compounds such as styrene, α-methylstyrene, chlorostyrene, chloromethylstyrene, vinyltoluene, hydroxystyrene, α-methylhydroxystyrene, and α-ethylhydroxystyrene; vinyl group-containing aliphatic compounds such as vinyl acetate; conjugated diolefins such as butadiene, and isoprene; nitrile group-containing polymerizable compounds such as acrylonitrile, and methacrylonitrile; chlorine-containing polymerizable compounds such as vinyl chloride and vinylidene chloride; amide bond-containing polymerizable compounds such as acrylamide and methacrylamide; and the like.

A ratio of a mass of the above-described acrylic resin (B1a) relative to the mass of the resin (B) is not particularly limited as long as the objects of the present invention are not impaired. The ratio of a mass of the above-described acrylic resin (B1a) may be 50% by mass or more, 70% by mass or more, 80% by mass or more, 90% by mass or more, or 100% by mass relative to the mass of the resin (B).

### [Acrylic Resin (B1A)]

The resin (B) may include an acrylic resin (B1A) which is an acrylic resin other than the acrylic resin (B1a). The acrylic resin (B1A) is not particularly limited as long as the acrylic resin (B1A) in an acrylic resin that corresponds to the resin (B). The acrylic resin (B1A) may be an acrylic resin that does not correspond to the acrylic resin (B1a), but is composed of various constituent units described above for the acrylic resin (B1a). The acrylic resin (B1A) may be a homopolymer or a copolymer.

### [Novolak Resin (B2)]

As the novolak resin (B2), a resin including the constituent unit represented by the following formula (b1) may be used.

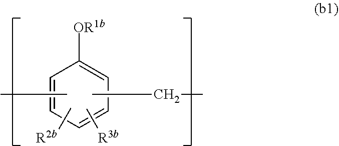

In the formula (b1), R^{1b} represents an acid-dissociable dissolution-inhibiting group, and R^{2b} and R^{3b} each independently represent a hydrogen atom or an alkyl group having 1 or more and 6 or less carbon atoms.

The acid-dissociable dissolution-inhibiting group represented by the above R^{1b} is preferably a group represented by the following formula (b2) or (b3), a linear, branched or cyclic alkyl group having 1 or more and 6 or less carbon atoms, a vinyloxyethyl group, a tetrahydropyranyl group, a tetrahydrofuranyl group, or a trialkylsilyl group.

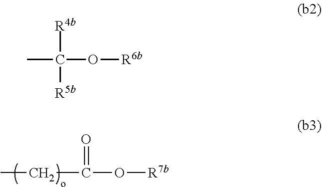

In the above formulae (b2) and (b3), R^{4b} and R^{5b} each independently represent a hydrogen atom, or a linear or branched alkyl group having 1 or more and 6 or less carbon atoms, R^{6b} represents a linear, branched or cyclic alkyl group having 1 or more and 10 or less carbon atoms, R^{7b} represents a linear, branched or cyclic alkyl group having 1 or more and 6 or less carbon atoms, and o represents 0 or 1.

Examples of the above linear or branched alkyl group include a methyl group, an ethyl group, a propyl group, an isopropyl group, an n-butyl group, an isobutyl group, a tert-butyl group, a pentyl group, an isopentyl group, a neopentyl group, and the like. Also, examples of the above cyclic alkyl group include a cyclopentyl group, a cyclohexyl group, and the like.

Specific examples of the acid-dissociable dissolution-inhibiting group represented by the above formula (b2) include methoxyethyl group, ethoxyethyl group, n-propoxyethyl group, isopropoxyethyl group, n-butoxyethyl group, isobutoxyethyl group, tert-butoxyethyl group, cyclohexyloxyethyl group, methoxypropyl group, ethoxypropyl group, 1-methoxy-1-methylethyl group, 1-ethoxy-1-methylethyl group, and the like. Furthermore, specific examples of the acid-dissociable dissolution-inhibiting group represented by the above formula (b3) include tert-butoxycarbonyl group, tert-butoxycarbonylmethyl group, and the like. Examples of the above trialkylsilyl group include a group having alkyl groups respectively having 1 or more and 6 or less carbon atoms such as trimethylsilyl group and tri-tert-butyldimethylsilyl group.

### [Polyhydroxystyrene Resin (B3)]

As the polyhydroxystyrene resin (B3), a resin including a constituent unit represented by the following formula (b4) may be used.

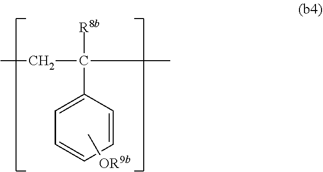

In the above formula (b4), R^{8b} represents a hydrogen atom or an alkyl group having 1 or more and 6 or less carbon atoms, and R^{9b} represents an acid-dissociable dissolution-inhibiting group.

The above alkyl group having 1 or more and 6 or less carbon atoms may include, for example, linear, branched or cyclic alkyl groups having 1 or more and 6 or less carbon atoms. Examples of the linear or branched alkyl group include methyl group, ethyl group, propyl group, isopropyl group, n-butyl group, isobutyl group, tert-butyl group, pentyl group, isopentyl group, neopentyl group, and the like. Examples of the cyclic alkyl group include a cyclopentyl group and cyclohexyl group.

The acid-dissociable dissolution-inhibiting group represented by the above R^{9b} may be same as those exemplified in terms of the above formulae (b2) and (b3).

Furthermore, the polyhydroxystyrene resin (B3) may include another polymerizable compound as a constituent unit in order to moderately control physical or chemical properties. The polymerizable compound is exemplified by conventional radical polymerizable compounds and anion polymerizable compounds. Examples of the polymerizable compound include monocarboxylic acids such as crotonic acid; dicarboxylic acids such as maleic acid, fumaric acid and itaconic acid; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; and the like.

The weight-average molecular weight of the resin (B) described above in terms of polystyrene is preferably 10000 or more and 600000 or less, more preferably 20000 or more and 400000 or less, and even more preferably 30000 or more and 300000 or less. A weight-average molecular weight within these ranges allows a photosensitive layer made of the first photosensitive composition to maintain sufficient strength without reducing detachability from a substrate, and can further prevent a swelled profile and crack generation when plating.

It is also preferred that the resin (B) has a dispersivity of 1.05 or more. Dispersivity herein indicates a value of a weight average molecular weight divided by a number average molecular weight. A dispersivity in the range described above can avoid problems with respect to stress resistance on intended plating or possible swelling of metal layers resulting from the plating process.

The content of the resin (B) is preferably 5% by mass or more and 60% by mass or less relative to the total mass of the first photosensitive composition. Furthermore, the content of the resin (B) is preferably 5% by mass or more and 98% by mass or less, and more preferably 10% by mass or more and 95% by mass or less relative to the total solid mass of the first photosensitive composition.

### {Alkali-Soluble Resin (C)}

It is preferred that the first photosensitive composition further contains an alkali-soluble resin (C) in order to improve crack resistance. The alkali-soluble resin as referred to herein may be determined as follows. A solution of the resin having a resin concentration of 20% by mass (solvent: propylene glycol monomethyl ether acetate) is used to form a resin film having a thickness of 1 μm on a substrate, and immersed in an aqueous 2.38% by mass TMAH (tetramethylammonium hydroxide) solution for 1 min. When the resin was dissolved in an amount of 0.01 μm or more, the resin is defined as being alkali soluble. As the alkali-soluble resin (C), at least one selected from the group consisting of novolak resin (C1), polyhydroxystyrene resin (C2), and acrylic resin (C3) are preferable.

### [Novolak Resin (C1)]

A novolak resin is prepared by addition condensation of, for example, aromatic compounds having a phenolic hydroxyl group (hereinafter, merely referred to as “phenols”) and aldehydes in the presence of an acid catalyst.

Examples of the above phenols include phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethyl phenol, 3,4,5-trimethyl phenol, p-phenylphenol, resorcinol, hydroquinone, hydroquinone monomethyl ether, pyrogallol, phloroglycinol, hydroxydiphenyl, bisphenol A, gallic acid, gallic acid ester, α-naphthol, β-naphthol, and the like. Examples of the above aldehydes include formaldehyde, furfural, benzaldehyde, nitrobenzaldehyde, acetaldehyde, and the like. The catalyst used in the addition condensation reaction is not particularly limited, and examples thereof include hydrochloric acid, nitric acid, sulfuric acid, formic acid, oxalic acid, acetic acid, etc., for acid catalyst.

The flexibility of the novolak resins can be enhanced more when o-cresol is used, a hydrogen atom of a hydroxyl group in the resins is substituted with other substituents, or bulky aldehydes are used.

The mass average molecular weight of novolak resin (C1) is not particularly limited as long as the purpose of the present invention is not impaired, but the weight average molecular weight is preferably 1,000 or more and 50,000 or less.

### [Polyhydroxystyrene Resin (C2)]

The hydroxystyrene compound to constitute the polyhydroxystyrene resin (C2) is exemplified by p-hydroxystyrene, α-methylhydroxystyrene, α-ethylhydroxystyrene, and the like. Furthermore, the polyhydroxystyrene resin (C2) is preferably prepared to give a copolymer with a styrene resin. Examples of the styrene compound to constitute such a styrene resin include styrene, chlorostyrene, chloromethylstyrene, vinyltoluene, α-methylstyrene, and the like.

The mass average molecular weight of the polyhydroxystyrene resin (C2) is not particularly limited as long as the purpose of the present invention is not impaired, but the weight average molecular weight is preferably 1,000 or more and 50,000 or less.

### [Acrylic Resin (C3)]

It is preferable that the acrylic resin (C3) includes a constituent unit derived from a polymerizable compound having an ether bond and a constituent unit derived from a polymerizable compound having a carboxyl group.

Examples of the above polymerizable compound having an ether bond include (meth)acrylic acid derivatives having an ether bond and an ester bond such as 2-methoxyethyl (meth)acrylate, methoxytriethylene glycol (meth)acrylate, 3-methoxybutyl (meth)acrylate, ethylcarbitol (meth)acrylate, phenoxypolyethylene glycol (meth)acrylate, methoxypolypropylene glycol (meth)acrylate, tetrahydrofurfuryl (meth)acrylate, and the like. The above polymerizable compound having an ether bond is preferably, 2-methoxyethyl acrylate, and methoxytriethylene glycol acrylate. These polymerizable compounds may be used alone, or in combinations of two or more.

Examples of the above polymerizable compound having a carboxy group include monocarboxylic acids such as acrylic acid, methacrylic acid and crotonic acid; dicarboxylic acids such as maleic acid, fumaric acid and itaconic acid; compounds having a carboxy group and an ester bond such as 2-methacryloyloxyethyl succinic acid, 2-methacryloyloxyethyl maleic acid, 2-methacryloyloxyethyl phthalic acid, 2-methacryloyloxyethyl hexahydrophthalic acid and the like. The above polymerizable compound having a carboxy group is preferably, acrylic acid and methacrylic acid. These polymerizable compounds may be used alone, or in combinations of two or more thereof.

The weight average molecular weight of the acrylic resin (C3) is not particularly limited as long as the purpose of the present invention is not impaired, but the mass average molecular weight is preferably 50,000 or more and 800,000 or less.

The content of the alkali-soluble resin (C) is such that when the total amount of the above resin (B) and the alkali-soluble resin (C) is taken as 100 parts by mass, the content is preferably 0 parts by mass or more and 80 parts by mass or less, and more preferably 0 parts by mass or more and 60 parts by mass or less. By setting the content of the alkali-soluble resin (C) to the range described above, there is a tendency for resistance to cracking to increase, and film loss at the time of development can be prevented.

### {Sulfur-Containing Compound (D)}

In the case of the first photosensitive composition being used in pattern formation on a metal substrate, the photosensitive preferably contains a sulfur-containing compound (D). The sulfur-containing compound (D) is a compound including a sulfur atom which can coordinate to the metal. It should be noted that, for a compound which can produce two or more tautomers, in the case of at least one tautomer containing a sulfur atom which coordinates to a metal constituting the surface of the metal substrate, this compound corresponds to the sulfur-containing compound. In the case of forming a patterned resist film used as a template for plating on the surface consisting of metal such as Cu, defects in the cross-sectional shape such as footing (hemming) may occur. As mentioned above, in the case of using the above-mentioned first photosensitive composition, the formation of a patterned resist film having preferable rectangularity of the cross-sectional shape is easy. On the other hand, with the purpose of suppressing defects in the cross-sectional shape more reliably, it is preferable for the first photosensitive composition to contain the sulfur-containing compound (D). In the case of the first photosensitive composition containing the sulfur-containing compound (D), the occurrence of defects in the cross-sectional shape such as footing tends to be more reliably suppressed, even in a case of forming a patterned resist film on a surface consisting of metal of a substrate.

The sulfur atom that can coordinate with metal is included in a sulfur-containing compound as, for example, a mercapto group (—SH), a thiocarboxy group (—CO—SH), a dithiocarboxy group (—CS—SH), a thiocarbonyl group (—CS—), and the like. From the viewpoint of easiness in coordinating with metal and being excellent in suppressing footing, the sulfur-containing compound preferably includes a mercapto group.

Suitable examples of the sulfur-containing compound having a mercapto group include compounds represented by the following formula (d1).

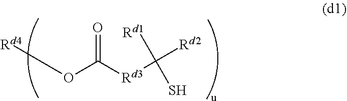

(In the formula (d1), R^{d1} and R^{d2} each independently represent a hydrogen atom or an alkyl group, R^{d3} represents a single bond or an alkylene group, R^{d4} represents a u-valence aliphatic group which may include an atom other than carbon, and u is an integer of 2 or more and 4 or less.)

When R^{d1} and R^{d2} are an alkyl group, the alkyl group may be linear or branched, and is preferably linear. When R^{d1} and R^{d2} are an alkyl group, the number of carbon atoms in the alkyl group is not particularly limited within a range where the objects of the present invention are not impaired. The number of carbon atoms in the alkyl group is preferably 1 or more and 4 or less, particularly preferably 1 or 2, and the most preferably 1. As the combination of R^{d1} and R^{d2}, preferably, one is a hydrogen atom and the other is an alkyl group, and particularly preferably one is a hydrogen atom and the other is a methyl group.

When R^{d3} is an alkylene group, the alkylene group may be linear or branched, and is preferably linear. When R^{d3} is an alkylene group, the number of carbon atoms in the alkylene group is not particularly limited within a range where the objects of the present invention are not impaired. The number of carbon atoms in the alkylene group is preferably 1 or more and 10 or less, more preferably 1 or more and 5 or less, particularly preferably 1 or 2, and the most preferably 1.

R^{d4} is an aliphatic group having two or more and four or less valences and which may include an atom other than carbon atom. Examples of the atoms which may be included in R^{d4} include a nitrogen atom, an oxygen atom, a sulfur atom, a fluorine atom, a chlorine atom, a bromine atom, an iodine atom, and the like. A structure of the aliphatic group as R^{d4} may be linear or branched, or may be cyclic, and a structure combining these structures.

Among the compounds represented by the formula (d1), a compound represented by the following formula (d2) is more preferable.

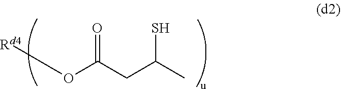

(In the formula (d2), R^{d4} and u are the same as those in the formula (d1).)

Among the compounds represented by the above formula (d2), the following compounds are preferable.

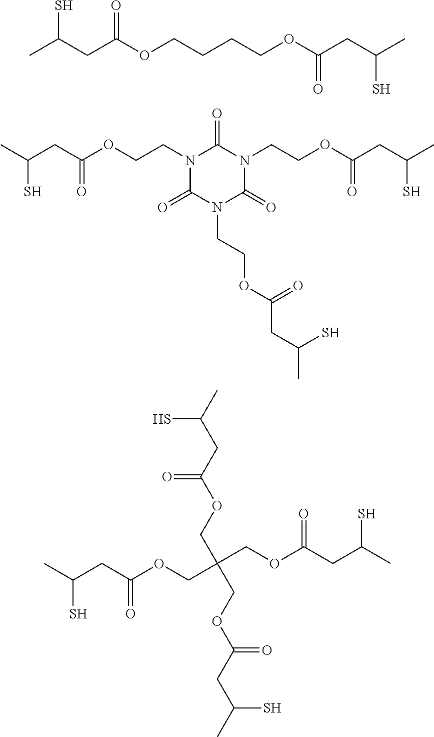

Compounds represented by the following formulae (d3-L1) to (d3-L7) are also preferable examples as the sulfur-containing compound having a mercapto group.

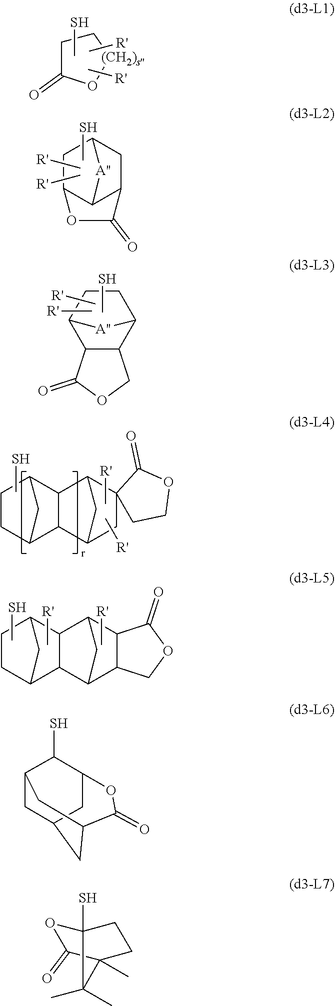

(In the formulae (d3-L1) to (d3-L7), R′, s″, A″, and r are the same as in the formulae (bL4-L1) to (bL4-L7) described for the acrylic resin (B1a).)

Suitable specific examples of the mercapto compound represented by the above formulae (d3-L1) to (d3-L7) include the following compounds.

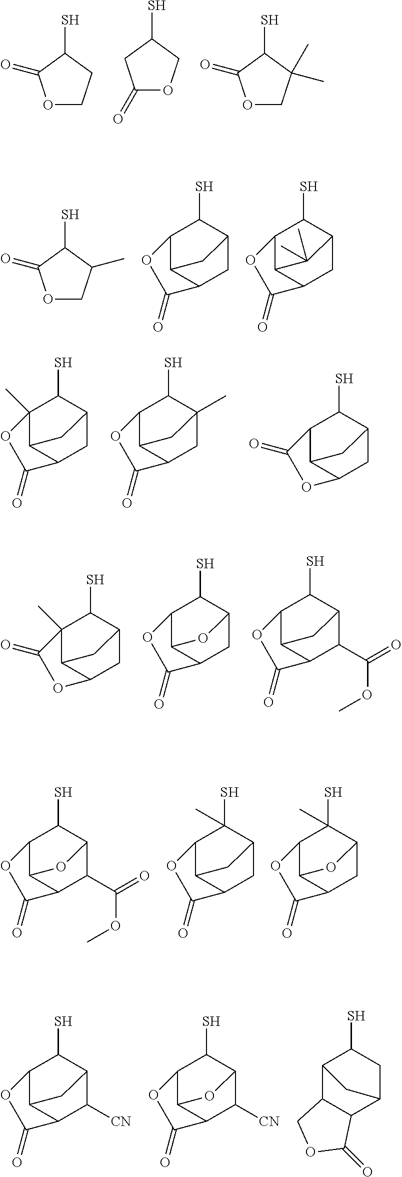

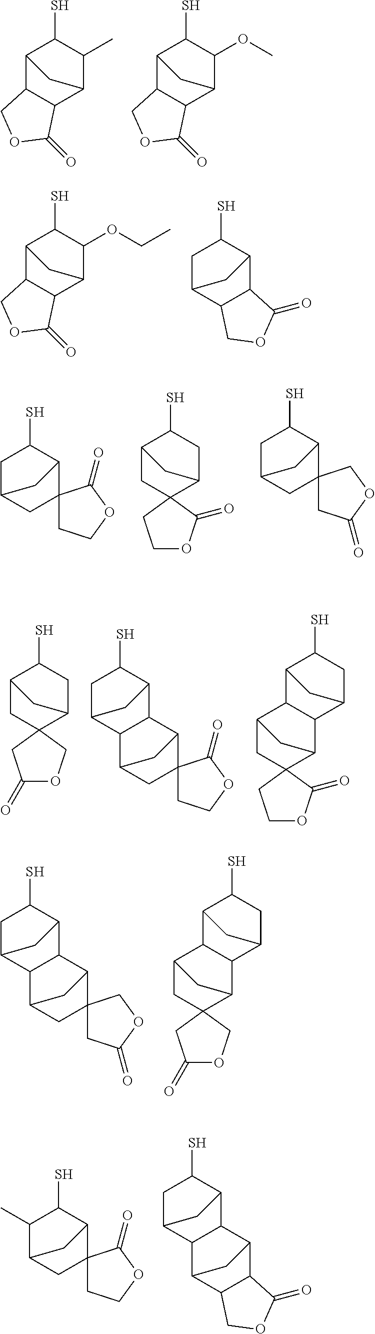

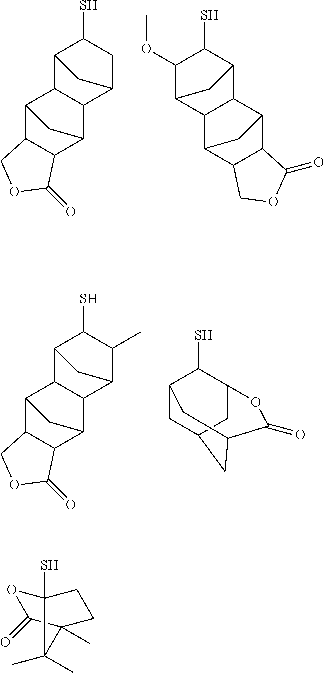

Compounds represented by the following formulae (d3-1) to (d3-7) are also preferable examples as the sulfur-containing compound having a mercapto group.

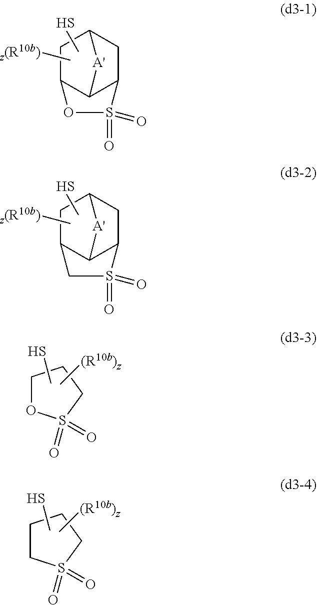

(In the formulae (d3-1) to (d3-4), definitions of abbreviations are the same as mentioned for the formulae (3-1) to (3-4) described for acrylic resin (B1a).)

Suitable specific examples of the mercapto compound represented by the above formulae (d3-1) to (d3-4) include the following compounds.

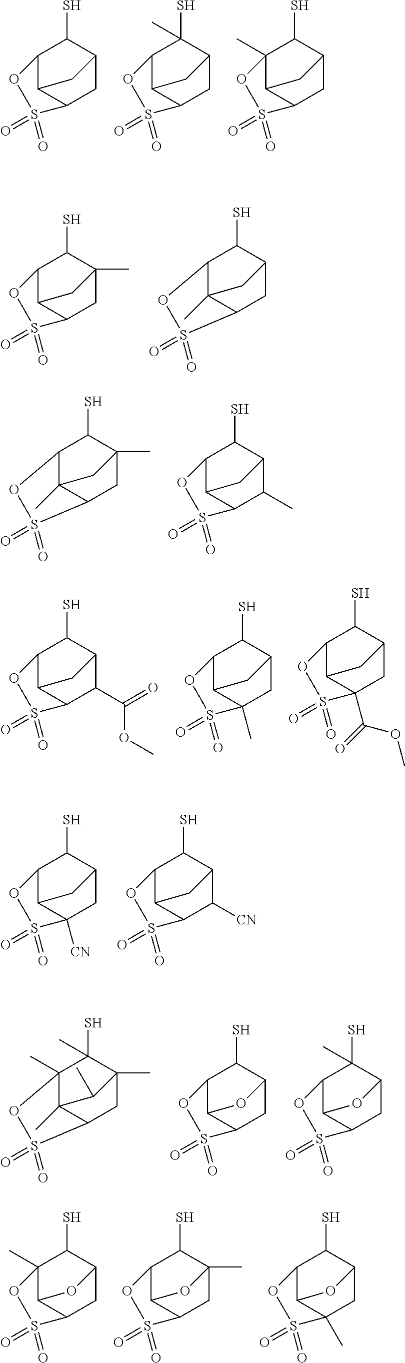

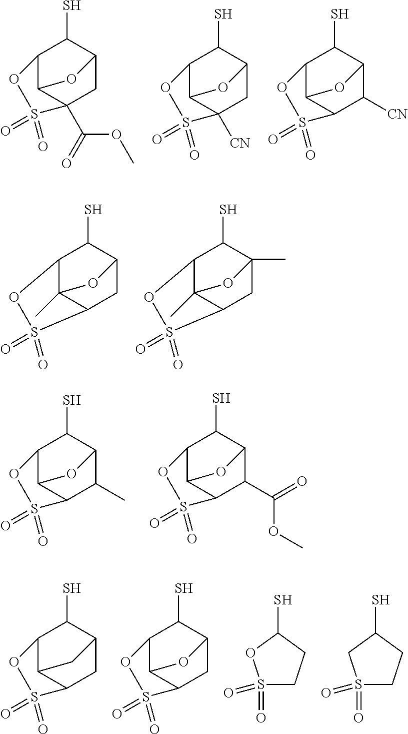

Furthermore, preferable examples of the compound having a mercapto group include compounds represented by the following formula (d4).

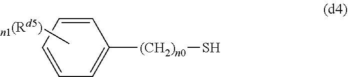

(In the formula (d4), R^{d5} is a group selected from the group consisting of a hydroxyl group, an alkyl group having 1 or more 4 or less carbon atoms, an alkoxy group having 1 or more 4 or less carbon atoms, an alkylthio group having 1 or more and 4 or less carbon atoms, a hydroxyalkyl group having 1 or more and 4 or less carbon atoms, a mercapto alkyl group having 1 or more and 4 or less carbon atoms, a halogenated alkyl group having 1 or more and 4 or less carbon atoms, and a halogen atom, n1 is an integer of 0 or more and 3 or less, n0 is an integer of 0 or more and 3 or less, when n1 is 2 or 3, R^{d5} may be the same as or different from each other.)

Specific examples when R^{d5} is an alkyl group which may have a hydroxyl group having 1 or more 4 or less carbon atoms include a methyl group, an ethyl group, an n-propyl group, an isopropyl group, an n-butyl group, an isobutyl group, a sec-butyl group, and a tert-butyl group. Among these alkyl groups, a methyl group, a hydroxymethyl group, and an ethyl group are preferable.

Specific examples when R^{d5} is an alkoxy group having 1 or more 4 or less carbon atoms include a methoxy group, an ethoxy group, an n-propyloxy group, an isopropyloxy group, an n-butyloxy group, an isobutyloxy group, a sec-butyloxy group, and a tert-butyloxy group. Among these alkoxy groups, a methoxy group and an ethoxy group are preferable, and a methoxy group is more preferable.

Specific examples when R^{d5} is an alkylthio group having 1 or more 4 or less carbon atoms include a methylthio group, an ethylthio group, an n-propylthio group, an isopropylthio group, an n-butylthio group, an isobutylthio, a sec-butylthio group, and a tert-butylthio group. Among these alkylthio groups, a methylthio group, and an ethylthio group are preferable, and a methylthio group is more preferable.

Specific examples when R^{d5} is a hydroxyalkyl group having 1 or more 4 or less carbon atoms include hydroxymethyl group, 2-hydroxyethyl group, 1-hydroxyethyl group, 3-hydroxy-n-propyl group, and 4-hydroxy-n-butyl group, and the like. Among these hydroxyalkyl groups, hydroxymethyl group, 2-hydroxyethyl group, and 1-hydroxyethyl group are preferable, and hydroxymethyl group is more preferable.

Specific examples when R^{d5} is a mercapto alkyl group having 1 or more 4 or less carbon atoms include mercapto methyl group, 2-mercapto ethyl group, 1-mercapto ethyl group, 3-mercapto-n-propyl group, 4-mercapto-n-butyl group, and the like. Among these mercapto alkyl groups, mercapto methyl group, 2-mercapto ethyl group, and 1-mercapto ethyl group are preferable, and mercapto methyl group is more preferable.

When R^{d5} is an alkyl halide group having 1 or more 4 or less carbon atoms, examples of the halogen atom included in the alkyl halide group include fluorine, chlorine, bromine, iodine, and the like. Specific examples when R^{d5} is an alkyl halide group having 1 or more 4 or less carbon atoms include chloromethyl group, bromomethyl group, iodomethyl group, fluoromethyl group, dichloromethyl group, dibromomethyl group, difluoromethyl group, trichloromethyl group, tribromomethyl group, trifluoromethyl group, 2-chloroethyl group, 2-bromoethyl group, 2-fluoroethyl group, 1,2-dichloroethyl group, 2,2-difluoroethyl group, 1-chloro-2-fluoroethyl group, 3-chloro-n-propyl group, 3-bromon-propyl group, 3-fluoro-n-propyl group, 4-chloro-n-butyl group, and the like. Among these alkyl halide groups, chloromethyl group, bromomethyl group, iodomethyl group, fluoromethyl group, dichloromethyl group, dibromomethyl group, difluoromethyl group, trichloromethyl group, tribromomethyl group, and trifluoromethyl group are preferable, and chloromethyl group, dichloromethyl group, trichloromethyl group, and trifluoromethyl group are more preferable.

Specific examples when R^{d5} is a halogen atom include fluorine, chlorine, bromine, or iodine.

In the formula (d4), n1 is an integer of 0 or more and 3 or less, and 1 is more preferable. When n1 is 2 or 3, a plurality of R^{e5} may be the same as or different from each other.

In the compound represented by the formula (d4), a substituted position of R^{d5} on a benzene ring is not particularly limited. The substituted position of R^{d5} on a benzene ring is preferably a meta position or a para position with respect to the bond position of —(CH₂)ₙ₀—SH.

The compound represented by the formula (d4) is preferably a compound having at least one group selected from the group consisting of an alkyl group, a hydroxyalkyl group, and a mercapto alkyl group as R^{d5}, and more preferably a compound having one group selected from the group consisting of an alkyl group, a hydroxyalkyl group, and a mercapto alkyl group as R^{d5}. When the compound represented by the formula (d4) has one group selected from the group consisting of an alkyl group, a hydroxyalkyl group, and a mercapto alkyl group as R^{d5}, the substituted position on the benzene ring of the alkyl group, the hydroxyalkyl group, or the mercapto alkyl group is preferably a meta position or a para position with respect to the bond position of —(CH₂)ₙ₀—SH, and more preferably a para position.

In the formula (d4), n0 is an integer of 0 or more 3 or less. From the viewpoint that preparation or availability of a compound is easy, n0 is preferably 0 or 1, and more preferably 0.

Specific examples of the compound represented by the formula (d4) include p-mercaptophenol, p-thiocresol, m-thiocresol, 4-(methylthio)benzenethiol, 4-methoxybenzenethiol, 3-methoxybenzenethiol, 4-ethoxybenzenethiol, 4-isopropyloxy benzenethiol, 4-tert-butoxybenzenethiol, 3,4-dimethoxy benzenethiol, 3,4,5-trimethoxybenzenethiol, 4-ethylbenzenethiol, 4-isopropyl benzenethiol, 4-n-butylbenzenethiol, 4-tert-butylbenzenethiol, 3-ethylbenzenethiol, 3-isopropyl benzenethiol, 3-n-butylbenzenethiol, 3-tert-butylbenzenethiol, 3,5-dimethyl benzenethiol, 3,4-dimethyl benzenethiol, 3-tert-butyl-4-methylbenzenethiol, 3-tert-4-methylbenzenethiol, 3-tert-butyl-5-methylbenzenethiol, 4-tert-butyl-3-methylbenzenethiol, 4-mercaptobenzyl alcohol, 3-mercaptobenzyl alcohol, 4-(mercaptomethyl)phenol, 3-(mercaptomethyl)phenol, 1,4-di(mercaptomethyl)phenol, 1,3-di(mercaptomethyl)phenol, 4-fluorobenzenethiol, 3-fluorobenzenethiol, 4-chlorobenzenethiol, 3-chlorobenzenethiol, 4-bromobenzenethiol, 4-iodobenzenethiol, 3-bromobenzenethiol, 3,4-dichlorobenzenethiol, 3,5-dichlorobenzenethiol, 3,4-difluorobenzenethiol, 3,5-difluorobenzenethiol, 4-mercaptocatechol, 2,6-di-tert-butyl-4-mercaptophenol, 3,5-di-tert-butyl-4-methoxybenzenethiol, 4-bromo-3-methylbenzenethiol, 4-(trifluoromethyl)benzenethiol, 3-(trifluoromethyl)benzenethiol, 3,5-bis(trifluoromethyl)benzenethiol, 4-methylthiobenzenethiol, 4-ethylthiobenzenethiol, 4-n-butylthiobenzenethiol, and 4-tert-butylthiobenzenethiol, and the like.

Furthermore, examples of the sulfur-containing compound having a mercapto group include a compound including nitrogen-containing aromatic heterocycle substituted with a mercapto group, and a tautomer of a compound including nitrogen-containing aromatic heterocycle substituted with a mercapto group. Preferable specific examples of the nitrogen-containing aromatic heterocycle include imidazole, pyrazole, 1,2,3-triazol, 1,2,4-triazol, oxazole, thiazole, pyridine, pyrimidine, pyridazine, pyrazine, 1,2,3-triazine, 1,2,4-triazine, 1,3,5-triazine, indole, indazole, benzimidazole, benzoxazole, benzothiazole, 1H-benzotriazole, quinoline, isoquinoline, cinnoline, phthalazine, quinazoline, quinoxaline, and 1,8-naphthyridine.

Suitable specific examples of a nitrogen-containing heterocyclic compound suitable as a sulfur-containing compound, and suitable tautomer of the nitrogen-containing heterocyclic compound include the following compounds.

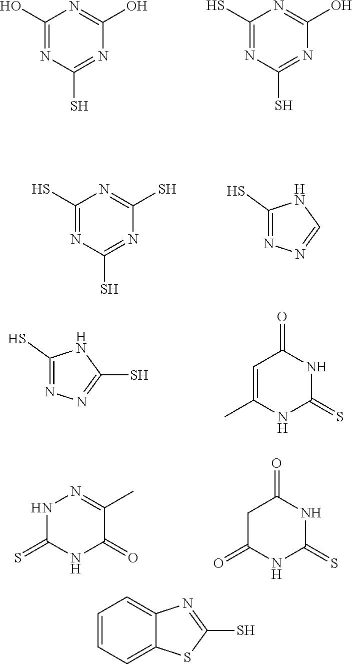

When the first photosensitive composition includes a sulfur-containing compound (D), the use amount is preferably 0.01 parts by mass or more 5 parts by mass or less, more preferably 0.02 parts by mass or more 3 parts by mass or less, and particularly preferably 0.05 parts by mass or more 2 parts by mass or less with respect to 100 parts by mass that is the total mass of the above resin (B) and the alkali-soluble resin (C).

### {Acid Diffusion Inhibitor (E)}

The first photosensitive composition may include an acid diffusion inhibitor (E). As the acid diffusion inhibitor (E), a nitrogen-containing compound (E1) is preferable, and furthermore, an organic carboxylic acid or oxoacid of phosphorus, or derivative thereof (E2) can be included in the first photosensitive composition as necessary.

### [Nitrogen-Containing Compound (E1)]

Examples of the nitrogen-containing compound (E1) include trimethylamine, diethylamine, triethylamine, di-n-propylamine, tri-n-propylamine, tri-n-pentylamine, tribenzylamine, diethanolamine, triethanolamine, n-hexylamine, n-heptyl amine, n-octyl amine, n-nonyl amine, ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, formamide, N-methylformamide, N,N-dimethylformamide, acetamide, N-methylacetamide, N,N-dimethylacetamide, propionamide, benzamide, pyrrolidone, N-methylpyrrolidone, methylurea, 1,1-dimethylurea, 1,3-dimethylurea, 1,1,3,3-tetramethylurea, 1,3-diphenylurea, imidazole, benzimidazole, 4-methylimidazole, 8-oxyquinoline, acridine, purine, pyrrolidine, piperidine, 2,4,6-tri(2-pyridyl)-S-triazine, morpholine, 4-methylmorpholine, piperazine, 1,4-dimethylpiperazine, 1,4-diazabicyclo[2.2.2]octane and pyridine, and pyridines.

In addition, commercially available hindered amine compounds such as ADEKASTAB LA-52 (tetrakis(1,2,2,6,6-pentamethyl-4-piperidyl)butane-1,2,3,4-carboxylate), ADEKASTAB LA-57 (tetrakis(2,2,6,6-tetramethyl-4-piperidyl)butane-1,2,3,4-tetracarboxylate), ADEKASTAB LA-63P (reaction product of 1,2,3,4-butanetetracarboxylic acid methyl ester, 1,2,2,6,6-pentamethyl-4-piperidinol, and β,β,β′,β′-tetramethyl-2,4,8,10-tetraoxaspiro[5.5]undecane-3,9-diethanol), ADEKASTAB LA-68 (reaction product of 1,2,3,4-butanetetracarboxylic acid tetramethyl ester, 2,2,6,6-tetramethyl-4-piperidinol, and β,β,β′,β′-tetramethyl-2,4,8,10-tetraoxaspiro[5.5]undecane-3,9-diethanol), ADEKASTAB LA-72 (hindered amine containing bis(1,2,2,6,6-pentamethyl-4-piperidyl) sebacate as main component), ADEKASTAB LA-77Y (bis(2,2,6,6-tetramethyl-4-piperidyl) sebacate), ADEKASTAB LA-77G (bis(2,2,6,6-tetramethyl-4-piperidiyl) sebacate), ADEKASTAB LA-81 (bis(1-undecanoxy-2,2,6,6-tetramethylpiperidine-4-yl) carbonate), ADEKASTAB LA-82 (1,2,2,6,6-pentamethyl-4-piperidyl methacrylate), ADELASTAB LA-87 (2,2,6,6-tetramethyl-4-piperidyl methacrylate) and the like (all manufactured by ADEKA Corporation), and pyridines substituted with substituent such as a hydrocarbon group at 2- and 6-position such as 2,6-diphenylpyridine, 2,4,6-triphenylpyridine, and 2,6-di-tert-butylpyridine can be used as the nitrogen-containing compound (E1).

The nitrogen-containing compound (E1) may be used in an amount typically in the range of 0 parts by mass or more and 5 parts by mass or less, and particularly preferably in the range of 0 parts by mass or more and 3 parts by mass or less, with respect to 100 parts by mass of total mass of the above resin (B) and the above alkali-soluble resin (C).

### [Organic Carboxylic Acid or Oxo Acid of Phosphorus or Derivative Thereof (E2)]

Among the organic carboxylic acid, or the oxo acid of phosphorus or the derivative thereof (E2), specific preferred examples of the organic carboxylic acid include malonic acid, citric acid, malic acid, succinic acid, benzoic acid, salicylic acid and the like, and salicylic acid is particularly preferred.

Examples of the oxo acid of phosphorus or derivatives thereof include phosphoric acid and derivatives such as esters thereof such as phosphoric acid, phosphoric acid di-n-butyl ester, and phosphoric acid diphenyl ester; phosphonic acid and derivatives such as esters thereof such as phosphonic acid, phosphonic acid dimethyl ester, phosphonic acid di-n-butyl ester, phenylphosphonic acid, phosphonic acid diphenyl ester, and phosphonic acid dibenzyl ester; and phosphinic acid and derivatives such as esters thereof such as phosphinic acid and phenylphosphinic acid; and the like. Among these, phosphonic acid is particularly preferred. These may be used alone, or in combinations of two or more thereof.

The organic carboxylic acid or oxo acid of phosphorus or derivative thereof (E2) may be used in an amount usually in the range of 0 parts by mass or more and 5 parts by mass or less, and particularly preferably in the range of 0 parts by mass and 3 parts by mass or less, with respect to 100 parts by mass of total mass of the above resin (B) and the above alkali-soluble resin (C).

Moreover, in order to form a salt to allow for stabilization, the organic carboxylic acid, or the oxo acid of phosphorous or the derivative thereof (E2) is preferably used in an amount equivalent to that of the above nitrogen-containing compound (E1).

### {Polyfunctional Vinyl Ether Monomer (G)}

The fists photosensitive composition may include a polyfunctional vinyl ether monomer (F). When the first photosensitive composition includes the above-mentioned resin (B) and alkali-soluble resin (C), together with a polyfunctional vinyl ether (F), by a coating film consisting of the first photosensitive composition being heated upon forming the resist film, a carboxy group and phenolic hydroxyl group possessed by the resin (B) and the alkali-soluble resin (C), and the polyfunctional vinyl ether monomer (F) react, and the molecular chain of the resin (B) and alkali-soluble resin (C) are linked. By being linked the molecular chains of the resin (B) and the alkali-soluble resin (C), it is possible to suppress the occurrence of cracks upon forming the resist film using the first photosensitive composition, and it is possible to form a patterned resist film for which the shape hardly changes, even if contacting with a plating solution under plating conditions.

The polyfunctional vinyl ether monomer (F) can be blended with the first photosensitive composition as mentioned above. In addition, the polyfunctional vinyl ether monomer (F) may be used in a state crosslinking reaction with the resin (B) and/or alkali-soluble resin (C), prior to preparing the first photosensitive composition. It should be noted that, in the case of the alkali-soluble resin (C) being crosslinked by the polyfunctional vinyl ether monomer (F), the carboxy group and phenolic hydroxyl group possessed by the alkali-soluble resin (C) are crosslinked by a crosslinking group of acetal type. This acetal-type crosslinking group dissociates from the carboxy group or phenolic hydroxyl group by action of the acid, and causes a carboxy group or phenol hydroxyl group to be generated. In other words, the alkali-soluble resin (C) crosslinked by the polyfunctional vinyl ether monomer (F) corresponds to the resin (B) for which the solubility to alkali increases by the action of the acid. It should be noted that, for the resin (B) having a crosslinking group derived from the polyfunctional vinyl ether monomer (F), the mass of crosslinking group is included in the mass of the resin (B).

The polyfunctional vinyl ether monomer (F) is not particularly limited so long as being an organic compound containing two or more vinyloxy groups in one molecule. A divalent or polyvalent organic group which is the mother nucleus bonded by the vinyloxy group may be a hydrocarbon group, or may be an organic group including a heteroatom. As the heteroatom, O, S, N, P, halogen atoms, etc. can be exemplified.

A divalent or higher valency organic group as the mother nucleus bonded by the vinyloxy group in the polyfunctional vinyl ether monomer (F) is preferably a hydrocarbon group due to being chemically stable, and having good solubility in the first photosensitive composition. This hydrocarbon group may be an aliphatic hydrocarbon group, may be an aromatic hydrocarbon group, may be a combination of aliphatic hydrocarbon group and aromatic hydrocarbon group, and is preferably an aliphatic hydrocarbon group.

In the case of the divalent or higher valency organic group as the mother nucleus bonded by the vinyloxy group in the polyfunctional vinyl ether monomer (F) being a hydrocarbon group, the number of carbon atoms in this hydrocarbon group is not particularly limited in a range not inhibiting the object of the present invention. The number of carbon atoms in this hydrocarbon group, for example, is preferably 1 or more and 40 or less, more preferably 2 or more and 20 or less, and even more preferably 2 or more and 10 or less.

The number of vinyloxy groups possessed by the polyfunctional vinyl ether monomer (F) is not particularly limited. The number of vinyloxy groups in one molecule is preferably 2 or more and 6 or less, more preferably 2 or more and 4 or less, and particularly preferably 2 or 3.

Specific examples of the polyfunctional vinyl ether monomer (F) include linear aliphatic divinyl ethers such as ethylene glycol divinyl ether, diethylene glycol divinyl ether, triethyleneglycol divinyl ether, polyethylene glycol divinyl ether, propylene glycol divinyl ether, dipropyleneglycol divinyl ether, tripropyleneglycol divinyl ether, polypropylene glycol divinyl ether, 1,3-propanediol divinyl ether, 1,4-butanediol divinyl ether, 1,5-pentanediol divinyl ether, 1,6-hexanediol divinyl ether, 1,8-octanediol divinyl ether, 1,10-decanediol divinyl ether, neopentyl glycol divinyl ether, trimethylolpropane divinyl ether and pentaerythritol divinyl ether; cycloaliphatic divinyl ethers such as 1,4-cyclohexanediol divinyl ether, 1,4-cyclohexane dimethanol divinyl ether and 2-vinyloxy-5-(vinyloxymethyl)-7-oxabicyclo[2.2.1]heptane; aromatic divinyl ethers such as 1,4-divinyloxybenzene, 1,3-divinyloxybenzene, 1,2-divinyloxybenzene, 1,4-divinyloxynaphthalene, 1,3-divinyloxynaphthalene, 1,2-divinyloxynaphthalene, 1,5-divinyloxynaphthalene, 1,6-divinyloxynaphthalene, 1,7-divinyloxynaphthalene, 1,8-divinyloxynaphthalene, 2,3-divinyloxynaphthalene, 2,6-divinyloxynaphthalene, 2,7-divinyloxynaphthalene, 4,4′-divinyloxy biphenyl, 3,3′-divinyloxy biphenyl, 2,2′-divinyloxy biphenyl, 3,4′-divinyloxy biphenyl, 2,3′-divinyloxy biphenyl, 2,4′-divinyloxy biphenyl, bisphenol A divinyl ether, 1,4-benzene dimethanol divinyl ether, 1,3-benzene dimethanol divinyl ether, 1,2-benzene dimethanol divinyl ether, and naphthalene-1,4-bismethanol divinyl ether; and trivalent or higher polyvalent vinyl ethers such as trimethylolpropane trivinyl ether, pentaerythritol tetravinyl ether, sorbitol tetravinyl ether, sorbitol pentavinyl ether, dipentaerythritol pentavinyl ether and dipentaerythritol hexavinyl ether can be exemplified.

The usage amount of the polyfunctional vinyl ether monomer (F) in the first photosensitive composition is not particularly limited in a range not inhibiting the object of the present invention. Since the formation is particularly easy of a patterned resist film which tends to particularly suppress the occurrence of cracks during resist film formation, and for which the shape hardly changes even if contacting with a plating solution under plating conditions, the usage amount of the polyfunctional vinyl ether monomer (F) in the first photosensitive compound is preferably 0.5 parts by mass or more and 50 parts by mass or less, and more preferably 1 part by mass or more and 30 parts by mass or less, relative to a total of 100 parts by mass of the mass of the resin (B) and the mass of the alkali-soluble resin (C).

### {Organic Solvent (S)}

The first photosensitive composition includes an organic solvent (S). There is no particular limitation on the types of the organic solvent (S) as long as the objects of the present invention are not impaired, and an organic solvent appropriately selected from those conventionally used for photosensitive compositions can be used.

Specific examples of the organic solvent (S) include ketones such as acetone, methyl ethyl ketone, cyclohexanone, methyl isoamyl ketone, and 2-heptanone; polyhydric alcohols and derivatives thereof such as ethylene glycol, ethylene glycol monoacetate, diethylene glycol, diethylene glycol monoacetate, propylene glycol, propylene glycol monoacetate, propylene glycol monomethyl ether acetate, dipropylene glycol, and a monomethyl ether, a monoethyl ether, a monopropyl ether, a monobutyl ether, and a monophenyl ether of dipropylene glycol monoacetate; cyclic ethers such as dioxane; esters such as ethyl formate, methyl lactate, ethyl lactate, methyl acetate, ethyl acetate, butyl acetate, methyl pyruvate, methyl acetoacetate, ethyl acetoacetate, ethyl pyruvate, ethylethoxy acetate, methyl methoxypropionate, ethyl ethoxypropionate, methyl 2-hydroxypropionate, ethyl 2-hydroxypropionate, ethyl 2-hydroxy-2-methylpropionate, methyl 2-hydroxy-3-methylbutanate, 3-methoxybutyl acetate, and 3-methyl-3-methoxybutyl acetate; aromatic hydrocarbons such as toluene and xylene; and the like. These may be used alone, or as a mixture of two or more thereof.

There is no particular limitation on the content of the organic solvent (S) as long as the objects of the present invention are not impaired. In a case where the first photosensitive composition is used for a thick-film application such that a photosensitive layer obtained by the spin coating method and the like has a film thickness of 5 μm or more, the organic solvent (S) is preferably used in a range where the solid content concentration of the first photosensitive composition is 30% by mass or more and 55% by mass or less.

### {Other Components}

The first photosensitive composition may further contain a polyvinyl resin for improving plasticity. Specific examples of the polyvinyl resin include polyvinyl chloride, polystyrene, polyhydroxystyrene, polyvinyl acetate, polyvinylbenzoic acid, polyvinyl methyl ether, polyvinyl ethyl ether, polyvinyl alcohol, polyvinyl pyrrolidone, polyvinyl phenol, and copolymers thereof, and the like. The polyvinyl resin is preferably polyvinyl methyl ether in view of lower glass transition temperatures.

It is also preferable that the first photosensitive composition includes a Lewis acidic compound. When the first photosensitive composition includes the Lewis acidic compound, the first photosensitive composition with high sensitivity is easily obtained, so that a patterned resist film whose cross-sectional shape is rectangular is more easily formed using the first photosensitive composition. Furthermore, when a patterned cured film is formed using the first photosensitive composition, when time required for each process at the time of cured film formation or time required between the processes is long, a pattern having a desired shape and dimension may not be easily formed, or developing property may be deteriorated. However, when the Lewis acidic compound is blended into the first photosensitive composition, such adverse effects on the pattern shape or the developing property can be mitigated or a process margin can be widened.

The Lewis acidic compound herein represents “a compound that acts as an electron-pair receptor having an empty orbital capable of receiving at least one electron pair.” The Lewis acidic compound is not particularly limited as long as it corresponds to the above definition, and is a compound which is recognized as the Lewis acidic compound by a person skilled in the art. As the Lewis acidic compound, a compound that does not correspond to a Bronsted acid (proton acid) is preferably used. Specific examples of the Lewis acidic compound include boron fluoride, ether complexes of boron fluoride (for example, BF3·Et2O, BF₃·Me₂O, BF₃·THF, etc., Et represents an ethyl group, Me represents a methyl group, and THF represents tetrahydrofuran), organic boron compounds (for example, tri-n-octyl borate, tri-n-butyl borate, triphenyl borate, triphenylboron, etc.), titanium chloride, aluminum chloride, aluminum bromide, gallium chloride, gallium bromide, indium chloride, thallium trifluoroacetate, tin chloride, zinc chloride, zinc bromide, zinc iodide, zinc trifluoromethanesulfonate, zinc acetate, zinc nitrate, zinc tetrafluoroborate, manganese chloride, manganese bromide, nickel chloride, nickel bromide, nickel cyanide, nickel acetylacetonate, cadmium chloride, cadmium bromide, stannous chloride, stannous bromide, stannous sulfate, stannous tartrate, and the like. Furthermore, other specific examples of the Lewis acidic compound include chloride, bromide, sulfate, nitrate, carboxylate, or trifluoromethanesulfonate, of the rare earth metal element, and cobalt chloride, ferrous chloride, yttrium chloride, and the like. Examples of the rare earth metal element herein include lanthanum, cerium, praseodymium, neodymium, samarium, europium, gadolinium, terbium, dysprosium, holmium, erbium, thulium, ytterbium, and lutetium.

From the viewpoint of easiness in availability and preferable effect by addition thereof, it is preferable that the Lewis acidic compound contains a Lewis acidic compound including elements belonging to Group 13. Herein, examples of the elements belonging to Group 13 include boron, aluminum, gallium, indium, and thallium. Among the above elements belonging to Group 13, boron is preferable from the viewpoint that the Lewis acidic compound is easily available and addition effect is particularly excellent. In other words, it is preferable that the Lewis acidic compound contains a Lewis acidic compound including boron.

Examples of the Lewis acidic compound containing boron include boron fluoride, ether complexes of boron fluoride, boron halides such as boron chloride and boron bromide, and various organic boron compounds. As the Lewis acidic compound including boron, an organic boron compound is preferable because the content ratio of halogen atoms in the Lewis acidic compound is small and the first photosensitive composition is easily applicable to an application requiring a low halogen content.

Suitable examples of the organic boron compound include a boron compound represented by the following formula (g1):

B(R^{g1})ₜ₁(OR^{g2})₍₃₋ₜ₁₎ (g1)

(In the formula (g1), R^{g1} and R^{g2} each independently represent a hydrocarbon group having 1 or more and 20 or less carbon atoms; the hydrocarbon group may have one or more substituents; t1 is an integer of 0 or more and 3 or less; when a plurality of R^{g1} exists, two of the plurality of R^{g1} may be bonded to each other to form a ring; and when a plurality of OR^{g2} is present, two of the plurality of OR^{g2} may be bonded to each other to form a ring).
The first photosensitive composition preferably includes one or more boron compounds represented by the above formula (g1) as the Lewis acidic compound mentioned above.

In the formula (g1), R^{g1} and R^{g2} are a hydrocarbon group, the number of carbon atoms in the hydrocarbon group is 1 or more and 20 or less. The hydrocarbon group having 1 or more and 20 or less carbon atoms may be an aliphatic hydrocarbon group, or an aromatic hydrocarbon group, a hydrocarbon group having a combination of an aliphatic group and an aromatic group. As the hydrocarbon group having 1 or more and 20 or less carbon atoms, a saturated aliphatic hydrocarbon group, or an aromatic hydrocarbon group is preferable. The number of carbon atoms in the hydrocarbon group as R^{g1} and R^{g2} is preferably 1 or more and 10 or less. When the hydrocarbon group is an aliphatic hydrocarbon group, the number of carbon atoms thereof is preferably 1 or more and 6 or less, and particularly preferably 1 or more and 4 or less. The hydrocarbon group as R^{g1} and R^{g2} may be a saturated hydrocarbon group, or an unsaturated hydrocarbon group, and a saturated hydrocarbon group is preferable. When the hydrocarbon group as R^{g1} and R^{g2} is an aliphatic hydrocarbon group, the aliphatic hydrocarbon group may be linear, branched or cyclic or combination thereof.

Suitable specific examples of aromatic hydrocarbon groups include a phenyl group, a naphthalene-1-yl group, a naphthalene-2-yl group, a 4-phenylphenyl, 3-phenylphenyl, and 2-phenylphenyl. Among these, a phenyl group is preferred.

The saturated aliphatic hydrocarbon group is preferably an alkyl group. Suitable examples of alkyl groups include methyl group, ethyl group, n-propyl group, isopropyl group, n-butyl group, isobutyl group, sec-butyl group, tert-butyl group, n-pentyl group, n-hexyl group, n-heptyl group, n-octyl group, 2-ethyl hexyl group, n-nonyl group, and n-decyl group.

The hydrocarbon group as R^{g1} and R^{g2} may have one or more substituents. Examples of the substituent include a halogen atom, a hydroxyl group, an alkyl group, an aralkyl group, an alkoxy group, a cycloalkyloxy group, an aryloxy group, an aralkyloxy group, an alkylthio group, a cycloalkylthio group, an arylthio group, an aralkylthio group, an acyl group, an acyloxy group, an acylthio group, an alkoxycarbonyl group, a cycloalkyloxycarbonyl group, an aryloxycarbonyl group, an amino group, an N-monosubstituted amino group, an N,N-disubstituted amino group, a carbamoyl group (—CO—NH₂), an N-monosubstituted carbamoyl group, an N,N-disubstituted carbamoyl group, a nitro group and a cyano group. The number of carbon atoms in the substituent is not particularly limited within a range where the objects of the present invention are not impaired, but the number is preferably 1 or more and 10 or less, and more preferably 1 or more and 6 or less.

Suitable specific examples of the organic boron compound represented by the above formula (g1) include the following compounds. Note here that in the following formulae, Pen represents a pentyl group, Hex represents a hexyl group, Hep represents a heptyl group, Oct represents an octyl group, Non represents a nonyl group, and Dec represents a decyl group.

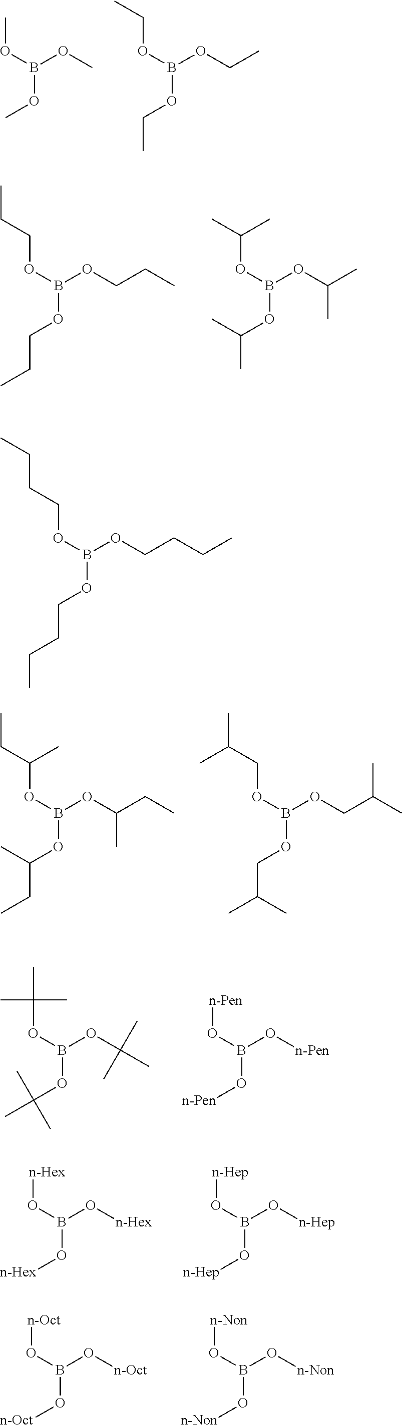

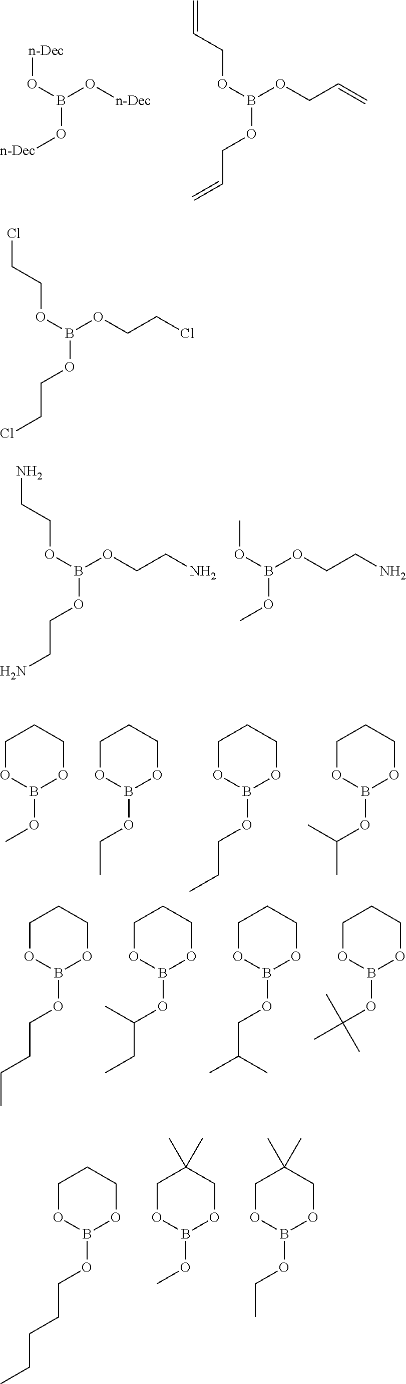

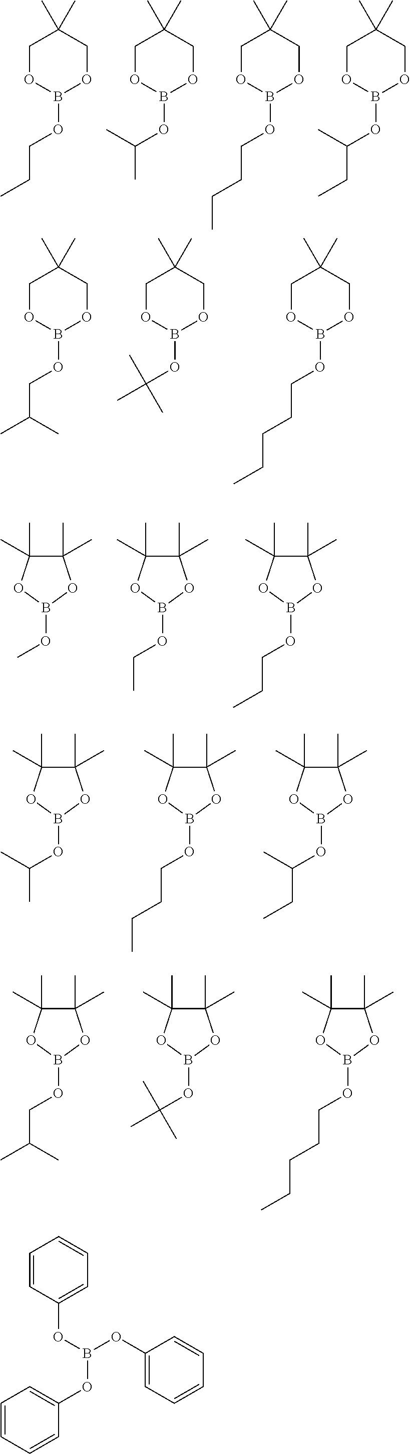

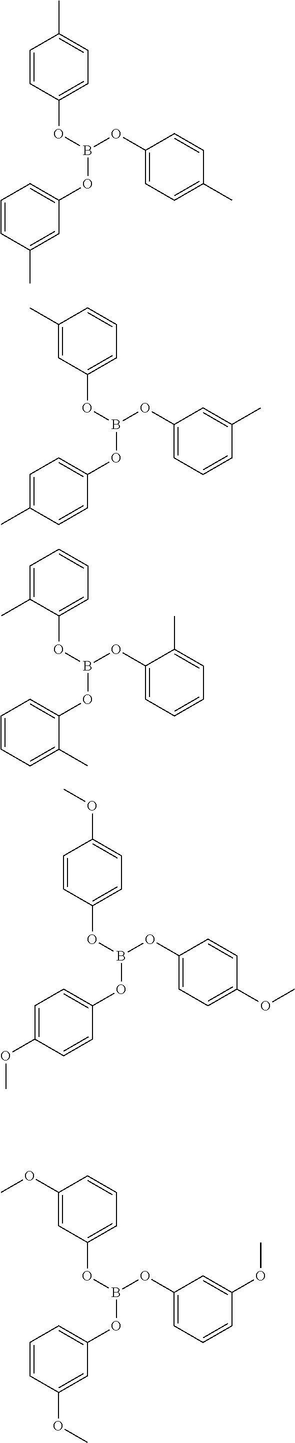

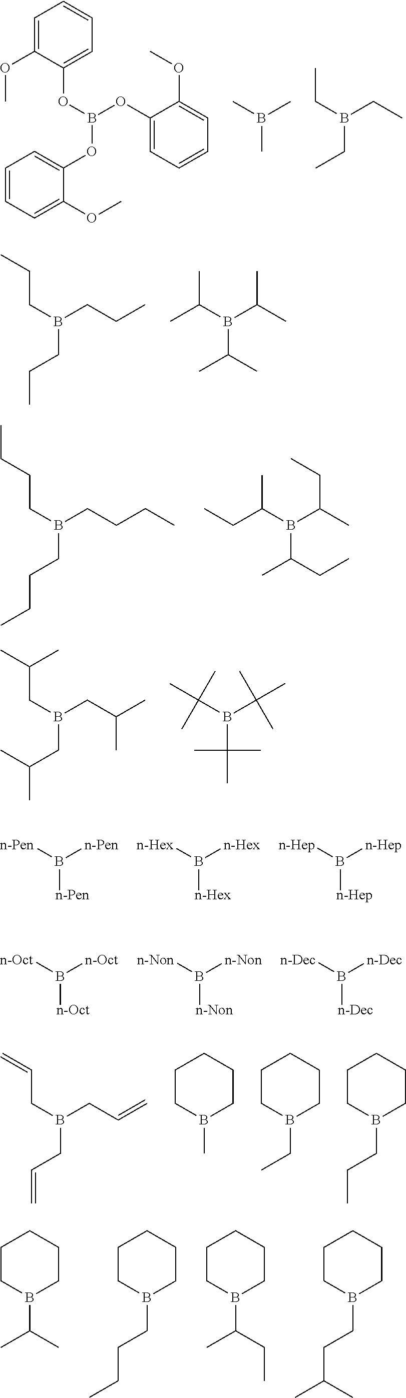

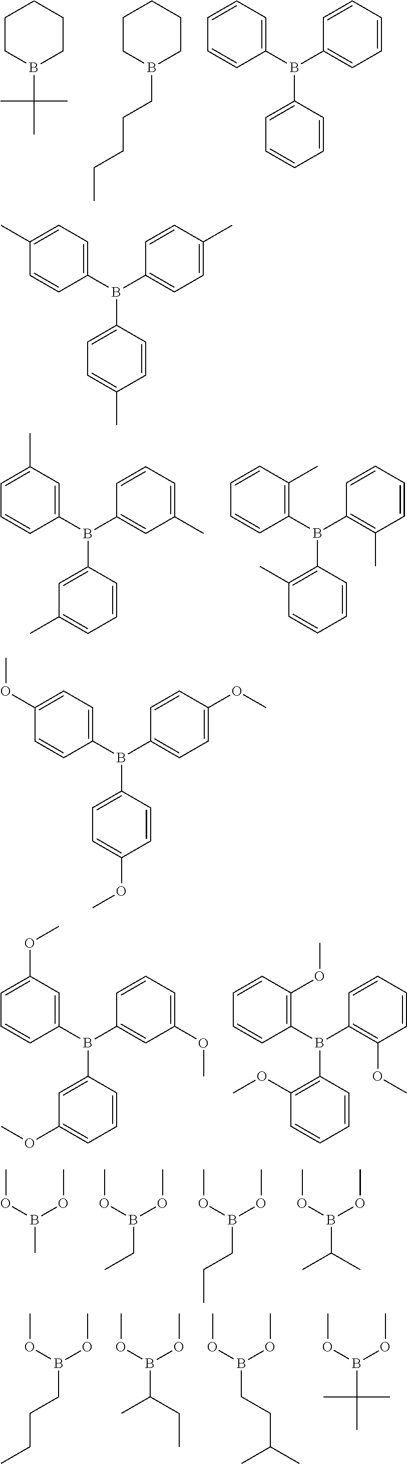

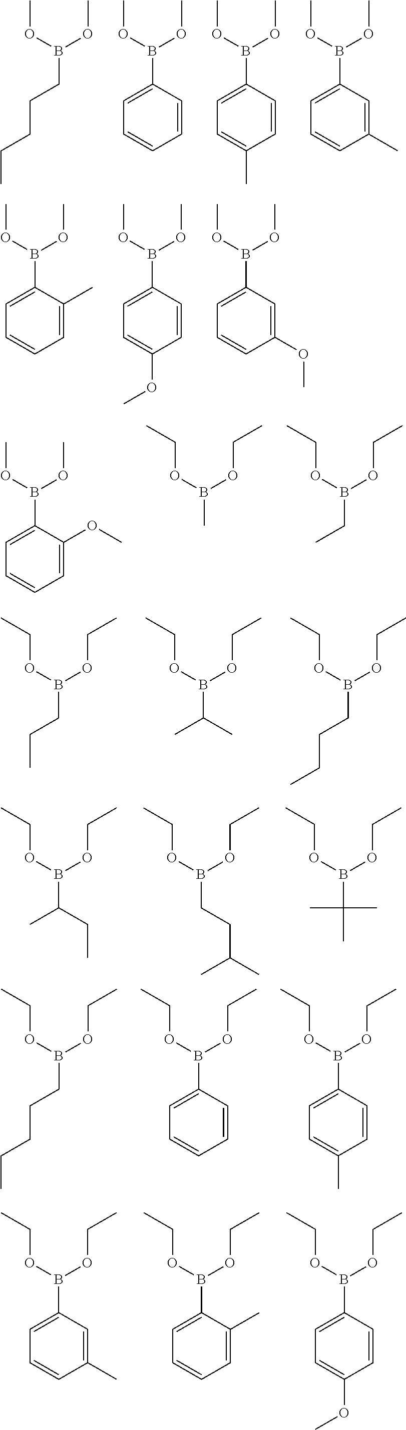

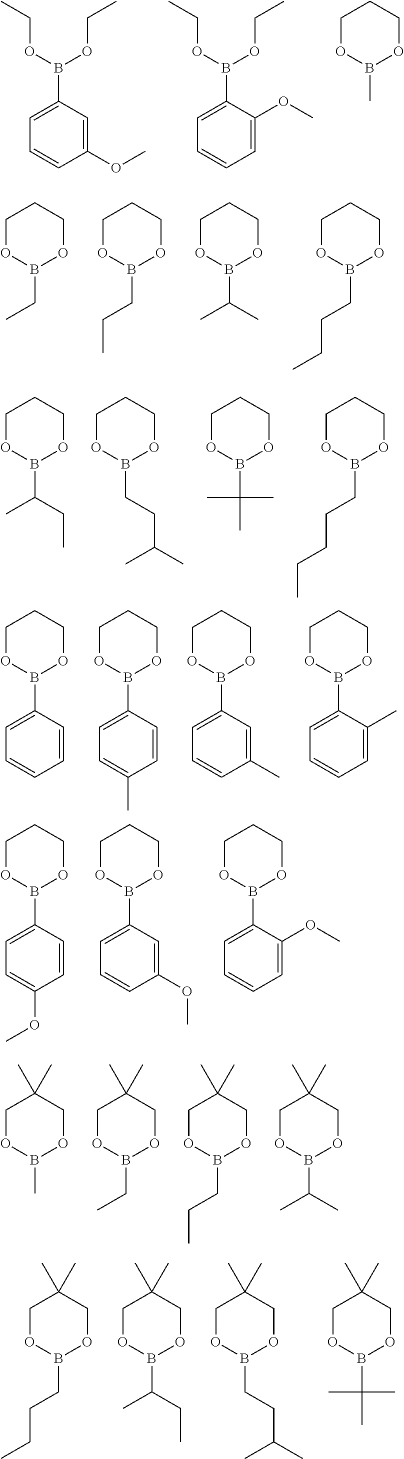

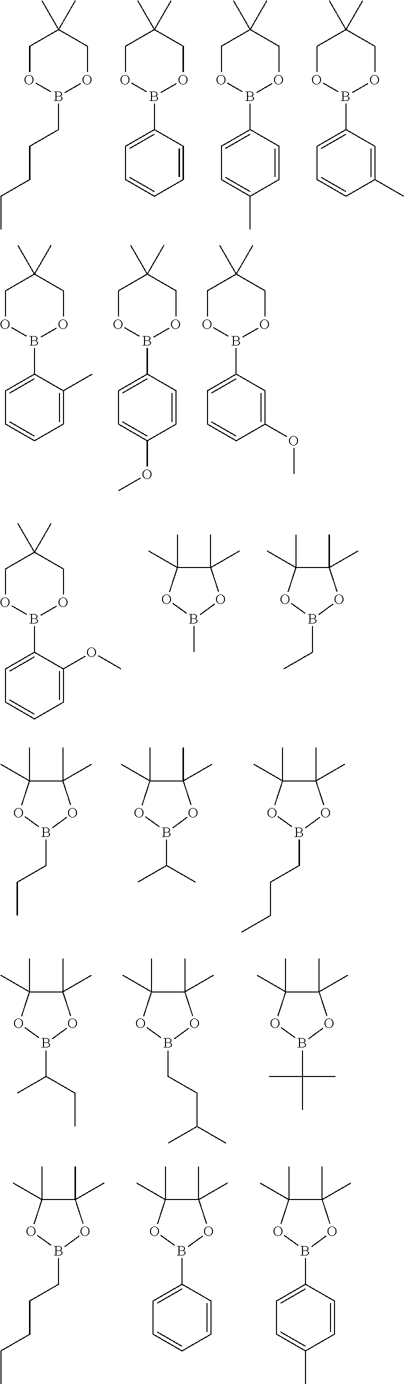

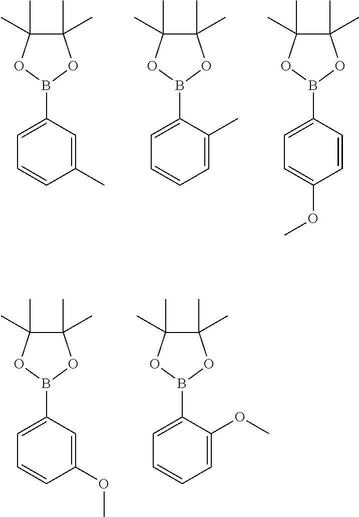

The Lewis acidic compound is used in the amount in a range of preferably 0.01 parts by mass or more and 5 parts by mass or less, more preferably 0.01 parts by mass or more and 3 parts by mass or less, even more preferably 0.05 part by mass or more and 2 parts by mass or less, relative to 100 parts by mass of the total mass of the above resin (B) and the above alkali-soluble resin (C).

Further, when the first photosensitive composition is used for forming pattern serving as a template for forming a plated article, the first photosensitive composition may also contain an adhesive auxiliary agent in order to improve the adhesiveness between a template formed with the photosensitive composition and a substrate.

Also, the first photosensitive composition may further contain a surfactant for improving coating characteristics, defoaming characteristics, leveling characteristics, and the like. As the surfactant, for example, a fluorine-based surfactant or a silicone-based surfactant is preferably used. Specific examples of the fluorine-based surfactant include commercially available fluorine-based surfactants such as BM-1000 and BM-1100 (both manufactured by B.M-Chemie Co., Ltd.), Megafac F142D, Megafac F172, Megafac F173 and Megafac F183 (all manufactured by Dainippon Ink And Chemicals, Incorporated), Flolade FC-135, Flolade FC-170C, Flolade FC-430 and Flolade FC-431 (all manufactured by Sumitomo 3M Ltd.), Surflon S-112, Surflon S-113, Surflon S-131, Surflon S-141 and Surflon S-145 (all manufactured by Asahi Glass Co., Ltd.), SH-28PA, SH-190, SH-193, SZ-6032 and SF-8428 (all manufactured by Toray Silicone Co., Ltd.) and the like, but not limited thereto. As the silicone-based surfactant, an unmodified silicone-based surfactant, a polyether modified silicone-based surfactant, a polyester modified silicone-based surfactant, an alkyl modified silicone-based surfactant, an aralkyl modified silicone-based surfactant, a reactive silicone-based surfactant, and the like, can be preferably used. As the silicone-based surfactant, commercially available silicone-based surfactant can be used. Specific examples of the commercially available silicone-based surfactant include Paintad M (manufactured by Dow Corning Toray Co., Ltd.), Topica K1000, Topica K2000, and Topica K5000 (all manufactured by Takachiho Industry Co., Ltd.), XL-121 (polyether modified silicone-based surfactant, manufactured by Clariant Co.), BYK-310 (polyester modified silicone-based surfactant, manufactured by BYK), and the like.

Additionally, in order to finely adjust the solubility in a developing solution, the first photosensitive composition may further contain an acid, an acid anhydride, or a solvent having a high boiling point.

Specific examples of the acid and acid anhydride include monocarboxylic acids such as acetic acid, propionic acid, n-butyric acid, isobutyric acid, n-valeric acid, isovaleric acid, benzoic acid, and cinnamic acid; hydroxymonocarboxylic acids such as lactic acid, 2-hydroxybutyric acid, 3-hydroxybutyric acid, salicylic acid, m-hydroxybenzoic acid, p-hydroxybenzoic acid, 2-hydroxycinnamic acid, 3-hydroxycinnamic acid, 4-hydroxycinnamic acid, 5-hydroxyisophthalic acid, and syringic acid; polyvalent carboxylic acids such as oxalic acid, succinic acid, glutaric acid, adipic acid, maleic acid, itaconic acid, hexahydrophthalic acid, phthalic acid, isophthalic acid, terephthalic acid, 1,2-cyclohexanedicarboxylic acid, 1,2,4-cyclohexanetricarboxylic acid, butanetetracarboxylic acid, trimellitic acid, pyromellitic acid, cyclopentanetetracarboxylic acid, butanetetracarboxylic acid, and 1,2,5,8-naphthalenetetracarboxylic acid; acid anhydrides such as itaconic anhydride, succinic anhydride, citraconic anhydride, dodecenylsuccinic anhydride, tricarbanilic anhydride, maleic anhydride, hexahydrophthalic anhydride, methyltetrahydrophthalic anhydride, Himic anhydride, 1,2,3,4-butanetetracarboxylic anhydride, cyclopentanetetracarboxylic dianhydride, phthalic anhydride, pyromellitic anhydride, trimellitic anhydride, benzophenonetetracarboxylic anhydride, ethylene glycol bis anhydrous trimellitate, and glycerin tris anhydrous trimellitate; and the like.

Furthermore, specific examples of the solvent having a high boiling point include N-methylformamide, N,N-dimethylformamide, N-methylformanilide, N-methylacetamide, N,N-dimethlyacetamide, N-methylpyrrolidone, dimethyl sulfoxide, benzyl ethyl ether, dihexyl ether, acetonyl acetone, isophorone, caproic acid, caprylic acid, 1-octanol, 1-nonanol, benzyl alcohol, benzyl acetate, ethyl benzoate, diethyl oxalate, diethyl maleate, y-butyrolactone, ethylene carbonate, propylene carbonate, phenyl cellosolve acetate, and the like.

Moreover, the first photosensitive composition may further contain a well-known sensitizer for improving the sensitivity.

### <Second Chemically Amplified Positive-Type Photosensitive Composition>

The second chemically amplified positive-type photosensitive composition is a chemically amplified positive-type photosensitive composition used for forming a template for plating on a substrate by photolithography method. Hereinafter, the second chemically amplified positive-type photosensitive composition is also referred to as “second photosensitive composition”

The second positive-type photosensitive composition includes an acid generator (A) which generates an acid by irradiation of active rays or radioactive rays; and a resin (B) whose solubility in alkali increases under an action of acid.

The resin (B) includes an acrylic resin (B1b) including: a constituent unit (bL1) derived form a crosslinkable monomer represented by formula (BL1):

R^{B1}—O—R^{B3}—O—R^{B2} (BL1)
in which, in the formula (BL1), R^{B1} and R^{B2} are each independently a (meth)acryloyl group or a vinylphenyl group, R^{B3} is a divalent bridging group, and at least one of two O—R^{B3} bonds in the formula (BL1) generates a carboxy group or a phenolic hydroxy group by cleavage by an action of acid, a constituent unit (bL2) derived from an alkyl (meth)acrylate (BL2), and
a constituent unit (bL3) derived from an (meth)acrylate (BL3) including an alicyclic hydrocarbon group or an aromatic group.

In the alkyl (meth)acrylate (BL2), an alkyl group optionally substituted with a hydroxy group or an alkoxy group and having 1 or more and 10 or less carbon atoms bonds to a (meth)acryloyloxy group, and a carbon atom which bonds to the (meth)acryloyloxy group does not correspond to a tertiary carbon atom having an sp³ hybrid orbital. In the (meth)acrylate (BL3) including the alicyclic hydrocarbon group or the aromatic group, the alicyclic hydrocarbon group or the aromatic group bonds to a (meth)acryloyloxy group, the alicyclic hydrocarbon group or the aromatic group may be substituted with one or more substituents selected from the group consisting of an alkyl group having 1 or more and 4 or less carbon atoms, an alkoxy group having 1 or more and 4 or less carbon atoms, and a hydroxy group, and a carbon atom to which the (meth)acryloyloxy group bonds does not correspond to a tertiary carbon atom having an sp³ hybrid orbital A molar ratio of the constituent unit (bL1) is 1% by mole or more and 10% by mole or less relative to all constituent units of the acrylic resin (B1b). A molar ratio of the constituent unit (bL2) is 0.1% by mole or more and 10% by mole or less relative to all constituent units of the acrylic resin (B1b). A molar ratio of the constituent unit (bL3) is 25% by mole or more and 50% by mole or less relative to all constituent units of the acrylic resin (B1b).

The patterned resist film having a square cross-section of a nonresist portion and good plating liquid resistance can be formed by using the second photosensitive composition which meets the above requirements, even when forming a thick patterned resist film by photolithography method.

The second photosensitive composition is the same as the first photosensitive composition except that the second photosensitive composition includes the acrylic resin (B1b) instead or the acrylic resin (Bia), and a calculated value of glass transition temperature of hypothetical non-crosslinked acrylic resin which the constituent unit (bL1) is excluded from the acrylic resin (B1b) does not necessarily have to be 90° C. or higher and 120° C. or lower.

It should be noted that a group of acrylic resins included in the acrylic resin (Bia) and a group of acrylic resins included in the acrylic resin (B1b) largely overlap. Additionally, the calculated value of glass transition temperature of hypothetical non-crosslinked acrylic resin which the constituent unit (bL1) is excluded from the acrylic resin (B1b) is preferably 90° C. or higher and 120° C. or lower.

The constituent unit (bL1), the constituent unit (bL2), and the constituent unit (bL3) essentially included in the acrylic resin (B1b) are the same as these constituent units described for the resin (Bia) included in the first photosensitive composition. In addition, the acrylic resin (B1b) may also include the aforementioned constituent unit (bL4), constituent unit (bL5), constituent unit (bL6), and other constituent units as in the acrylic resin (Bia).

### <<Method of Preparing Chemically Amplified Positive-Type Photosensitive Composition>>

The first photosensitive composition and the second photosensitive composition are prepared by mixing and stirring the constituting component of the composition by the common method. Machines which can be used for mixing and stirring the above components include dissolvers, homogenizers, 3-roll mills and the like. After uniformly mixing the above components, the resulting mixture may be filtered through a mesh, a membrane filter and the like.

### <<Photosensitive Dry Film>>

A photosensitive dry film includes a substrate film, and a photosensitive layer formed on the surface of the substrate film. In the photosensitive dry film, the photosensitive layer is made of the aforementioned first photosensitive composition or second photosensitive composition.

As the substrate film, a film having optical transparency is preferable. Specifically, a polyethylene terephthalate (PET) film, a polypropylene (PP) film, a polyethylene (PE) film, and the like. In view of excellent balance between the optical transparency and the breaking strength, a polyethylene terephthalate (PET) film is preferable.

The aforementioned first photosensitive composition or second photosensitive composition is applied on the substrate film to form a photosensitive layer, and thereby a photosensitive dry film is manufactured. When the photosensitive layer is formed on the substrate film, the first photosensitive composition or the second photosensitive composition is applied and dried on the substrate film using an applicator, a bar coater, a wire bar coater, a roller coater, a curtain flow coater, and the like, so that a film thickness after drying is preferably 0.5 μm or more and 300 μm or less, more preferably 1 μm or more and 300 μm or less, and particularly preferably 3 μm or more and 100 μm or less.

The photosensitive dry film may have a protective film on the photosensitive layer. Examples of the protective film include a polyethylene terephthalate (PET) film, a polypropylene (PP) film, a polyethylene (PE) film, and the like.

### <<Patterned Resist Film>>

Using the first photosensitive composition or the second photosensitive composition explained above, the method of forming a patterned resist film on a substrate is not particularly limited. Such a patterned resist film is suitably used as a template and the like for forming a plated article. As a suitable method, a production method of a patterned resist film can be exemplified which includes:
a lamination step of laminating a photosensitive layer consisting of the first photosensitive composition or the second photosensitive composition on the substrate;
an exposure step of exposing the photosensitive layer by position selectively irradiating active rays or radioactive rays; and
a development step of developing an exposed photosensitive layer. A method of forming a substrate with a template for forming a plated article is the same method as the method of manufacturing a patterned resist film except that the method includes laminating a photosensitive layer on a substrate, and a template for forming a plated article is produced by developing in the developing step.

The substrate on which the photosensitive layer is laminated is not particularly limited, and conventionally known substrates can be used. Examples thereof include a substrate for an electronic component, and the substrate on which a predetermined wiring pattern is formed. As the substrate, a silicon substrate, glass substrate, or the like, can be used. When a substrate with a template for forming a plated article is manufactured, for the substrate, a substrate having a metal surface is used. As metal species constituting a metal surface, copper, gold and aluminum are preferred, and copper is more preferred.

The photosensitive layer is laminated on the substrate, for example, as follows. In other words, the liquid first photosensitive composition or second photosensitive composition is coated onto a substrate, and the coating is heated to remove the solvent and thus to form a photosensitive layer having a desired thickness. The thickness of the photosensitive layer is not particularly limited as long as it is possible to form a patterned resist film which has a desired thickness. The thickness of the photosensitive layer is not particularly limited, and is preferably 0.5 μm or more, more preferably 0.5 μm or more and 300 μm or less, even more preferably 0.5 μm or more and 200 μm or less, and particularly preferably 0.5 μm or more and 150 μm or less.

In addition, a photosensitive layer thickness of 50 μm or more and 300 μm or less is also preferred. When a thick resist film is used as a template, there is a case that the temperature during plating is set higher or plating is performed over a longer period of time. Therefore, high resistance to the plating liquid is required for the patterned resist film used as the template. However, the patterned resist film formed using the aforementioned first photosensitive composition or second photosensitive composition has high resistance to the plating liquid Therefore, when the aforementioned first photosensitive composition or second photosensitive composition is used, plated article can be produced well even if the resist film used as the template is thick.

As a method of applying the first photosensitive composition or the second photosensitive composition onto a substrate, methods such as the spin coating method, the slit coat method, the roll coat method, the screen printing method and the applicator method can be employed. Pre-baking is preferably performed on a photosensitive layer. The conditions of pre-baking may differ depending on the components in the first photosensitive composition or the second photosensitive composition, the blending ratio, the thickness of a coating film and the like. They are usually about 2 minutes or more and 120 minutes or less at 70° C. or more and 200° C. or less, and preferably 80° C. or more and 150° C. or less.

The photosensitive layer formed as described above is selectively irradiated (exposed) with an active ray or radiation, for example, an ultraviolet radiation or visible light with a wavelength of 300 nm or more and 500 nm or less through a mask having a predetermined pattern.

Low pressure mercury lamps, high pressure mercury lamps, super high pressure mercury lamps, metal halide lamps, argon gas lasers, etc. can be used for the light source of the radiation. The radiation may include micro waves, infrared rays, visible lights, ultraviolet rays, X-rays, y-rays, electron beams, proton beams, neutron beams, ion beams, etc. The irradiation dose of the radiation may vary depending on the constituent of the first photosensitive composition or the second photosensitive composition, the film thickness of the photosensitive layer, and the like. For example, when an ultra-high-pressure mercury lamp is used, the dose may be 100 mJ/cm² or more and 10,000 mJ/cm² or less. The radiation includes a light ray to activate the acid generator (A) in order to generate an acid.

After the exposure, the diffusion of acid is promoted by heating the photosensitive layer using a known method to change the alkali solubility of the photosensitive layer in developing solution such as an alkali developing solution at an exposed portion in the photosensitive resin film.

Subsequently, the exposed photosensitive layer is developed in accordance with a conventionally known method, and an unnecessary portion is dissolved and removed to form a template for forming a patterned resist film having predetermined pattern or plated articles. At this time, as the developing solution, an alkaline aqueous solution is used.

As the developing solution, an aqueous solution of an alkali such as, for example, sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, 1,8-diazabicyclo[5.4.0]-7-undecene or 1,5-diazabicyclo[4.3.0]-5-nonane can be used. Also, an aqueous solution prepared by adding an adequate amount of a water-soluble organic solvent such as methanol or ethanol, or a surfactant to the above aqueous solution of the alkali can be used as the developing solution.

The developing time may vary depending on the composition of the first photosensitive composition or the second photosensitive composition, the film thickness of the photosensitive layer, and the like. Usually, the developing time is 1 minute or more and 30 minutes or less. The method of the development may be any one of a liquid-filling method, a dipping method, a paddle method, a spray developing method, and the like.

After development, running water wash is performed for at least 30 seconds and no more than 90 seconds, and then dried using an air gun, oven or the like. By configuring in this way, the patterned resist film is formed in the desired shape on the surface of the substrate. In addition, by configuring in this way, it is possible to produce a substrate with a template including a patterned resist film as the template on the substrate.

A conductor such as a metal may be embedded, by plating, into a nonresist portion (a portion removed with a developing solution) in the template formed by the above method on the substrate to form a plated article, for example, like a contacting terminal such as a bump and a metal post, or Cu rewiring. Note here that there is no particular limitation on the method of plate processing, and various conventionally known methods can be used. As a plating liquid, in particular, a solder plating liquid, a copper plating liquid, a gold plating liquid, or a nickel plating liquid is suitably used. The remaining template is removed with a stripping liquid and the like in accordance with a conventional method.

Upon producing a plated article, it is preferable to perform an ashing treatment on the surface of the substrate exposed at a non-pattern part of the patterned resist film which becomes the template for the plated article. A plated article which is superior in adhesion to the surface of the substrate tends to be formed in this case. This is because, by ashing, it is possible to reduce the adverse effect exerted by the components in the first photosensitive composition or the second photosensitive composition bound or attached to the surface of the substrate, on adhesion of the plated article.

The ashing treatment is not particularly limited as long as long as it does not damage a resist pattern serving as a template for forming the plated article to such an extent that the plated article having a desired shape cannot be formed. Preferable ashing treatment methods include a method using oxygen plasma. For ashing with respect to the surface of the substrate using oxygen plasma, an oxygen plasma is generated using a known oxygen plasma generator, and the surface of the substrate is irradiated with the oxygen plasma.

Various gases which have conventionally been used for plasma treatment together with oxygen can be mixed into gas to be used for generating oxygen plasma within a range where the objects of the present invention are not impaired. Examples of such gas include nitrogen gas, hydrogen gas, CF₄ gas, and the like. Conditions of ashing using oxygen plasma are not particularly limited within a range where the objects of the present invention are not impaired, but treatment time is, for example, in a range of 10 seconds or more and 20 minutes or less, preferably in a range of 20 seconds or more and 18 minutes or less, and more preferably in a range of 30 seconds or more and 15 minutes or less. By setting the treatment time by oxygen plasma to the above range, an effect of improving the adhesiveness of the plated article can be easily achieved without changing a shape of the resist pattern.

### EXAMPLES

Hereinafter, the present invention will be explained in further detail by way of Examples; however, the present invention is not to be limited to these Examples.

### Examples 1 to 7, Comparative Example 1, and Comparative Example 2

In Examples and Comparative Examples, PAG1 and PAG2 represented by the following formulae were used as the acid generator (A).

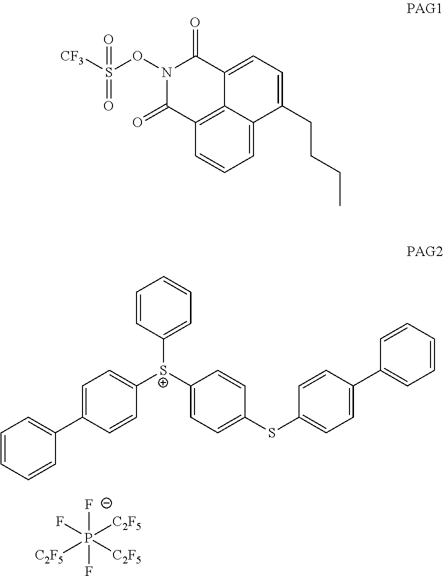

In Examples and Comparative Examples, Resin-B1 to Resin-B9 that is a resin (resin (B)) whose solubility in alkali increases under an action of acid, and includes constituent unit derived from monomers M1 to M11 shown in the Table 1 below at a molar ratio shown in the Table 1 were used. Weight average molecular weights of Resin-B1 to Resin-B9 and calculated values of glass transition temperatures of hypothetical non-crosslinked acrylic resins which the constituent units (bL1) are excluded from Resin-B1 to Resin-B9 are listed in the Table 1.

Specific structures of monomers M1 to M11 are as follows.

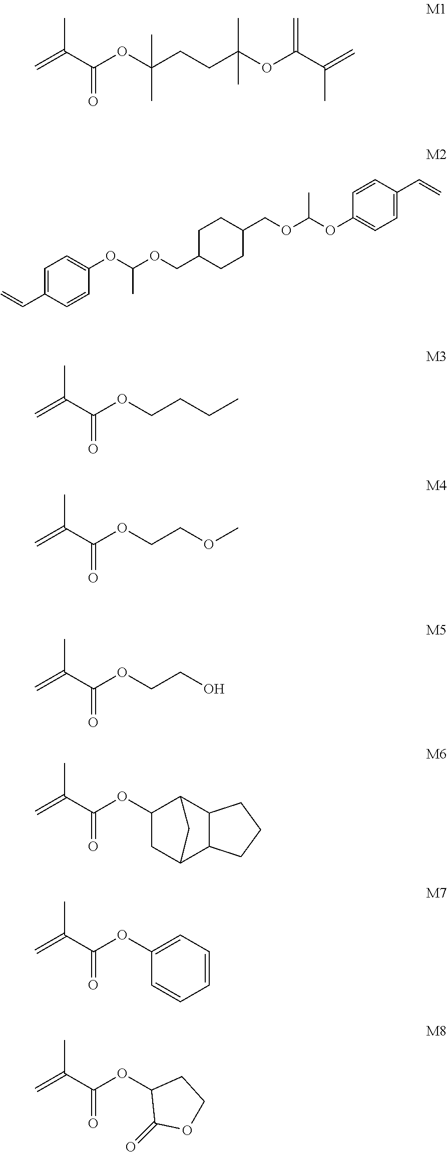

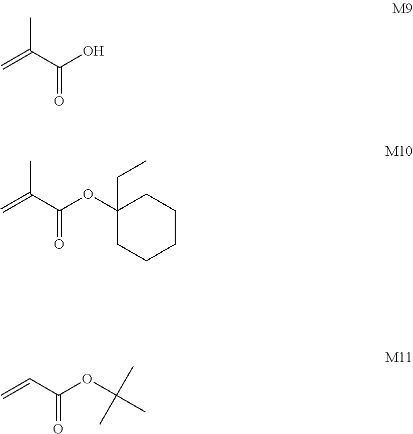

TABLE 1

| | Ratio of constituent unit (% by mole) | | | | | | | | | | | | |
|---|---|---|---|---|---|---|---|---|---|---|---|---|---|
| | bL1 | | bL2 | | | bL3 | | bL4 | bL5 | bL6 | | | |
| Monomer | M1 | M2 | M3 | M4 | M5 | M6 | M7 | M8 | M9 | M10 | M11 | Mw | (° C.) |
| Resin-B1 | 3 | — | 2 | — | — | 32 | — | 20 | 16 | 27 | — | 80000 | 111 |
| Resin-B2 | — | 3 | 2 | — | — | 32 | — | 20 | 16 | 27 | — | 80000 | 111 |
| Resin-B3 | 3 | — | — | 2 | — | 32 | — | 20 | 16 | 27 | — | 80000 | 112 |
| Resin-B4 | 3 | — | 2 | — | — | — | 32 | 20 | 16 | 27 | — | 80000 | 110 |
| Resin-B5 | 3 | — | — | 7 | — | 27 | — | 17 | 16 | — | 29 | 80000 | 91 |
| Resin-B6 | 3 | — | — | — | 2 | 32 | — | 20 | 16 | 27 | — | 80000 | 112 |
| Resin-B7 | 3 | — | 2 | — | — | 32 | — | 20 | 16 | 27 | — | 130000 | 111 |
| Resin-B8 | 3 | — | 0.3 | — | — | 56 | — | 22.7 | 7 | 12 | — | 80000 | 121 |
| Resin-B9 | 3 | — | — | 6 | — | 24 | — | 17 | 16 | — | 32 | 80000 | 87 |

In Examples and Comparative Example, the following compound was used as the sulfur-containing compound (D).

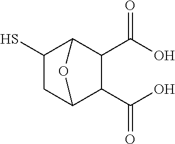 [SMILES: O=C(O)C1C2CC(S)C(O2)C1C(=O)O]

In Examples and Comparative Example, ADEKASTAB LA-63P (reaction product of 1,2,3,4-butanetetracarboxylic acid methyl ester, 1,2,2,6,6-pentamethyl-4-piperidinol, and β,β,β′-tetramethyl-2,4,8,10-tetraoxaspiro[5.5]undecane-3,9-diethanol) was used as the acid diffusion inhibitor (E).

The photosensitive compositions of each of Examples and Comparative Examples were obtained by dissolving 100 parts by mass of resin of the type shown in Table 1, 0.1 parts by mass of PAG1 described above, 1 parts by mass of PAG2 described above, 0.1 parts by mass of the sulfur-containing compound (D) described above, 0.05 parts by mass of the acid diffusion inhibitor (E) described above, and 0.05 parts by mass of the surfactant (BYK310, manufactured by BYK-Chemie) in propyleneglycol monomethyl ether acetate, so that the solid content concentration is 22% by mass.

A patterned resist film as a template for plating was formed using obtained photosensitive composition, and a cross-sectional shape of the resist film and a plating liquid resistance of the resist film were evaluated according to following methods. Evaluation results are shown in Table 2

### [Evaluation of Cross-Sectional Shape of Resist Film]

Substrates with copper films of a 200 nm thick sputtered onto the surfaces of a Si substrates were prepared. The photosensitive compositions of Examples and Comparative Examples were applied on copper layers on these substrates, and dried at 130° C. for 20 seconds to form photosensitive layers (applied films of the photosensitive compositions) with 240 μm thickness. Subsequently, the photosensitive layer was exposed via mask of line-and-space pattern of 100 μm line width and 100 μm space width by using a projection exposure device (Ultratech ghi prisma (manufactured by Ultratech, Inc., NA=0.12) at an exposure amount of 2000 J/cm². After exposure, post-exposure heating (PEB) was performed for 180 seconds at 100° C. by placing the substrate on a hot plate. Subsequently, the operation of dropping a 2.38% by weight aqueous solution of tetramethylammoniumhydroxide (TMAH) (developing solution, NMD-3, manufactured by Tokyo Ohka Kogyo Co., Ltd.) onto the exposed photosensitive layer, leaving to stand for 60 seconds at 23° C. (puddle development) was repeated a total of twelve times. Subsequently, after running water washing (rinse) the surface of the resist film patterned by development for 60 seconds, it was spin dried to obtain a patterned resist film as a template for plating. With respect to obtained resist films, cross-sectional shape was evaluated according to the following criteria by observing a cross-section which is perpendicular to the plane direction of the Si substrate, and in which a line part with about 100 μm width and a space part with about 100 μm width can be observed, to measure a width of the line part at a center in thickness-direction and a width of a top surface of the line part. It should be noted that the top surface of the line part is a surface opposite to a surface of the line part contacting with the substrate.
Good: The width of the top surface is 95% or more and 105% or less relative to the width of the line part at the center in thickness-direction.
Bad: The width of the top surface is less than 95% or more than 105% relative to the width of the line part at the center in thickness-direction.

### [Evaluation of Plating Liquid Resistance of Resist Film]

The patterned resist film obtained in the same manner as that in the evaluation of cross-sectional shape of was immersed in an acidic plating liquid at 45° C. for 120 minutes. Plating resistance of the resist film was evaluated according to the following criteria by measuring a width of the line part at a center in thickness-direction with respect to the resist film not immersed and the resist film immersed.
Good: The width of the line part at the center in thickness-direction in the resist film immersed is 97% or more and 103% or less relative to the width of the line part at the center in thickness-direction in the resist film not immersed.
Poor: The width of the line part at the center in thickness-direction in the resist film immersed is less than 97% and more than 103% relative to the width of the line part at the center in thickness-direction in the resist film not immersed.

TABLE 2

| | | Cross-sectional | Plating liquid |
|---|---|---|---|
| | Acrylic resin | shape | resistance |
| Ex. 1 | Resin-B1 | Good | Good |
| Ex. 2 | Resin-B2 | Good | Good |
| Ex. 3 | Resin-B3 | Good | Good |
| Ex. 4 | Resin-B4 | Good | Good |
| Ex. 5 | Resin-B5 | Good | Good |
| Ex. 6 | Resin-B6 | Good | Good |
| Ex. 7 | Resin-B7 | Good | Good |
| Comp. Ex. 1 | Resin-B8 | Bad | Poor |
| Comp. Ex. 2 | Resin-B9 | Good | Poor |

According to Table 1, it is found that the patterned resist film having good cross-sectional shape and good plating liquid resistance can be formed by using the chemically amplified positive-type photosensitive composition including Resin-B1 to Resin-B7 that satisfy both the requirements for acrylic resin (B1a) for the first photosensitive composition described above and the requirements for acrylic resin (B1b) for the second photosensitive composition described above.

On the other hand, when the chemically amplified positive-type photosensitive composition of Comparative Example 1 including Resin-B8 in which the calculated value of glass transition temperature of hypothetical non-crosslinked acrylic resin which the constituent unit (bL1) is excluded is 120° C. or higher, and the content of the constituent unit (bL3) is 50% by mole or more, or the chemically amplified positive-type photosensitive composition of Comparative Example 2 including Resin-B9 in which the calculated value of glass transition temperature of hypothetical non-crosslinked acrylic resin which the constituent unit (bL1) is 90° C. lower, and the content of the constituent unit (bL3) is 25% by mole or less, it is found that formation of patterned resist film having good cross-sectional shape and good plating liquid resistance is difficult.

1. A chemically amplified positive-type photosensitive composition used for forming a template for plating on a substrate by a photolithography method,
wherein the chemically amplified positive-type photosensitive composition comprises an acid generator (A) which generates an acid by irradiation of active rays or radioactive rays; and a resin (B) whose solubility in alkali increases under an action of acid,
wherein the resin (B) comprises an acrylic resin (B1a) comprising a constituent unit (bL1) derived form a crosslinkable monomer represented by formula (BL1):
R^{B1}—O—R^{B3}—O—R^{B2} (BL1)
wherein, in the formula (BL1), R^{B1} and R^{B2} are each independently a (meth)acryloyl group or a vinylphenyl group, R^{B3} is a divalent bridging group, and at least one of two O—R^{B3} bonds in the formula (BL1) generates a carboxy group or a phenolic hydroxy group by cleavage by an action of acid,
a molar ratio of the constituent unit (bL1) is 1% by mole or more and 10% by mole or less relative to all constituent units of the acrylic resin (B1a), and
a calculated value of a glass transition temperature of a hypothetical non-crosslinked acrylic resin in which the constituent unit (bL1) is excluded from the acrylic resin (B1a) is 90° C. or higher and 120° C. or lower.

2. The chemically amplified positive-type photosensitive composition according to claim 1,
wherein the acrylic resin (B1a) further comprises a constituent unit (bL2) derived from an alkyl (meth)acrylate (BL2), and a constituent unit (bL3) derived from an (meth)acrylate (BL3) comprising an alicyclic hydrocarbon group or an aromatic group,
in the alkyl (meth)acrylate (BL2), an alkyl group optionally substituted with a hydroxy group or an alkoxy group and having 1 or more and 10 or less carbon atoms bonds to a (meth)acryloyloxy group, and a carbon atom which bonds to the (meth)acryloyloxy group does not correspond to a tertiary carbon atom having an sp³ hybrid orbital,
in the (meth)acrylate (BL3) comprising the alicyclic hydrocarbon group or the aromatic group, the alicyclic hydrocarbon group or the aromatic group bonds to a (meth)acryloyloxy group, the alicyclic hydrocarbon group or the aromatic group may be substituted with one or more substituents selected from the group consisting of an alkyl group, an alkoxy group and a hydroxy group, and a carbon atom to which the (meth)acryloyloxy group bonds does not correspond to a tertiary carbon atom having an sp³ hybrid orbital,
a molar ratio of the constituent unit (bL2) is 0.1% by mole or more and 10% by mole or less relative to all constituent units of the acrylic resin (B1a), and
a molar ratio of the constituent unit (bL3) is 25% by mole or more and 50% by mole or less relative to all constituent units of the acrylic resin (B1a).

3. A chemically amplified positive-type photosensitive composition used for forming a template for plating on a substrate by a photolithography method, wherein the chemically amplified positive-type photosensitive composition comprises an acid generator (A) which generates an acid by irradiation of active rays or radioactive rays; and a resin (B) whose solubility in alkali increases under an action of acid,
wherein the resin (B) comprises an acrylic resin (B1b) comprising a constituent unit (bL1) derived form a crosslinkable monomer represented by formula (BL1):
R^{B1}—O—R^{B3}—O—R^{B2} (BL1)
wherein, in the formula (BL1), R^{B1} and R^{B2} are each independently a (meth)acryloyl group or a vinylphenyl group, R^{B3} is a divalent bridging group, and at least one of two O—R^{B3} bonds in the formula (BL1) generates a carboxy group or a phenolic hydroxy group by cleavage by an action of acid,
a constituent unit (bL2) derived from an alkyl (meth)acrylate (BL2), and
a constituent unit (bL3) derived from an (meth)acrylate (BL3) comprise an alicyclic hydrocarbon group or an aromatic group,
in the alkyl (meth)acrylate (BL2), an alkyl group optionally substituted with a hydroxy group or an alkoxy group and having 1 or more and 10 or less carbon atoms bonds to a (meth)acryloyloxy group, and a carbon atom which bonds to the (meth)acryloyloxy group does not correspond to a tertiary carbon atom having an sp³ hybrid orbital,
in the (meth)acrylate (BL3) comprising the alicyclic hydrocarbon group or the aromatic group, the alicyclic hydrocarbon group or the aromatic group bonds to a (meth)acryloyloxy group, the alicyclic hydrocarbon group or the aromatic group may be substituted with one or more substituents selected from the group consisting of an alkyl group, an alkoxy group and a hydroxy group, and a carbon atom to which the (meth)acryloyloxy group bonds does not correspond to a tertiary carbon atom having an sp³ hybrid orbital,
a molar ratio of the constituent unit (bL1) is 1% by mole or more and 10% by mole or less relative to all constituent units of the acrylic resin (B1b),
a molar ratio of the constituent unit (bL2) is 0.1% by mole or more and 10% by mole or less relative to all constituent units of the acrylic resin (B1b), and
a molar ratio of the constituent unit (bL3) is 25% by mole or more and 50% by mole or less relative to all constituent units of the acrylic resin (B1b).

4. The chemically amplified positive-type photosensitive composition according to claim 1, wherein the acrylic resin (B1a) or the acrylic resin (B1b) comprises a constituent unit (bL4) comprising an —SO₂-containing cyclic group or a lactone-containing cyclic group.

5. The chemically amplified positive-type photosensitive composition according to claim 1, wherein the acrylic resin (B1a) or the acrylic resin (B1b) comprises a constituent unit (bL5) derived from a (meth)acrylic acid, and a molar ratio of the constituent unit (bL5) is 5% by mole or more and 30% by mole or less relative to all constituent units of the acrylic resin (B1a) or the acrylic resin (B1b).

6. The chemically amplified positive-type photosensitive composition according to claim 1, wherein the R^{B3} is a divalent group represented by formula (BL1-A):
—CR^{B4}R^{B5}—R^{B8}—CR^{B6}R^{B7}— (BL1-A)
wherein, in the formula (BL1-A), R^{B4}, R^{B5}, R^{B6}, and R^{B7} are each independently an alkyl group having 1 or more and 4 or less carbon atoms, R^{B8} is a single bond or a divalent organic group, R^{B4} or R^{B5} may form a ring with R^{B8}, R^{B6} or R^{B7} may form a ring with R^{B8}, and a carbon atom to which R^{B4} and R^{B5} bond, and a carbon atom to which R^{B6} and R^{B7} bond are both tertiary carbon atoms having sp3 hybrid orbitals.

7. A photosensitive dry film comprising a base film, and a photosensitive layer formed on a surface of the base film, wherein the photosensitive layer comprises the chemically amplified positive-type photosensitive composition according to claim 1.

8. A method of producing a substrate having a template for plating, comprising:
laminating a photosensitive layer consisting of the chemically amplified positive-type photosensitive composition according to claim 1 on a substrate,
position selectively irradiating active rays or radioactive rays onto the photosensitive layer; and
forming a patterned resist film as a template for plating by developing the photosensitive layer after exposure.

9. The production method of the substrate having the template for plating according to claim 8, wherein a thickness of the photosensitive layer is 50 μm or more and 300 μm or less.

10. A method of producing a plated article comprising forming the plated article by plating to the substrate having the template produced by the method according to claim 8.

11. The chemically amplified positive-type photosensitive composition according to claim 3, wherein the acrylic resin (B1a) or the acrylic resin (B1b) comprises a constituent unit (bL4) comprising an —SO₂-containing cyclic group or a lactone-containing cyclic group.

12. The chemically amplified positive-type photosensitive composition according to claim 3, wherein the acrylic resin (B1a) or the acrylic resin (B1b) comprises a constituent unit (bL5) derived from a (meth)acrylic acid, and a molar ratio of the constituent unit (bL5) is 5% by mole or more and 30% by mole or less relative to all constituent units of the acrylic resin (B1a) or the acrylic resin (B1b).

13. The chemically amplified positive-type photosensitive composition according to claim 3, wherein the R^{B3} is a divalent group represented by formula (BL1-A):
—CR^{B4}R^{B5}—R^{B8}—CR^{B6}R^{B7}— (BL1-A)
wherein, in the formula (BL1-A), R^{B4}, R^{B5}, R^{B6}, and R^{B7} are each independently an alkyl group having 1 or more and 4 or less carbon atoms, R^{B8} is a single bond or a divalent organic group, R^{B4} or R^{B5} may form a ring with R^{B8}, R^{B6} or R^{B7} may form a ring with R^{B8}, and a carbon atom to which R^{B4} and R^{B5} bond, and a carbon atom to which R^{B6} and R^{B7} bond are both tertiary carbon atoms having sp3 hybrid orbitals.

14. A photosensitive dry film comprising a base film, and a photosensitive layer formed on a surface of the base film, wherein the photosensitive layer comprises the chemically amplified positive-type photosensitive composition according to claim 3.

15. A method of producing a substrate having a template for plating comprising:
laminating a photosensitive layer consisting of the chemically amplified positive-type photosensitive composition according to claim 3 on a substrate;
position selectively irradiating active rays or radioactive rays onto the photosensitive layer; and
forming a patterned resist film as a template for plating by developing the photosensitive layer after exposure.

16. The of according to claim 15, wherein a thickness of the photosensitive layer is 50 μm or more and 300 μm or less.

17. A method of producing a plated article comprising forming the plated article by plating to the substrate having the template produced by the method according to claim 15.
